(19) United States
(12) Patent Application Publication
(10) Pub. No.: US 2024/0101761 A1
(43) Pub. Date: Mar. 28, 2024

(54) POLYIMIDE PRECURSOR RESIN COMPOSITION AND METHOD FOR MANUFACTURING SAME

(71) Applicant: ASAHI KASEI KABUSHIKI KAISHA, Tokyo (JP)

(72) Inventors: Kohei MURAKAMI, Tokyo (JP); Tomohito OGURA, Tokyo (JP)

(73) Assignee: ASAHI KASEI KABUSHIKI KAISHA, Tokyo (JP)

(21) Appl. No.: 18/271,758

(22) PCT Filed: Jan. 12, 2022
(86) PCT No.: PCT/JP2022/000778

§ 371 Date: Jul. 11, 2023

(30) Foreign Application Priority Data
Jan. 12, 2021 (JP) 2021-002598
Sep. 30, 2021 (JP) 2021-161406

(51) Int. Cl. C08G 73/14; G03F 7/004; G03F 7/022; G03F 7/031; G03F 7/038; G03F 7/38

(52) U.S. Cl. CPC C08G 73/14; G03F 7/0048; G03F 7/0226; G03F 7/031; G03F 7/0382; G03F 7/0387; G03F 7/38

(57) ABSTRACT

The purpose of the present disclosure is to provide a method for manufacturing a polyimide (PI) precursor resin composition that has excellent resolution performance, a broad range of available exposure and good handling properties. Provided is a method for manufacturing a PI precursor resin composition that comprises a PI precursor resin, an exposure light absorber, a photopolymerization initiator and a solvent. The PI precursor resin is selected from among materials having an absorbance parameter Xp for a light species within a range of 0.001-0.20, the exposure light absorber is selected from among materials having an absorbance parameter Xt for the light species within a range of 0.01-0.05, and the photopolymerization initiator is selected from among materials having an absorbance parameter Xr for the light species within a range of 0-0.04. On the basis of an assumed thickness D of a film that is formed by applying the PI precursor resin composition and desolventing, the addition amount (parts by mass) α of the exposure light absorber and the addition amount (parts by mass) β of the photopolymerization initiator are determined so as to satisfy the formula: 0.7≤(Xp+Xt×α+Xr×β)×D≤2.2.

### FIELD

The present disclosure relates to a polyimide precursor resin composition and to a method for producing it.

### BACKGROUND

Polyimide (PI) resins exhibit excellent heat resistance, electrical characteristics and chemical resistance and are therefore used as insulating materials for electronic parts and as passivation films, surface-protecting films and interlayer dielectric films in semiconductor devices. Photosensitive polyimides, obtained by imparting photosensitivity to polyimide resins, are provided in the form of polyimide precursor resin compositions containing a polyimide precursor resin (also known as “varnish”) and a photosensitive agent, and it is possible to form relief patterns of the polyimide by carrying out thermal imidization treatment involving coating, exposure, development and curing of the varnish. Formation of non-photosensitive polyimide relief patterns requires coating and release of a resist material, but photosensitive polyimide precursor resins allow the process to be greatly shortened.

In addition, recent years have also seen changes to the methods of mounting semiconductor devices onto printed wiring boards (packaging structures), from the viewpoint of increasing integration and computing function, as well as reducing chip sizes. Specifically, there has been a trend away from the conventional mounting methods using metal pins and lead-tin eutectic solder, and toward structures wherein polyimide coating films directly contact with solder bumps, such as BGA (ball grid array) and CSP (chip-size packages), that allow high-density mounting. There have also been proposed structures in which the surfaces of semiconductor chips are provided with multiple redistribution layers having larger areas than the semiconductor chip area, as in FO (fan-out) methods (see PTLs 1 and 2, for example).

Along with the decreasing sizes and increasing densities of such packages there has been a demand for higher resolution performance in the resin films forming the redistribution layers.

### CITATION LIST

### Patent Literature

[PTL 1] Japanese Unexamined Patent Publication No. 2005-167191
[PTL 2] Japanese Unexamined Patent Publication No. 2011-129767

### SUMMARY

### Technical Problem

When a negative-type photosensitive resin composition is used as a PI precursor resin composition, the exposure rays must sufficiently converge onto the film bottom layer during photoresist patterning in order to prevent residue from being generated at the development opening by the exposure rays reflected at the film bottom layer, and to prevent development defects. If the exposure rays fail to reach the film bottom layer, photocrosslinking of the film bottom layer will be insufficient and tapered defects known as “undercuts” (overhanging) may occur. It is therefore an object of the present disclosure to provide a PI precursor resin composition with excellent resolvability, a wide range of usable exposure doses, and excellent handleability. The problems referred to above occur most notably when a PI precursor resin composition is thinly coated, or when a PI precursor resin composition with low exposure ray absorbance is used.

### Solution to Problem

The present inventors have found that it is possible to provide a PI precursor resin composition with excellent resolvability, a wide range of usable exposure doses and excellent handleability, if it is a PI precursor resin composition that includes a PI precursor resin, an exposure ray absorber, a photopolymerization initiator and a solvent, wherein the composition is decided on by a specific method based on the light absorption parameters of the PI precursor resin, the exposure ray absorber and the photopolymerization initiator for the type of light used for exposure. The following [1] to [43] are examples of embodiments of the disclosure.

[1]

A method for producing a polyimide (PI) precursor resin composition comprising a PI precursor resin, an exposure ray absorber, a photopolymerization initiator and a solvent, wherein the method includes:
a step of specifying a type of light to be used for exposure;
a step of selecting the PI precursor resin from among resins having an absorbance parameter Xp in the range of 0.001 to 0.20 for the specified type of light, selecting the exposure ray absorber from among materials having an absorbance parameter Xt in the range of 0.01 to 0.05 for the specified type of light, and selecting the photopolymerization initiator from among materials having an absorbance parameter Xr in the range of 0 to 0.04 for the specified type of light;
a step of deciding mass fraction α of the exposure ray absorber to be added and mass fraction β of the photopolymerization initiator to be added, with respect to 100 parts by mass of the PI precursor resin, so as to satisfy the following formula:

0.7≤(Xp+Xt×α+Xr×β)×D≤2.2

based on the absorbance parameter Xp of the selected PI precursor resin, the absorbance parameter Xt of the selected exposure ray absorber, the absorbance parameter Xr of the selected photopolymerization initiator, and an assumed thickness D of a prebaked film after coating and solvent removal of the PI precursor resin composition; and
a step of preparing a PI precursor resin composition so as to include the decided PI precursor resin, the exposure ray absorber at the decided mass fraction α, the photopolymerization initiator at the decided mass fraction β, and the solvent.
   [2]

The method according to [1] above, wherein the PI precursor resin has a structural unit represented by the following formula (1):

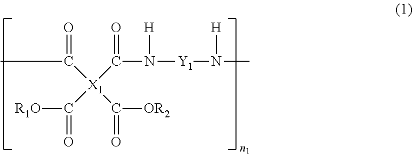

{where X₁ is a tetravalent organic group, Y₁ is a divalent organic group, n₁ is an integer of 2 to 150, and R₁ and R₂ are each independently a hydrogen atom, a monovalent organic group represented by the following general formula (2) or a saturated aliphatic group of 1 to 4 carbon atoms.}

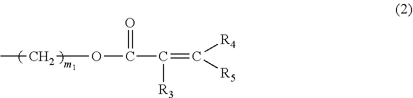

{where R₃, R₄ and R₅ are each independently a hydrogen atom or an organic group of 1 to 3 carbon atoms, and mi is an integer of 2 to 10}.
[3]

The method according to [1] or [2] above, wherein the type of light used for exposure is i-line.

[4]

The method according to any one of [1] to [3] above, wherein the assumed thickness D is set to be 1 μm or greater and less than 7 μm for deciding the mass fraction α of the exposure ray absorber to be added and the mass fraction β of the photopolymerization initiator to be added.

[5]

The method according to any one of [1] to [4] above, wherein the photopolymerization initiator has an oxime ester structure represented by the following general formula (5):

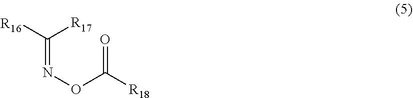

{where R₁₆, R₁₇ and R₁₈ are each a monovalent organic group, and R₁₆ and R₁₇ may be linked together to form a ring structure}.
[6]

The method according to any one of [1] to [5] above, wherein the PI precursor resin composition further includes a nitrogen-containing heterocyclic rust inhibitor.

[7]

The method according to any one of [1] to [6] above, wherein the exposure ray absorber is a compound having a 1,2-naphthoquinonediazide structure.

[8]

The method according to any one of [1] to [7] above, wherein the PI precursor resin composition further includes a photopolymerizable compound.

[9]

The method according to any one of [1] to [8] above, wherein Y₁ in formula (1) is a divalent organic group represented by the following formula (3):

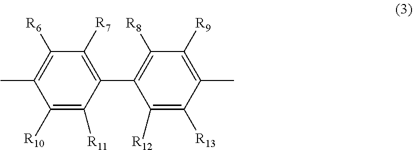

{where R₆ to R₁₃ are each independently a hydrogen atom, a fluorine atom or a monovalent organic group, with at least one of R₆ to R₁₃ being a methyl, trifluoromethyl or methoxy group}.
[10]

The method according to any one of [1] to [9] above, wherein Y₁ in formula (1) is a divalent organic group represented by the following formula (4):

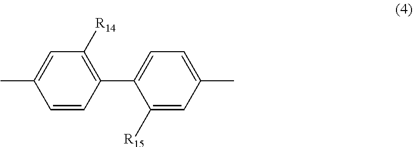

{where R₁₄ and R₁₅ are each independently a methyl, trifluoromethyl or methoxy group}.
[11]

The method according to any one of [1] to [10] above, wherein the exposure ray absorber is a 1,2-naphthoquinonediazide-4-sulfonic acid ester and/or 1,2-naphthoquinonediazide-5-sulfonic acid ester of at least one hydroxy compound selected from the group consisting of the following general formulas (6) to (10):

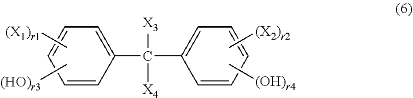

{where X₁ and X₂ are each independently a hydrogen atom or a monovalent organic group of 1 to 60 carbon atoms, X₃ and X₄ are each independently a hydrogen atom or a monovalent organic group of 1 to 60 carbon atoms, r1, r2, r3 and r4 are each independently an integer of 0 to 5, at least one of r3 and r4 is an integer of 1 to 5, r1+r3=5 and r2+r4=5},

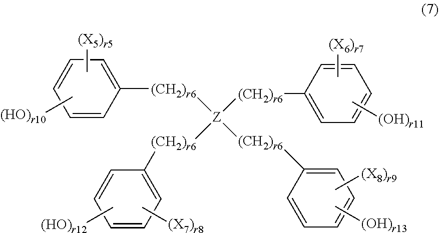

{where Z is a tetravalent organic group of 1 to 20 carbon atoms, X₅, X₆, X₇ and X₈ are each independently a monovalent organic group of 1 to 30 carbon atoms, r6 is an integer of 0 or 1, r5, r7, r8 and r9 are each independently an integer of 0 to 3, r10, r11, r12 and r13 are each independently an integer of 0 to 2, and at least one of r10, r11, r12 and r13 is 1 or 2},

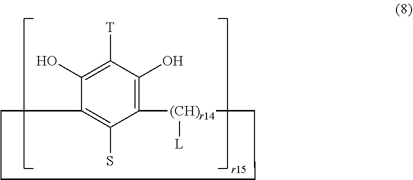

{where r14 is an integer of 1 to 5, r15 is an integer of 3 to 8, the L groups in the number of r14×r15 are each independently a monovalent organic group of 1 to 20 carbon atoms the T groups in the number of r15 are each independently a hydrogen atom or a monovalent organic group of 1 to 20 carbon atoms, and the S groups in the number of r15 are each independently a hydrogen atom or a monovalent organic group of 1 to 20 carbon atoms},

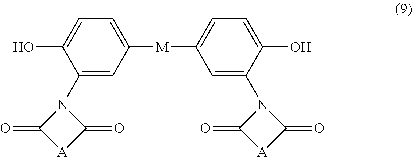

{where A is a divalent organic group including an aliphatic tertiary or quaternary carbon atom, and M is a divalent organic group},

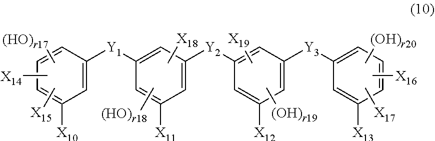

{where r17, r18, r19 and r20 are each independently an integer of 0 to 2, at least one of r17, r18, r19 and r20 being 1 or 2, X₁₀ to X₁₉ are each independently a hydrogen atom, a halogen atom or at least one monovalent group selected from the group consisting of alkyl, alkenyl, alkoxy, allyl and acyl groups, and Y₁ to Y₃ are each independently a single bond, or at least one divalent group selected from the group consisting of —O—, —S—, —SO—, —SO₂—, —CO—, —CO₂—, cyclopentylidene, cyclohexylidene, phenylene and divalent organic groups of 1 to 20 carbon atoms}.
[12]

The method according to any one of [1] to [11] above, wherein the exposure ray absorber is a 1,2-naphthoquinonediazide-5-sulfonic acid ester of at least one hydroxy compound selected from the group consisting of formulas (6) to (10).

[13]

The method according to any one of [1] to [12] above, wherein the esterification rate of the exposure ray absorber is 80% or greater.

[14]

The method according to any one of [1] to [13] above, wherein the hydroxy compound represented by general formula (6) above is represented by the following general formula (11):

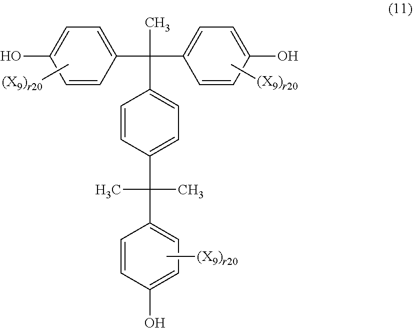

{where each r20 is independently an integer of 0 to 2, and each X₉ is independently a hydrogen atom or a monovalent organic group of 1 to 20 carbon atoms}.
[15]

A method for producing a relief pattern film, wherein the method includes:
a step in which a PI precursor resin composition comprising a PI precursor resin, an exposure ray absorber, a photopolymerization initiator and a solvent is produced by the method according to any one of [1] to [14] above,
a film coating step in which a coating film of the PI precursor resin composition is obtained,
a drying step in which the solvent in the coating film is removed to obtain a photosensitive resin layer of thickness D′,
an exposure step in which the photosensitive resin layer is exposed by a specified type of light, and
a developing step in which the exposed photosensitive resin layer is developed to obtain a relief pattern film.
   [16]

A method for producing a relief pattern film according to [15] above,
wherein the coating film of thickness D′ after solvent removal satisfies:

0.7≤(Xp+Xt×α+Xr×β)×D′≤2.2.

[17]

A PI precursor resin composition comprising a PI precursor resin, an exposure ray absorber at mass fraction α and a photopolymerization initiator at mass fraction β with respect to 100 parts by mass of the PI precursor resin, and a solvent, wherein:
the relationships between:
the absorbance parameter Xp of the PI precursor resin for i-line,
the absorbance parameter Xt of the exposure ray absorber for i-line,
the absorbance parameter Xr of the photopolymerization initiator for i-line,
the mass fraction α of the exposure ray absorber, and
the mass fraction β of the photopolymerization initiator, are:

0.7≤(Xp+Xt×α+Xr×β)×10≤2.2

0.001≤Xp≤0.20

0.01≤Xt≤0.05

0≤Xr≤0.04.

[18]

A polyimide (PI) precursor resin composition comprising a PI precursor resin, an exposure ray absorber at mass fraction α and a photopolymerization initiator at mass fraction β with respect to 100 parts by mass of the PI precursor resin, and a solvent, wherein:
the relationships between:
the absorbance parameter Xp of the PI precursor resin for i-line,
the absorbance parameter Xt of the exposure ray absorber for i-line,
the absorbance parameter Xr of the photopolymerization initiator for i-line,
the mass fraction α of the exposure ray absorber, and
the mass fraction β of the photopolymerization initiator, are:

0.7≤(Xp+Xt×α+Xr×β)×5≤2.2

0.001≤Xp≤0.20

0.01≤Xt≤0.05

0≤Xr≤0.04.

[19]

The PI precursor resin composition according to [17] or [18] above, wherein the PI precursor resin has a structural unit represented by the following formula (1):

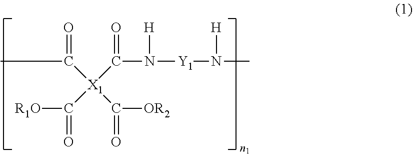

{where X₁ is a tetravalent organic group, Y₁ is a divalent organic group, n₁ is an integer of 2 to 150, and R₁ and R₂ are each independently a hydrogen atom or a monovalent organic group represented by the following general formula (2) or a saturated aliphatic group of 1 to 4 carbon atoms.}

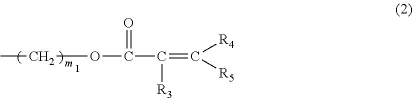

{where R₃, R₄ and R₅ are each independently a hydrogen atom or an organic group of 1 to 3 carbon atoms, and mi is an integer of 2 to 10}.
[20]

The PI precursor resin composition according to any one of [17] to [19] above, wherein the photopolymerization initiator has an oxime ester structure represented by the following general formula (5):

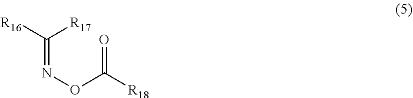

{where R₁₆, R₁₇ and R₁₈ are each a monovalent organic group, and R₁₆ and R₁₇ may be linked together to form a ring structure}.
[21]

The PI precursor resin composition according to any one of [17] to [20] above, wherein the PI precursor resin composition further includes a nitrogen-containing heterocyclic rust inhibitor.

[22]

The PI precursor resin composition according to any one of [17] to [21] above, wherein the exposure ray absorber is a compound having a 1,2-naphthoquinonediazide structure.

[23]

The PI precursor resin composition according to any one of [17] to [22] above, wherein the PI precursor resin composition further includes a photopolymerizable compound.

[24]

The PI precursor resin composition according to any one of [17] to [23] above, wherein Y₁ in formula (1) is a divalent organic group represented by the following formula (3):

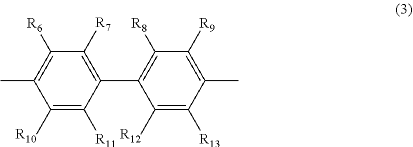

{where R₆ to R₁₃ are each independently a hydrogen atom, a fluorine atom or a monovalent organic group, with at least one of R₆ to R₁₃ being a methyl, trifluoromethyl or methoxy group}.
[25]

The PI precursor resin composition according to any one of [17] to [24] above, wherein Y₁ in formula (1) is a divalent organic group represented by the following formula (4):

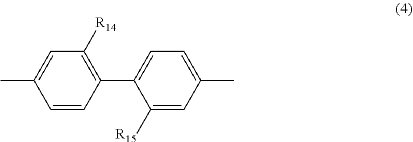

{where R₁₄ and R₁₅ are each independently a methyl, trifluoromethyl or methoxy group}.
[26]

The PI precursor resin composition according to any one of [17] to [25] above, wherein the exposure ray absorber is a 1,2-naphthoquinonediazide-4-sulfonic acid ester and/or 1,2-naphthoquinonediazide-5-sulfonic acid ester of at least one hydroxy compound selected from the group consisting of the following general formulas (6) to (10):

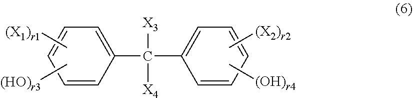

{where X₁ and X₂ are each independently a hydrogen atom or a monovalent organic group of 1 to 60 carbon atoms, X₃ and X₄ are each independently a hydrogen atom or a monovalent organic group of 1 to 60 carbon atoms, r1, r2, r3 and r4 are each independently an integer of 0 to 5, at least one of r3 and r4 is an integer of 1 to 5, r1+r3=5 and r2+r4=5},

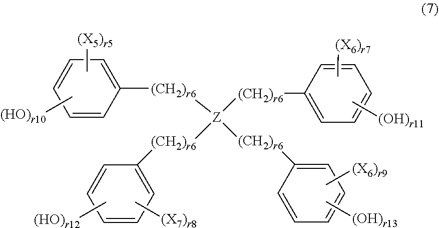

{where Z is a tetravalent organic group of 1 to 20 carbon atoms, X₅, X₆, X₇ and X₈ are each independently a monovalent organic group of 1 to 30 carbon atoms, r6 is an integer of 0 or 1, r5, r7, r8 and r9 are each independently an integer of 0 to 3, r10, r11, r12 and r13 are each independently an integer of 0 to 2, and at least one of r10, r11, r12 and r13 is 1 or 2},

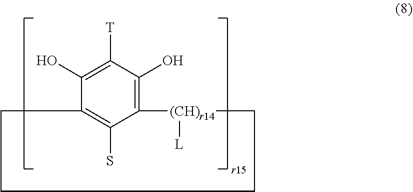

{where r14 is an integer of 1 to 5, r15 is an integer of 3 to 8, the L groups in the number of r14×r15 are each independently a monovalent organic group of 1 to 20 carbon atoms, the T groups in the number of r5 are each independently a hydrogen atom or a monovalent organic group of 1 to 20 carbon atoms, and the S groups in the number of r15 are each independently a hydrogen atom or a monovalent organic group of 1 to 20 carbon atoms},

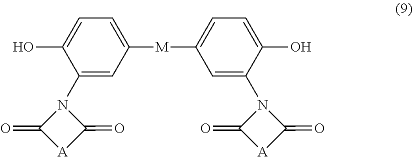

{where A is a divalent organic group including an aliphatic tertiary or quaternary carbon atom, and M is a divalent organic group},

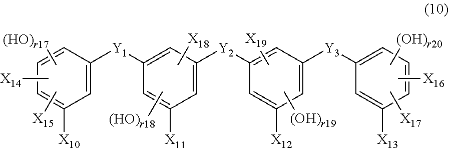

{where r17, r18, r19 and r20 are each independently an integer of 0 to 2, at least one of r17, r18, r19 and r20 being 1 or 2, X₁₀ to X₁₉ are each independently a hydrogen atom, a halogen atom or at least one monovalent group selected from the group consisting of alkyl, alkenyl, alkoxy, allyl and acyl groups, and Y₁ to Y₃ are each independently a single bond, or at least one divalent group selected from the group consisting of —O—, —S—, —SO—, —SO₂—, —CO—, —CO₂—, cyclopentylidene, cyclohexylidene, phenylene and divalent organic groups of 1 to 20 carbon atoms}.
[27]

The PI precursor resin composition according to any one of [17] to [26] above, wherein the exposure ray absorber is a 1,2-naphthoquinonediazide-5-sulfonic acid ester of at least one hydroxy compound selected from the group consisting of formulas (6) to (10).

[28]

The PI precursor resin composition according to any one of [17] to [27] above, wherein the esterification rate of the exposure ray absorber is 80% or greater.

[29]

The PI precursor resin composition according to any one of [17] to [28] above, wherein the hydroxy compound represented by general formula (6) above is represented by the following general formula (11):

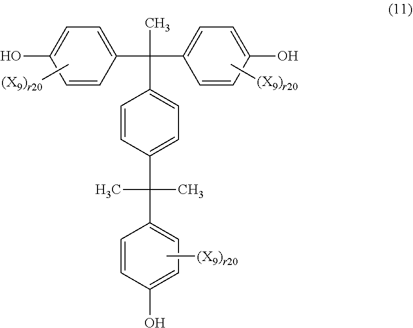

{where each r20 is independently an integer of 0 to 2, and each X₉ is independently a hydrogen atom or a monovalent organic group of 1 to 20 carbon atoms}.
[30]

A cured film of a PI precursor resin composition according to any one of [17] to [29] above.

[31]

A prebaked film which includes a polyimide (PI) precursor resin composition and has a thickness D′ satisfying 1 μm≤D′≤20 μm, wherein:
the PI precursor resin composition comprises a PI precursor resin, an exposure ray absorber at mass fraction α with respect to 100 parts by mass of the PI precursor resin and a photopolymerization initiator at mass fraction β with respect to 100 parts by mass of the PI precursor resin, and a solvent,
the PI precursor resin has an absorbance parameter Xp in the range of 0.001≤Xp≤0.20 for i-line,
the exposure ray absorber has an absorbance parameter Xt in the range of 0.01≤Xt≤0.05 for i-line,
the photopolymerization initiator has an absorbance parameter Xr in the range of 0≤Xr≤0.04 for i-line, and
the parameters satisfy the following inequality:

0.7≤(Xp+Xt×α+Xr×β)×D′≤2.2.

[32]

The prebaked film according to [31] above, wherein the PI precursor resin has a structural unit represented by the following formula (1):

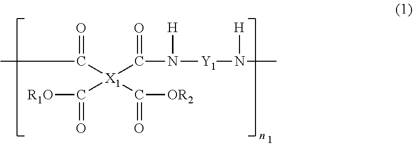

{where X₁ is a tetravalent organic group, Y₁ is a divalent organic group, n₁ is an integer of 2 to 150, and R₁ and R₂ are each independently a hydrogen atom or a monovalent organic group represented by the following general formula (2) or a saturated aliphatic group of 1 to 4 carbon atoms.}

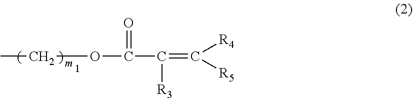

{where R₃, R₄ and R₅ are each independently a hydrogen atom or an organic group of 1 to 3 carbon atoms, and mi is an integer of 2 to 10}.
[33]

The prebaked film according to [31] or [32] above, wherein the thickness D′ of the prebaked film satisfies 1 μm≤D′<7 μm.

[34]

The prebaked film according to any one of [31] to [33] above, wherein the photopolymerization initiator has an oxime ester structure represented by the following general formula (5):

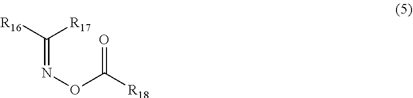

{where R₁₆, R₁₇ and R₁₈ are each a monovalent organic group, and R₁₆ and R₁₇ may be linked together to form a ring structure}.
[35]

The prebaked film according to any one of [31] to [34] above, wherein the PI precursor resin composition further includes a nitrogen-containing heterocyclic rust inhibitor.

[36]

The prebaked film according to any one of [31] to [35] above, wherein the exposure ray absorber is a compound having a 1,2-naphthoquinonediazide structure.

[37]

The prebaked film according to any one of [31] to [36] above, wherein the PI precursor resin composition further includes a photopolymerizable compound.

[38]

The prebaked film according to any one of [31] to [37] above, wherein Y₁ in formula (1) is a divalent organic group represented by the following formula (3):

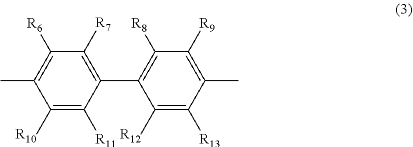

{where R₆ to R₁₃ are each independently a hydrogen atom, a fluorine atom or a monovalent organic group, with at least one of R₆ to R₁₃ being a methyl, trifluoromethyl or methoxy group}.
[39]

The prebaked film according to any one of [31] to [38] above, wherein Y₁ in formula (1) is a divalent organic group represented by the following formula (4):

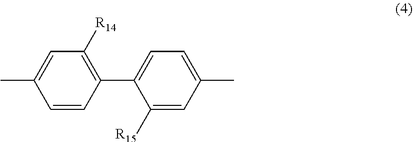

{where R₁₄ and R₁₅ are each independently a methyl, trifluoromethyl or methoxy group}.
[40]

The prebaked film according to any one of [31] to [39] above, wherein the exposure ray absorber is a 1,2-naphthoquinonediazide-4-sulfonic acid ester and/or 1,2-naphthoquinonediazide-5-sulfonic acid ester of at least one hydroxy compound selected from the group consisting of the following general formulas (6) to (10):

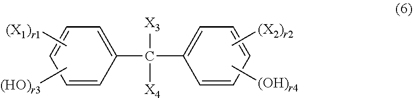

{where X₁ and X₂ are each independently a hydrogen atom or a monovalent organic group of 1 to 60 carbon atoms, X₃ and X₄ are each independently a hydrogen atom or a monovalent organic group of 1 to 60 carbon atoms, r1, r2, r3 and r4 are each independently an integer of 0 to 5, at least one of r3 and r4 is an integer of 1 to 5, r1+r3=5 and r2+r4=5},

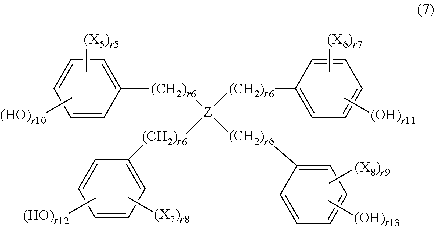

{where Z is a tetravalent organic group of 1 to 20 carbon atoms, X₅, X₆, X₇ and X₈ are each independently a monovalent organic group of 1 to 30 carbon atoms, r6 is an integer of 0 or 1, r5, r7, r8 and r9 are each independently an integer of 0 to 3, r10, r11, r12 and r13 are each independently an integer of 0 to 2, and at least one of r10, r11, r12 and r13 is 1 or 2},

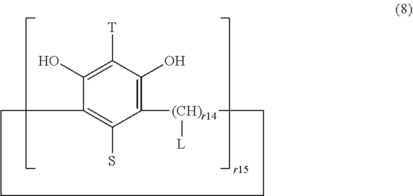

{where r14 is an integer of 1 to 5, r15 is an integer of 3 to 8, the L groups in the number of r14×r15 are each independently a monovalent organic group of 1 to 20 carbon atoms, the T groups in the number of r15 are each independently a hydrogen atom or a monovalent organic group of 1 to 20 carbon atoms, and the S groups in the number of r15 are each independently a hydrogen atom or a monovalent organic group of 1 to 20 carbon atoms},

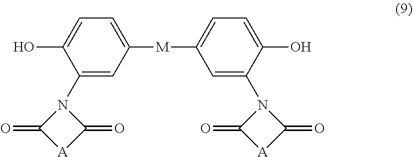

{where A is a divalent organic group including an aliphatic tertiary or quaternary carbon atom, and M is a divalent organic group},

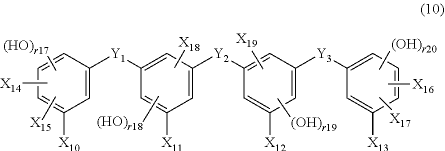

{where r17, r18, r19 and r20 are each independently an integer of 0 to 2, at least one of r17, r18, r19 and r20 being 1 or 2, X₁₀ to X₁₉ are each independently a hydrogen atom, a halogen atom or at least one monovalent group selected from the group consisting of alkyl, alkenyl, alkoxy, allyl and acyl groups, and Y₁ to Y₃ are each independently a single bond, or at least one divalent group selected from the group consisting of —O—, —S—, —SO—, —SO₂—, —CO—, —CO₂—, cyclopentylidene, cyclohexylidene, phenylene and divalent organic groups of 1 to 20 carbon atoms}.
[41]

The prebaked film according to any one of [31] to [40] above, wherein the exposure ray absorber is a 1,2-naphthoquinonediazide-5-sulfonic acid ester of at least one hydroxy compound selected from the group consisting of formulas (6) to (10).

[42]

The prebaked film according to any one of [31] to [41] above, wherein the esterification rate of the exposure ray absorber is 80% or greater.

[43]

The prebaked film according to any one of [31] to [42] above, wherein the hydroxy compound represented by general formula (6) above is represented by the following general formula (11):

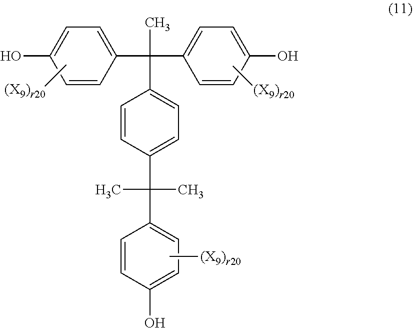

{where each r20 is independently an integer of 0 to 2, and each X₉ is independently a hydrogen atom or a monovalent organic group of 1 to 20 carbon atoms}.

### Advantageous Effects of Invention

According to the present disclosure it is possible to provide a method for producing a PI precursor resin composition with excellent resolvability, a wide range of usable exposure doses, and excellent handleability.

### BRIEF DESCRIPTION OF DRAWINGS

FIG. 1 is an FIB photograph of the pattern cross-sectional shape obtained in Example 1.

FIG. 2 is a sensitivity curve plotting normalized film thickness for different exposure doses on the relief pattern obtained in Example 50.

### DESCRIPTION OF EMBODIMENTS

### <Method for Producing PI Precursor Resin Composition>

The method for producing a PI precursor resin composition according to the disclosure is a method for producing a PI precursor resin composition that includes (A) a polyimide (PI) precursor resin, (B) an exposure ray absorber, (C) a photopolymerization initiator and (D) a solvent, wherein the method includes a step in which the type of light to be used for exposure is specified; a material selection step in which the polyimide precursor resin, the exposure ray absorber and the photopolymerization initiator are selected; a content deciding step in which mass fraction α of the exposure ray absorber to be added and mass fraction β of the photopolymerization initiator to be added are decided; and a step in which a PI precursor resin composition is prepared.

### <Light Type Specifying Step>

In the light type specifying step, the type of light for exposure of the PI precursor resin composition is specified. The type of light may be any type of light that can crosslink the polymerizable groups of the polyimide precursor resin by the action of the photopolymerization initiator when the PI precursor resin composition is exposed, thus insolubilizing it in the developing solution. For example, the type of light may be g-line (436 nm), h-line (405 nm), i-line (365 nm wavelength) or KrF excimer laser (248 nm wavelength), with i-line being preferred from the viewpoint of insolubilization and resolvability of the polyimide precursor resin.

### <Material Selection Step>

In the material selection step, the (A) polyimide precursor resin, (B) exposure ray absorber and (C) photopolymerization initiator are selected corresponding to the absorbance parameters for the selected type of light. The (D) solvent may be arbitrarily selected regardless of the selected type of light. Other materials such as (E) a photopolymerizable compound or thermal base generator, (H) a nitrogen-containing heterocyclic rust inhibitor, (F) a hindered phenol compound, organic titanium compound, adhesion aid or sensitizing agent, or (G) a polymerization inhibitor, as well as combinations thereof, may also be selected regardless of the selected type of light. Other materials including (E), (F) and (G) may likewise be arbitrarily selected, regardless of the selected type of light.

### Selection of Polyimide Precursor Resin (A)

The polyimide precursor resin is a resin component in the negative-type photosensitive resin composition, which is converted to polyimide by thermal cyclization treatment. The polyimide precursor resin is selected from among resins having an absorbance parameter Xp in the range of 0.001 to 0.20 for the specified type of light. The absorbance of the polyimide precursor resin can be measured with an ultraviolet and visible spectrophotometer using a 1 cm cell, and with the polyimide precursor resin prepared to 1000 mg/L using N-methyl-2-pyrrolidone as the solvent. The obtained value of the absorbance at 365 nm divided by 10 is defined as the absorbance parameter Xp of the polyimide precursor resin. The polyimide precursor resin is selected from among resins having an absorbance parameter Xp in the range of preferably 0.001 to 0.15, more preferably 0.005 to 0.10 and even more preferably 0.005 to 0.05. The structure of the polyimide precursor resin is not limited so long as it is a polyimide precursor resin that can be used in a negative-type photosensitive resin composition, but it is preferably not alkali-soluble. Avoiding alkali solubility of the polyimide precursor resin will allow high chemical resistance to be obtained. When the negative-type photosensitive resin composition comprises two or more polyimide precursor resins, the absorbance parameter Xp for the specified type of light may be in the range of 0.001 to 0.20 for the mixture of the two or more polyimide precursor resins. Preferably, all of the two or more polyimide precursor resins are selected so that their absorbance parameter Xp is in the range of 0.001 to 0.20 for the specified type of light.

The polyimide precursor resin is preferably a polyamide having the structure represented by the following general formula (1).

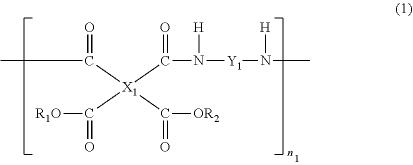

{In formula (1), X₁ is a tetravalent organic group, Y₁ is a divalent organic group, n₁ is an integer of 2 to 150, and R₁ and R₂ are each independently a hydrogen atom or a monovalent organic group.}

In general formula (1), preferably either or both of R₁ and R₂ have a structural unit represented by the following general formula (2):

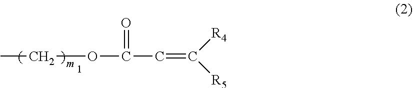

{where R₃, R₄ and R₅ are each independently a hydrogen atom or a monovalent organic group of 1 to 3 carbon atoms, and mi is an integer of 2 to 10}.

The proportion of R₁ and R₂ that are hydrogen atoms in general formula (1) is preferably 20% or less, more preferably 15% or less and even more preferably 5% or less, based on the entire number of moles of R₁ and R₂. The proportion of R₁ and R₂ in general formula (1) that are monovalent organic groups represented by general formula (2) is preferably 70% or greater, more preferably 80% or greater and even more preferably 90% or greater, based on the entire number of moles of R₁ and R₂. The proportion of hydrogen atoms and the proportion of organic groups of general formula (2) are preferably within these ranges from the viewpoint of photosensitivity and storage stability.

The value of n₁ in general formula (1) is not restricted so long as it is an integer of 2 to 150, but it is preferably an integer of 3 to 100 and more preferably an integer of 5 to 70 from the viewpoint of the photosensitivity and mechanical properties of the negative-type photosensitive resin composition.

In general formula (1), the tetravalent organic group represented by X₁ is preferably an organic group of 6 to 40 carbon atoms and more preferably an aromatic group or alicyclic aliphatic group with a —COOR₁ group and —COOR₂ group in mutual ortho positions with a —CONH— group, from the viewpoint of achieving both heat resistance and photosensitivity. The tetravalent organic group represented by X₁ may be, specifically, an organic group of 6 to 40 carbon atoms containing an aromatic ring, such as a group having a structure selected from the group consisting of those in the following general formula (I):

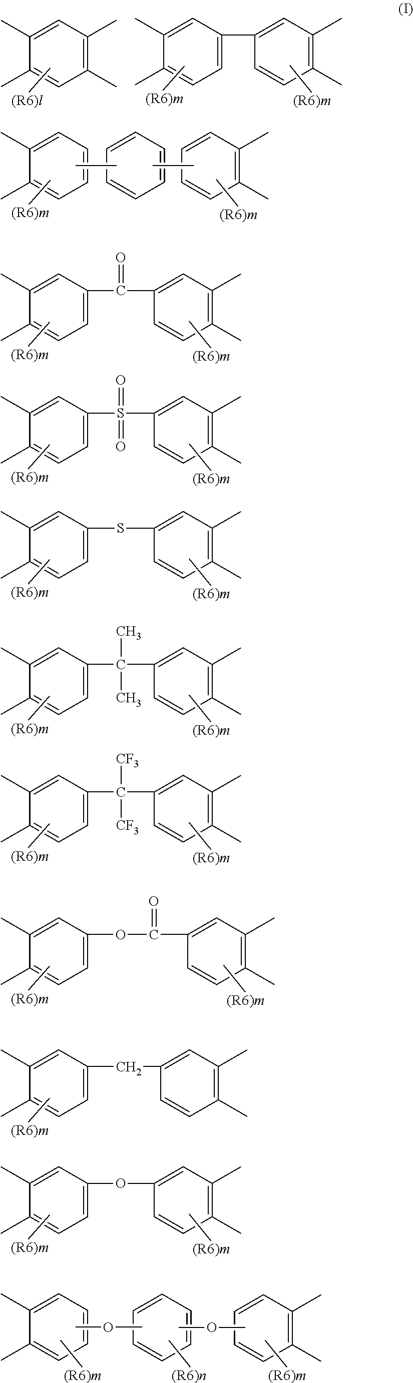

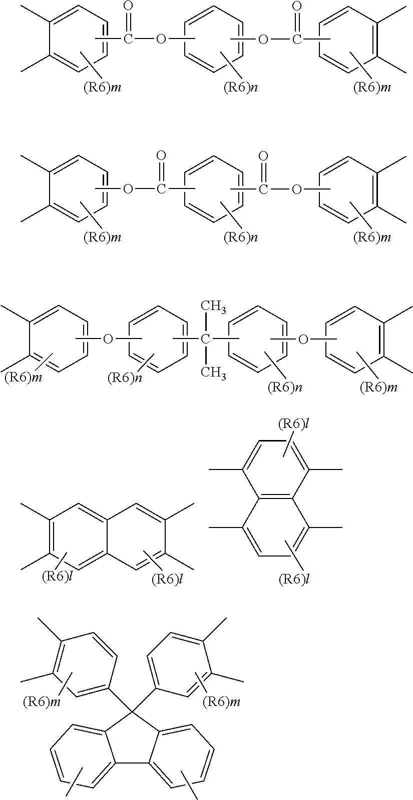

{where R₆ is at least one selected from the group consisting of hydrogen atoms, fluorine atoms, C₁ to C₁₀ monovalent hydrocarbon groups and C₁ to C₁₀ monovalent fluorinated hydrocarbon groups, 1 is an integer selected from among 0 to 2, m is an integer selected from among 0 to 3, and n is an integer selected from among 0 to 4},
with no limitation to these. The structure of X₁ may be one single type or a combination of two or more types. X₁ groups having the structures represented by formula (I) above are particularly preferred from the viewpoint of both heat resistance and photosensitivity.

Most preferred from among the structures represented by formula (I) for X₁ groups are those including a tetravalent organic group, represented by the following formulas:

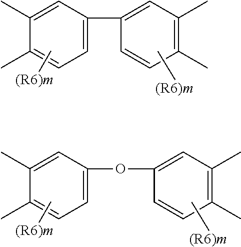

{where R₆ is at least one selected from the group consisting of fluorine atoms, monovalent hydrocarbon groups of 1 to 10 carbon atoms and monovalent fluorinated hydrocarbon groups of 1 to 10 carbon atoms, and m is an integer selected from among 0 to 3}. If the polyimide precursor resin has such a structure it will be possible to improve the heat resistance and resolution.

From the viewpoint of both heat resistance and photosensitivity, the divalent organic group represented by Y₁ in general formula (1) is preferably an aromatic group of 6 to 40 carbon atoms, and for example, it may be a structure represented by the following formula (II):

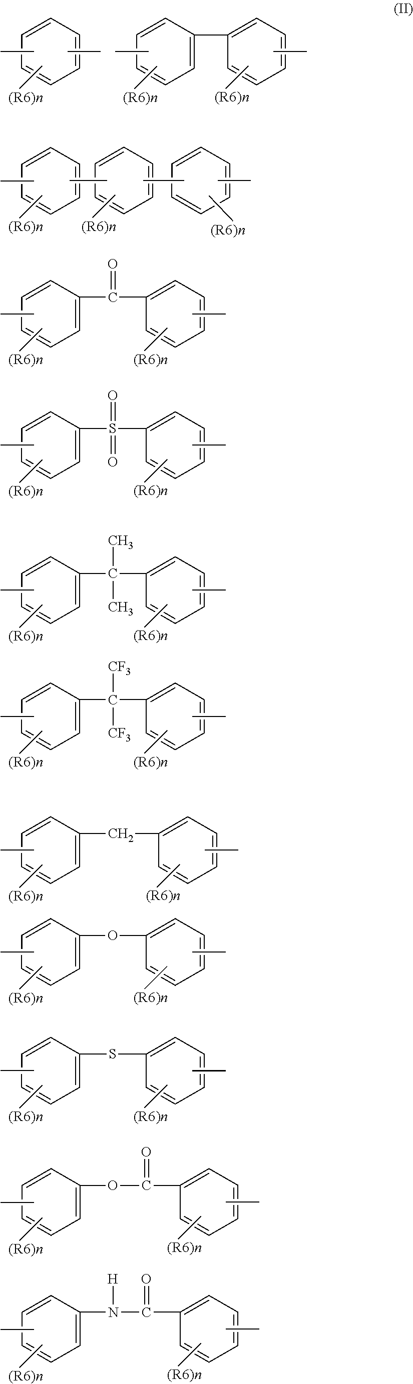

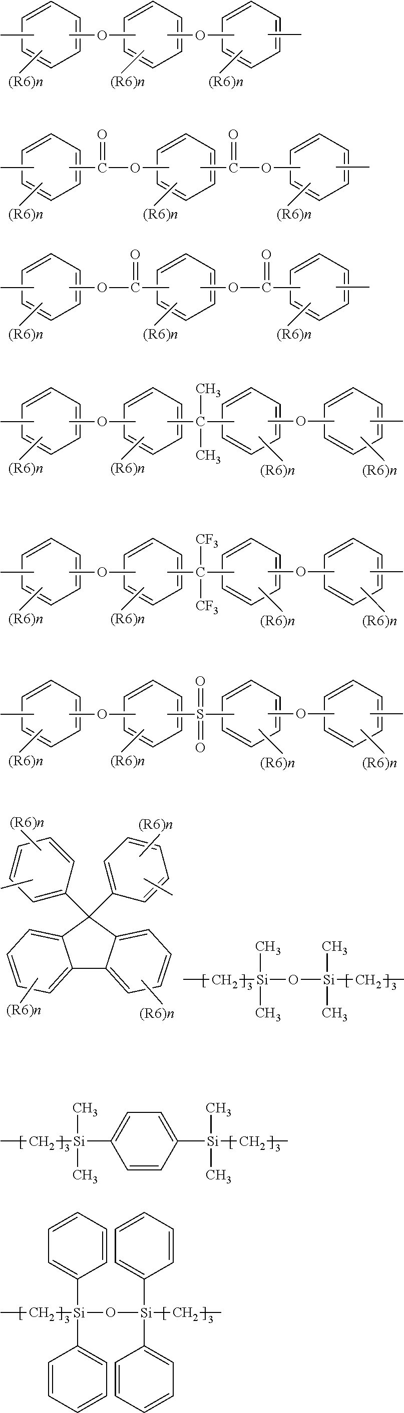

{where R₆ is at least one selected from the group consisting of hydrogen atoms, fluorine atoms, C₁ to C₁₀ monovalent hydrocarbon groups and C₁ to C₁₀ monovalent fluorinated hydrocarbon groups, and n is an integer selected from among 0 to 4}, with no limitation to these. The structure of Y₁ may be one single type or a combination of two or more types. Y₁ groups having the structures represented by formula (II) above are particularly preferred from the viewpoint of both heat resistance and photosensitivity.

Most preferred from among the structures represented by formula (II) for Y₁ groups are divalent groups represented by the following formulas:

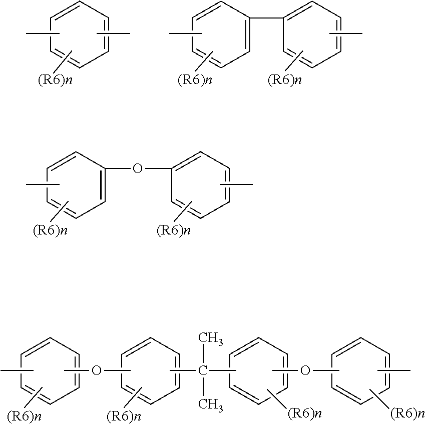

{where R₆ is at least one selected from the group consisting of fluorine atoms, monovalent hydrocarbon groups of 1 to 10 carbon atoms and monovalent fluorinated hydrocarbon groups of 1 to 10 carbon atoms, and n is an integer selected from among 0 to 4}, from the viewpoint of heat resistance, chemical resistance and resolution.

Among the structures represented by formula (II), Y₁ groups are more preferably divalent groups represented by the following formula (3):

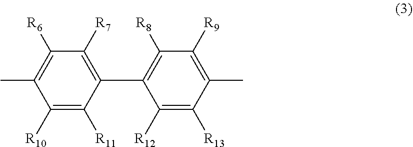

{where R₆ to R₁₃ are each independently a hydrogen atom, a fluorine atom or a monovalent organic group, with at least one of R₆ to R₁₃ being a methyl, trifluoromethyl or methoxy group}. If the polyimide precursor resin has such a rigid structure it will be possible to inhibit swelling of the film during development and to exhibit very high resolution.

Even more preferred among the structures represented by formula (II) for Y₁ groups are divalent groups represented by the following formula (4):

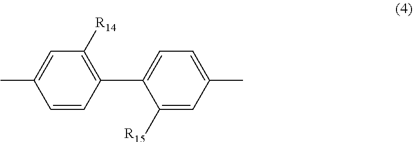

{where R₁₄ and R₁₅ are each independently a methyl, trifluoromethyl or methoxy group}. If the polyimide precursor resin has such a rigid structure it will be possible to inhibit swelling of the film during development and to exhibit very high resolution.

### Method for Preparing Polyimide Precursor Resin (A)

The polyimide precursor resin is first reacted with a tetracarboxylic dianhydride including the tetravalent organic group X₁, an alcohol having a photopolymerizable unsaturated double bond, and optionally with an alcohol without an unsaturated double bond, to prepare a partially esterified tetracarboxylic acid (hereunder also referred to as “acid/ester”). The partially esterified tetracarboxylic acid may then be subjected to amide polycondensation with a diamine that includes the divalent organic group Y₁ to obtain the product.

### (Preparation of Acid/Ester)

Tetracarboxylic dianhydrides including a tetravalent organic group X₁, that may be suitably used to prepare a polyimide precursor resin include, but are not limited to, tetracarboxylic dianhydrides having the structures shown in general formula (I), as well as, for example, pyromellitic anhydride, diphenyl ether-3,3′,4,4′-tetracarboxylic dianhydride, benzophenone-3,3′,4,4′-tetracarboxylic dianhydride, biphenyl-3,3′,4,4′-tetracarboxylic dianhydride, diphenylsulfone-3,3′,4,4′-tetracarboxylic dianhydride, diphenylmethane-3,3′,4,4′-tetracarboxylic dianhydride, 2,2-bis(3,4-phthalic anhydride)propane and 2,2-bis(3,4-phthalic anhydride)-1,1,1,3,3,3-hexafluoropropane, and preferably pyromellitic anhydride, diphenyl ether-3,3′,4,4′-tetracarboxylic dianhydride, benzophenone-3,3′,4,4′-tetracarboxylic dianhydride and biphenyl-3,3′,4,4′-tetracarboxylic dianhydride. These may be used alone, or two or more may be used in admixture.

Examples of alcohols having a photopolymerizable unsaturated double bond, that may be suitably used to prepare a polyimide precursor resin, include 2-acryloyloxyethyl alcohol, 1-acryloyloxy-3-propyl alcohol, 2-acrylamide ethyl alcohol, methylolvinyl ketone, 2-hydroxyethylvinyl ketone, 2-hydroxy-3-methoxypropyl acrylate, 2-hydroxy-3-butoxypropyl acrylate, 2-hydroxy-3-phenoxypropyl acrylate, 2-hydroxy-3-butoxypropyl acrylate, 2-hydroxy-3-t-butoxypropyl acrylate, 2-hydroxy-3-cyclohexyloxypropyl acrylate, 2-methacryloyloxyethyl alcohol, 1-methacryloyloxy-3-propyl alcohol, 2-methacrylamide ethyl alcohol, methylolvinyl ketone, 2-hydroxyethylvinyl ketone, 2-hydroxy-3-methoxypropyl methacrylate, 2-hydroxy-3-butoxypropyl methacrylate, 2-hydroxy-3-phenoxypropyl methacrylate, 2-hydroxy-3-butoxypropyl methacrylate, 2-hydroxy-3-t-butoxypropyl methacrylate and 2-hydroxy-3-cyclohexyloxypropyl methacrylate.

These examples of alcohols having a photopolymerizable unsaturated double bond may also be used in admixture with alcohols without unsaturated double bonds, such as methanol, ethanol, n-propanol, isopropanol, n-butanol, tert-butanol, 1-pentanol, 2-pentanol, 3-pentanol, neopentyl alcohol, 1-heptanol, 2-heptanol, 3-heptanol, 1-octanol, 2-octanol, 3-octanol, 1-nonanol, triethyleneglycol monomethyl ether, triethyleneglycol monoethyl ether, tetraethyleneglycol monomethyl ether, tetraethyleneglycol monoethyl ether and benzyl alcohol.

The polyimide precursor resin may also be a mixture of a photosensitive polyimide precursor resin with a non-photosensitive polyimide precursor resin prepared only with an alcohol lacking the aforementioned unsaturated double bond. From the viewpoint of resolution, the non-photosensitive polyimide precursor resin is preferably used at 200 parts by mass or lower based on 100 parts by mass of the photosensitive polyimide precursor.

The tetracarboxylic dianhydride and alcohol may also be stirred, dissolved and mixed in a solvent in the presence of a basic catalyst such as pyridine, to promote esterification reaction of the acid anhydride and obtain the desired acid/ester. The stirring, dissolution and mixing are preferably carried out for 4 to 24 hours at a temperature of 20 to 50° C., for example.

### (Preparation of Polyimide Precursor Resin)

An appropriate dehydrating condensation agent such as dicyclohexylcarbodiimide, 1-ethoxycarbonyl-2-ethoxy-1,2-dihydroquinoline, 1,1-carbonyldioxy-di-1,2,3-benzotriazole or N,N′-disuccinimidyl carbonate may be loaded into and mixed with the acid/ester (typically as a solution in the solvent described below), while cooling on ice, to convert the acid/ester to a polyacid anhydride. Next, a solution or dispersion of a diamine containing a divalent organic group Y₁ in a separate solvent may be added dropwise into the obtained polyacid anhydride of the acid/ester, and amide polycondensation carried out to obtain the polyimide precursor resin. Alternatively, the acid/ester thionyl chloride, for example, may be used to convert the acid portion to an acid chloride, and then reaction may be carried out with a diamine compound in the presence of a base such as pyridine, to obtain the polyimide precursor resin.

As a different synthesis method, a tetracarboxylic dianhydride and a diamine compound may be reacted beforehand to obtain a polyamic acid, and then a suitable dehydrating condensation agent such as trifluoroacetic anhydride may be used for introduction of the aforementioned alcohol into the carboxylic acid portion of a side chain of the obtained polyamic acid, to obtain the polyimide precursor resin.

Examples of diamines having a divalent organic group Y₁ include, but are not limited to, diamines having the structure represented by general formula (II) above, as well as p-phenylenediamine, m-phenylenediamine, 4,4-diaminodiphenyl ether, 3,4′-diaminodiphenyl ether, 3,3′-diaminodiphenyl ether, 4,4′-diaminodiphenyl sulfide, 3,4′-diaminodiphenyl sulfide, 3,3′-diaminodiphenyl sulfide, 4,4′-diaminodiphenylsulfone, 3,4′-diaminodiphenylsulfone, 3,3′-diaminodiphenylsulfone, 4,4′-diaminobiphenyl, 3,4′-diaminobiphenyl, 3,3′-diaminobiphenyl, 4,4′-diaminobenzophenone, 3,4′-diaminobenzophenone, 3,3′-diaminobenzophenone, 4,4′-diaminodiphenylmethane, 3,4′-diaminodiphenylmethane, 3,3′-diaminodiphenylmethane, 1,4-bis(4-aminophenoxy)benzene, 1,3-bis(4-aminophenoxy)benzene, 1,3-bis(3-aminophenoxy)benzene, bis[4-(4-aminophenoxy)phenyl]sulfone, bis[4-(3-aminophenoxy)phenyl]sulfone, 4,4-bis(4-aminophenoxy)biphenyl, 4,4-bis(3-aminophenoxy)biphenyl, bis[4-(4-aminophenoxy)phenyl]ether, bis[4-(3-aminophenoxy)phenyl]ether, 1,4-bis(4-aminophenyl)benzene, 1,3-bis(4-aminophenyl)benzene, 9,10-bis(4-aminophenyl)anthracene, 2,2-bis(4-aminophenyl)propane, 2,2-bis(4-aminophenyl)hexafluoropropane, 2,2-bis[4-(4-aminophenoxy)phenyl]propane, 2,2-bis[4-(4-aminophenoxy)phenyl]hexafluoropropane, 1,4-bis(3-aminopropyldimethylsilyl)benzene, ortho-tolidinesulfone and 9,9-bis(4-aminophenyl)fluorene; and those compounds having some of the hydrogens on the benzene ring replaced by methyl, ethyl, hydroxymethyl or hydroxyethyl groups or halogen atoms, such as 3,3′-dimethyl-4,4′-diaminobiphenyl, 2,2′-dimethyl-4,4′-diaminobiphenyl, 3,3′-dimethyl-4,4′-diaminodiphenylmethane, 2,2′-dimethyl-4,4′-diaminodiphenylmethane, 3,3′-dimethoxy-4,4′-diaminobiphenyl and 3,3′-dichloro-4,4′-diaminobiphenyl; and mixtures of the same.

After completion of the amide polycondensation reaction, the by-products of water absorption with the dehydrating condensation agent copresent in the reaction mixture are filtered, if necessary. Next, water, an aliphatic lower alcohol or a poor solvent for the liquid mixture is loaded into the obtained polymer component and the polymer component is separated out. The polymer is purified by further repeating the redissolution and the reprecipitation and separation procedures, and is then vacuum dried to isolate the desired polyimide precursor resin. In order to increase the purity, a solution of the polymer may be passed through a column packed with an anion- and/or cation-exchange resin that has been swelled with an appropriate organic solvent, to remove the ionic impurities.

The molecular weight of the polyimide precursor resin is preferably 8,000 to 150,000 and more preferably 9,000 to 50,000, as the measured weight-average molecular weight in terms of polystyrene by gel permeation chromatography. If the weight-average molecular weight is 8,000 or greater the mechanical properties will be satisfactory, and if it is 150,000 or lower the dispersibility in the developing solution will be satisfactory and the resolvability of the relief pattern will be satisfactory. The developing solvents for gel permeation chromatography are preferably tetrahydrofuran and N-methyl-2-pyrrolidone. The weight-average molecular weight is determined from a calibration curve drawn using standard monodisperse polystyrene. It is preferred to select standard monodisperse polystyrene from among the organic solvent-based reference samples STANDARD SM-105 by Showa Denko K.K.

### Selection of Exposure Ray Absorber (B)

The exposure ray absorber is selected from among materials having an absorbance parameter Xt in the range of 0.01 to 0.05 for the specified type of light. A parameter in this range will allow the absorbance of the film to be strictly adjusted within a suitable range of addition. If the absorbance parameter Xt is smaller than 0.01, a large amount of addition will be necessary to adjust the absorbance, and side-effects may occur, such as precipitation of the exposure ray absorber or interference with other performance. If the absorbance parameter Xt is larger than 0.05, on the other hand, the film absorbance will vary drastically with small amounts of addition, making it difficult to achieve strict adjustment. The absorbance of the exposure ray absorber can be measured with an ultraviolet and visible spectrophotometer using a 1 cm cell, and with the exposure ray absorber prepared to 10 mg/L using N-methyl-2-pyrrolidone as the solvent. The obtained value of the absorbance at 365 nm divided by 10 is defined as the absorbance parameter Xt of the exposure ray absorber. The exposure ray absorber is selected from among materials having an absorbance parameter Xt in the range of preferably 0.015 to 0.040, more preferably 0.015 to 0.03 and even more preferably 0.015 to 0.025. When the negative-type photosensitive resin composition comprises two or more exposure ray absorbers, the absorbance parameter Xt for the specified type of light may be in the range of 0.01 to 0.05 for the mixture of the two or more exposure ray absorbers. Preferably, all of the two or more exposure ray absorbers are selected so that their absorbance parameter Xt is in the range of 0.01 to 0.05 for the specified type of light.

The exposure ray absorber is preferably at least one compound selected from the group consisting of 2-(2′-hydroxyphenyl)benzotriazole-based compounds, hydroxyphenyltriazine-based compounds, 2-hydroxybenzophenone-based compounds, cyanoacrylate-based compounds, azobenzene-based compounds, polyphenol-based compounds and compounds with quinoneazide groups. Specific examples of exposure ray absorbers include 2-(2′-hydroxyphenyl)benzotriazole-based compounds such as 2-(2′-hydroxy-5′-methylphenyl)benzotriazole, 2-(2′-hydroxy-3′-tert-butyl-5′-methylphenyl)-5-chlorobenzotriazole, 2,2′-methylenebis[6-(2H-benzotriazol-2-yl)-4-tert-octylphenol], 2-(2′-hydroxy-5′-tert-octylphenyl)benzotriazole, 6-(2-benzotriazolyl)-4-tert-octyl-6′-tert-butyl-4′-methyl-2,2′-methylenebisphenol, 2-(2′-hydroxy-3′, 5′-di-tert-amylphenyl)benzotriazole, 2-[2-hydroxy-3,5-bis(α, α-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole and 2-(3,5-di-t-amyl-2-hydroxyphenyl)benzotriazole;
hydroxyphenyltriazine-based compounds such as 2,4-bis(2,4-dimethylphenyl)-6-(2-hydroxy-4-n-octyloxyphenyl)-1,3,5-triazine, 2-(2,4-dihydroxyphenyl)-4,6-bis(2,4-dimethylphenyl)-1,3,5-triazine, 2,4,6-tris(4-butoxy-2-hydroxyphenyl)-1,3,5-triazine, 2-(2-hydroxy-4-methoxyphenyl)-4,6-diphenyl-1,3,5-triazine, 2-(2,4-dihydroxyphenyl)-4,6-diphenyl-1,3,5-triazine, bemotrizinol and 2,4,6-tris(2,4-dihydroxyphenyl)-1,3,5-triazine; 2-hydroxybenzophenone-based compounds such as 2-hydroxy-4-octyloxybenzophenone, 2,2′, 4,4′-tetrahydroxybenzophenone and 2-hydroxy-4-methoxybenzophenone-5-sulfonic acid hydrate; and
polyphenol-based compounds such as cyanoacrylate-based compounds, azobenzene-based compounds, catechins, rutins, cyanidin and curcumin, and quinoneazide group-containing compounds (hereunder also referred to as “quinonediazide compounds”).

Among these, the exposure ray absorber is preferably a quinonediazide compound from the viewpoint of resolvability. Examples of quinonediazide compounds include compounds with 1,2-benzoquinonediazide structures and compounds with 1,2-naphthoquinonediazide structures, which are publicly known substances from U.S. Pat. Nos. 2,772,972, 2,797,213 and 3,669,658. From the viewpoint of resolvability and the cross-sectional shape of the pattern that is formed, these quinonediazide compounds are more preferably one or more types of compounds selected from the group consisting of 1,2-naphthoquinonediazide-4-sulfonic acid esters of polyhydroxy compounds and 1,2-naphthoquinonediazide-5-sulfonic acid esters of the polyhydroxy compounds, having the specific structures described below (hereunder also referred to as “NQD compounds”). Without being limited to any particular theory, the reason for this is thought to be that NQD compounds that have absorbed exposure rays undergo rearrangement reaction within the molecules, losing their photoabsorption ability, thus allowing appropriate adjustment of the amount reaching the film bottom layer. The satisfactory solubility of NQD compounds in solvents compared to other exposure ray absorbers is one of their excellent characteristics. This allows the absorbance of the coated film to be adjusted by addition of large amounts of NQD compounds, even when using polyimide precursor resins with low absorbance of exposure rays or when small film thicknesses are used.

An NQD compound can be obtained by converting a naphthoquinonediazidesulfonic acid compound to a sulfonyl chloride using chlorsulfonic acid or thionyl chloride by a common method, and conducting condensation reaction of the resulting naphthoquinonediazidesulfonyl chloride with a polyhydroxy compound. For example, prescribed amounts of a polyhydroxy compound and 1,2-naphthoquinonediazide-5-sulfonyl chloride or 1,2-naphthoquinonediazide-4-sulfonyl chloride may be reacted in a solvent such as dioxane, acetone or tetrahydrofuran in the presence of a basic catalyst such as triethylamine for esterification, and the obtained product may be washed and dried.

A compound having a quinonediazide group is preferably a 1,2-naphthoquinonediazide-4-sulfonic acid ester and/or a 1,2-naphthoquinonediazide-5-sulfonic acid ester compound of one or more hydroxy compounds selected from the group consisting of the following general formulas (6) to (10).

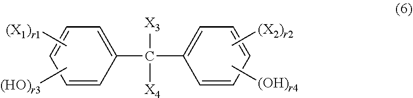

{In formula (6), X₁ and X₂ are each independently a hydrogen atom or a monovalent organic group of 1 to 60 carbon atoms and preferably 1 to 30 carbon atoms, X₃ and X₄ are each independently a hydrogen atom or a monovalent organic group of 1 to 60 carbon atoms and preferably 1 to 30 carbon atoms, and r1, r2, r3 and r4 are each independently an integer of 0 to 5, with at least one of r3 and r4 being an integer of 1 to 5, and satisfying r1+r3=5 and r2+r4=5.}

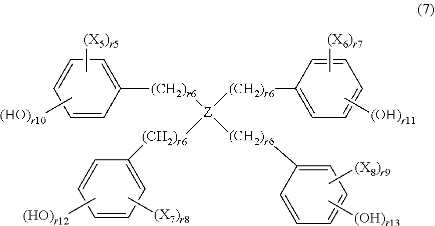

{In formula (7), Z represents a tetravalent organic group of 1 to 20 carbon atoms, X₅, X₆, X₇ and X₈ are each independently a monovalent organic group of 1 to 30 carbon atoms, r6 is an integer of 0 or 1, r5, r7, r8 and r9 are each independently an integer of 0 to 3, and r10, r11, r12 and r13 are each independently an integer of 0 to 2, with at least one of r10, r11, r12 and r13 being 1 or 2.}

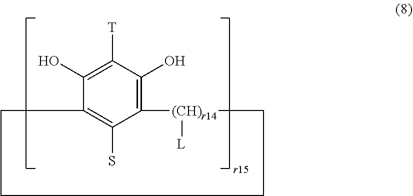

{In formula (8), r14 represents an integer of 1 to 5, r15 represents an integer of 3 to 8, the L groups in the number of r14×r15 are each independently a monovalent organic group of 1 to 20 carbon atoms, the T groups in the number of r15 are each independently a hydrogen atom or a monovalent organic group of 1 to 20 carbon atoms, and the S groups in the number of r5 are each independently a hydrogen atom or a monovalent organic group of 1 to 20 carbon atoms.}

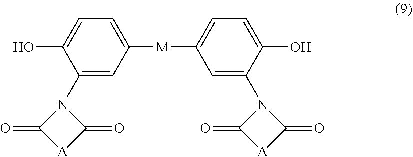

{In formula (9), A is a divalent organic group including an aliphatic tertiary or quaternary carbon atom, and M is a divalent organic group.}

In formula (9), A is preferably at least one divalent group selected from among the three groups represented by the following chemical formulas:

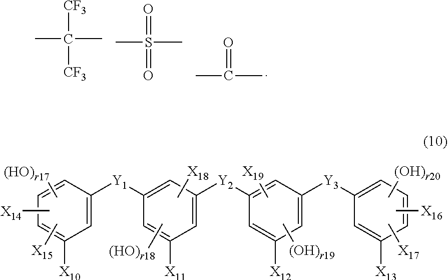

{In formula (10), r17, r18, r19 and r20 are each independently an integer of 0 to 2, with at least one of r17, r18, r19 and r20 being 1 or 2, X₁₀ to X₁₉ are each independently a hydrogen atom, a halogen atom or at least one monovalent group selected from the group consisting of alkyl, alkenyl, alkoxy, allyl and acyl groups, and Y₁ to Y₃ are each independently a single bond, or at least one divalent group selected from the group consisting of —O—, —S—, —SO—, —SO₂—, —CO—, —CO₂—, cyclopentylidene, cyclohexylidene, phenylene and divalent organic groups of 1 to 20 carbon atoms.}

In general formula (10), preferably Y₁ to Y₃ are each independently one or more selected from among the three divalent organic groups represented by the following general formula:

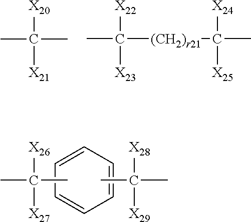

{where X₂₀ and X₂₁ are each independently a hydrogen atom or at least one monovalent group selected from the group consisting of alkyl, alkenyl, aryl and substituted aryl groups, X₂₂, X₂₃, X₂₄ and X₂₅ are each independently a hydrogen atom or an alkyl group, r21 is an integer of 1 to 5, and X₂₆, X₂₇, X₂₈ and X₂₉ are each independently a hydrogen atom or an alkyl group}.

A compound represented by general formula (6) is preferably a hydroxy compound represented by the following formula (11) or (17) to (20), and more preferably a hydroxy compound represented by formula (11).

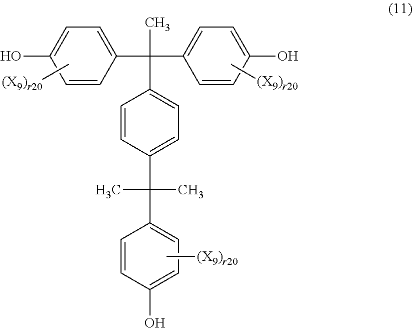

{In formula (11), each r20 is independently an integer of 0 to 2, and each X₉ is independently a hydrogen atom or a monovalent organic group of 1 to 20 carbon atoms. When multiple X₉ groups are present, the multiple X₉ groups may be the same or different.

In formula (11), X₉ is preferably a monovalent organic group represented by the following chemical formula:

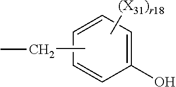

{where r18 is an integer of 0 to 2, X₃₁ is a hydrogen atom or at least one monovalent organic group selected from the group consisting of alkyl and cycloalkyl groups, and when two r18 groups are present, the two X₃₁ groups may be the same or different}.

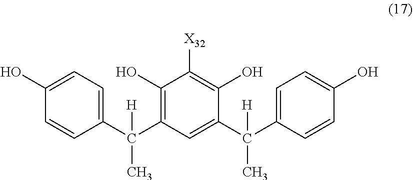

{In formula (17), X₃₂ is a hydrogen atom or at least one monovalent organic group selected from the group consisting of alkyl groups of 1 to 20 carbon atoms, alkoxy groups of 1 to 20 carbon atoms and cycloalkyl groups of 1 to 20 carbon atoms.}

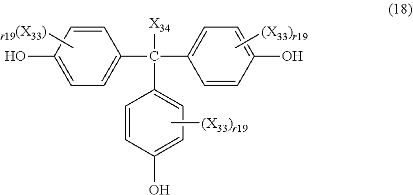

{In formula (18), each r19 is independently an integer of 0 to 2, each X₃₃ is independently a hydrogen atom or a monovalent organic group represented by the following general formula:

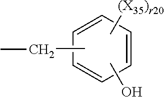

(where r20 is an integer of 0 to 2, X₃₅ is a hydrogen atom or at least one group selected from the group consisting of alkyl and cycloalkyl groups, and when two r20 groups are present, the two X₃₅ groups may be the same or different), and X₃₄ is a hydrogen atom or at least one group selected from the group consisting of alkyl groups of 1 to 20 carbon atoms and cycloalkyl groups of 1 to 20 carbon atoms.}

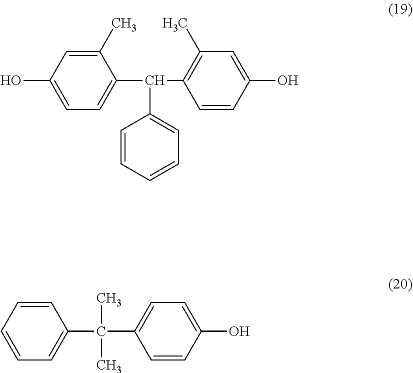 [SMILES: Cc1cc(O)ccc1C(c1ccccc1)c1ccc(O)cc1C ; CC(C)(c1ccccc1)c1ccc(O)cc1]

The compound represented by formula (20) above is p-cumylphenol.

Compounds represented by formula (11) are preferably hydroxy compounds represented by the following formulas (21) to (23) because they have high sensitivity as NQD compounds and low deposition in the PI precursor resin composition (the NQD compounds of polyhydroxy compounds described in Japanese Unexamined Patent Publication No. 2004-109849).

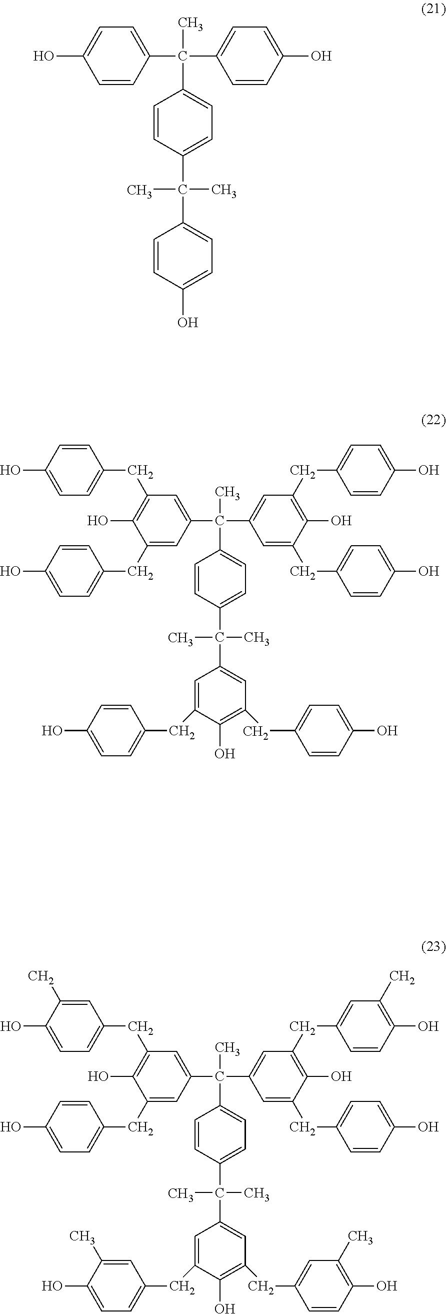 [SMILES: CC(C)(c1ccc(O)cc1)c1ccc(C(C)(c2ccc(O)cc2)c2ccc(O)cc2)cc1 ; CC(C)(c1ccc(C(C)(c2cc(Cc3ccc(O)cc3)c(O)c(Cc3ccc(O)cc3)c2)c2cc(Cc3ccc(O)cc3)c(O)c(Cc3ccc(O)cc3)c2)cc1)c1cc(Cc2ccc(O)cc2)c(O)c(Cc2ccc(O)cc2)c1 ; Cc1cc(Cc2cc(C(C)(C)c3ccc(C(C)(c4cc(Cc5ccc(O)cc5)c(O)c(Cc5ccc(O)c(C)c5)c4)c4cc(Cc5ccc(O)cc5)c(O)c(Cc5ccc(O)c(C)c5)c4)cc3)cc(Cc3ccc(O)c(C)c3)c2O)ccc1O]

Compounds represented by formula (17) are preferably hydroxy compounds represented by the following formula (24) because they have high sensitivity as NQD compounds and low deposition in the PI precursor resin composition (the NQD compounds of polyhydroxy compounds described in Japanese Unexamined Patent Publication No. 2001-356475).

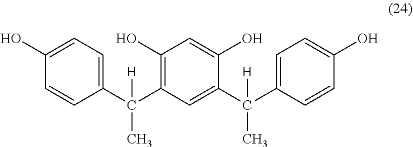 [SMILES: CC(c1ccc(O)cc1)c1cc(C(C)c2ccc(O)cc2)c(O)cc1O]

Compounds represented by formula (18) are preferably hydroxy compounds represented by the following formulas (25) to (27) because they have high sensitivity as NQD compounds and low deposition in the PI precursor resin composition (the NQD compounds of polyhydroxy compounds described in Japanese Unexamined Patent Publication No. 2005-8626).

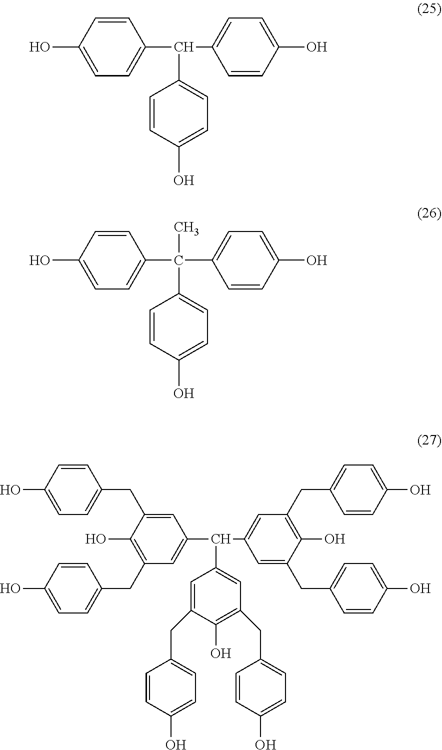 [SMILES: Oc1ccc(C(c2ccc(O)cc2)c2ccc(O)cc2)cc1 ; CC(c1ccc(O)cc1)(c1ccc(O)cc1)c1ccc(O)cc1 ; Oc1ccc(Cc2cc(C(c3cc(Cc4ccc(O)cc4)c(O)c(Cc4ccc(O)cc4)c3)c3cc(Cc4ccc(O)cc4)c(O)c(Cc4ccc(O)cc4)c3)cc(Cc3ccc(O)cc3)c2O)cc1]

In general formula (7), Z is not particularly restricted so long as it is a tetravalent organic group of 1 to 20 carbon atoms, but it is preferably a tetravalent group having a structure represented by the following formula:

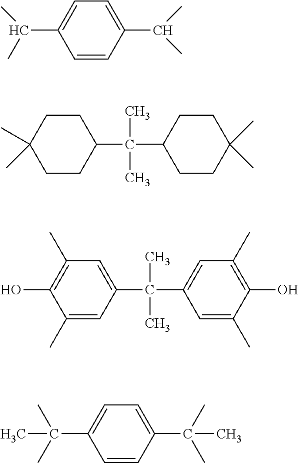

from the viewpoint of sensitivity.

Among compounds represented by formula (7), hydroxy compounds represented by the following formulas (28) to (31) are preferred because they have high sensitivity as NQD compounds and low deposition in the PI precursor resin composition (the NQD compounds of polyhydroxy compounds described in Japanese Unexamined Patent Publication No. 2001-92138).

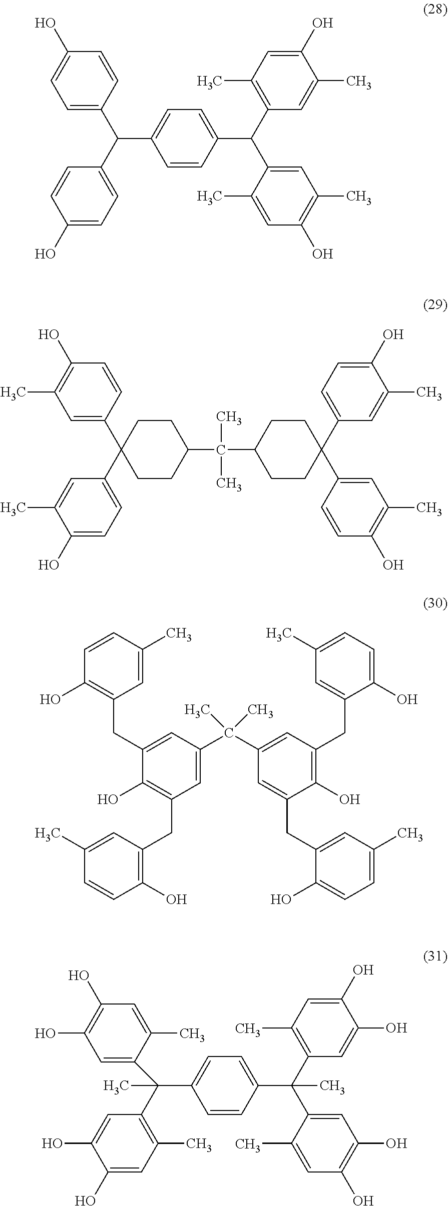

Compounds represented by formula (8) are preferably hydroxy compounds represented by the following formula (32) because they have high sensitivity as NQD compounds and low deposition in the PI precursor resin composition (the NQD compounds of polyhydroxy compounds described in Japanese Unexamined Patent Publication No. 2004-347902).

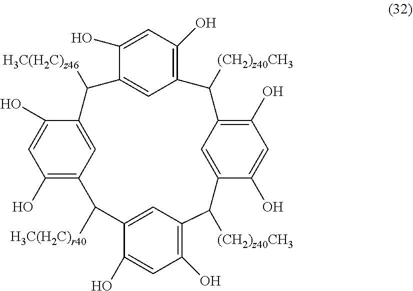

{In the formula, each r40 is independently an integer of 0 to 9.}

Compounds represented by general formula (9) are preferably hydroxy compounds represented by the following formulas (33) and (34), because they have high sensitivity as NQD compounds and low deposition in the PI precursor resin composition.

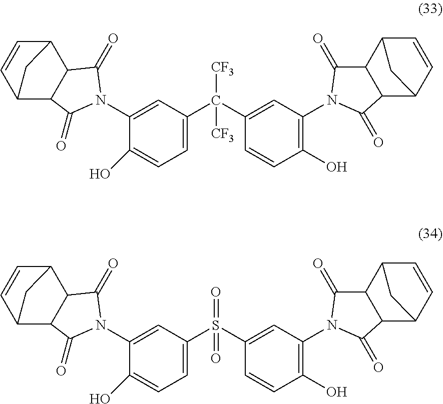

Specific compounds represented by general formula (10) include the NQD compounds of polyhydroxy compounds described in Japanese Unexamined Patent Publication No. 2001-109149. Among these compounds, NQD compounds of polyhydroxy compounds represented by the following formula (35) are preferred because they have high sensitivity and low deposition in the PI precursor resin composition.

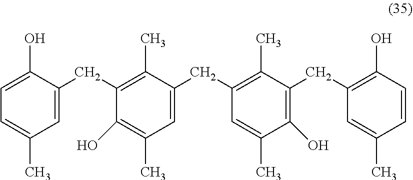 [SMILES: Cc1ccc(O)c(Cc2c(C)c(Cc3cc(C)c(O)c(Cc4cc(C)ccc4O)c3C)cc(C)c2O)c1]

The resolution will be excellent whether the 1,2-naphthoquinonediazidesulfonyl group in the quinonediazide compound is a 1,2-naphthoquinonediazide-5-sulfonyl group or a 1,2-naphthoquinonediazide-4-sulfonyl group, but a 1,2-naphthoquinonediazide-5-sulfonyl group results in more excellent resolution.

The average esterification rate for the naphthoquinonediazidesulfonyl ester of the hydroxy compound in the quinonediazide compound is preferably 60% to 100% and more preferably 80% to 100%, from the viewpoint of resolution. This is thought to be because swelling is inhibited during development due to esterification of the hydroxyl groups in the quinonediazide compound (B′).

For this embodiment it is preferred to select either or both a 1,2-naphthoquinonediazide-4-sulfonic acid ester compound and a 1,2-naphthoquinonediazide-5-sulfonic acid ester compound. A 1,2-naphthoquinonediazidesulfonic acid ester compound having both a 1,2-naphthoquinonediazide-4-sulfonyl and a 1,2-naphthoquinonediazide-5-sulfonyl group in the same molecule may also be used, or a mixture of a 1,2-naphthoquinonediazide-4-sulfonic acid ester compound and a 1,2-naphthoquinonediazide-5-sulfonic acid ester compound may be used.

### (C) Photopolymerization Initiator

The photopolymerization initiator is selected from among materials having an absorbance parameter Xr in the range of 0 to 0.04 for the specified type of light. The absorbance of the photopolymerization initiator can be measured with an ultraviolet and visible spectrophotometer using a 1 cm cell, and with the photopolymerization initiator prepared to 10 mg/L using N-methyl-2-pyrrolidone as the solvent. The obtained value of the absorbance at 365 nm divided by 10 is defined as the absorbance parameter Xr of the photopolymerization initiator. The photopolymerization initiator is selected from among compounds having an absorbance parameter Xr in the range of preferably 0 to 0.03, more preferably 0 to 0.02 and even more preferably 0 to 0.01. When the negative-type photosensitive resin composition comprises two or more photopolymerization initiators, the absorbance parameter Xr for the specified type of light may be in the range of 0 to 0.04 for the mixture of the two or more photopolymerization initiators. Preferably, all of the two or more photopolymerization initiators are selected so that the absorbance parameter Xr is in the range of 0 to 0.04 for the specified type of light.

The photopolymerization initiator is preferably a photoradical polymerization initiator, preferred photopolymerization initiators including benzophenone derivatives such as benzophenone, methyl o-benzoylbenzoate, 4-benzoyl-4′-methyldiphenyl ketone, dibenzyl ketone and fluorenone, acetophenone derivatives such as 2,2′-diethoxyacetophenone, 2-hydroxy-2-methylpropiophenone and 1-hydroxycyclohexylphenyl ketone, thioxanthone derivatives such as thioxanthone, 2-methylthioxanthone, 2-isopropylthioxanthone and diethylthioxanthone, benzyl derivatives such as benzyl, benzyldimethylketal and benzyl-β-methoxyethylacetal, benzoin derivatives such as benzoin and benzoinmethyl ether, oximes such as 1-phenyl-1,2-butanedione-2-(o-methoxycarbonyl)oxime, 1-phenyl-1,2-propanedione-2-(o-methoxycarbonyl)oxime, 1-phenyl-1,2-propanedione-2-(o-ethoxycarbonyl)oxime, 1-phenyl-1,2-propanedione-2-(o-benzoyl)oxime, 1,3-diphenylpropanetrione-2-(o-ethoxycarbonyl)oxime and 1-phenyl-3-ethoxypropanetrione-2-(o-benzoyl)oxime, N-arylglycines such as N-phenylglycine, peroxides such as benzoyl perchloride, photoacid generators such as aromatic biimidazoles, titanocenes and α-(n-octanesulfonyloxyimino)-4-methoxybenzyl cyanide, and photobase generators such as 9-antholylmethyl-N,N-diethyl carbamate, with no limitation to these. Oximes are preferred among these photopolymerization initiators, particularly from the viewpoint of photosensitivity.

Preferred among oxime photopolymerization initiators are compounds having an oxime ester structure represented by the following general formula (5):

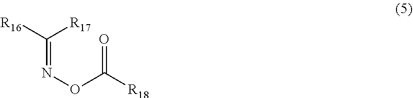

{where R₁₆, R₁₇ and R₁₈ are each a monovalent organic group, and R₁₆ and R₁₇ may be linked together to form a ring structure}, from the viewpoint of photosensitivity.

From the viewpoint of photosensitivity, the compounds having an oxime ester structure in formula (5) are more preferably one or more compounds selected from the group consisting of the following formulas (5A), (5B) and (5C).

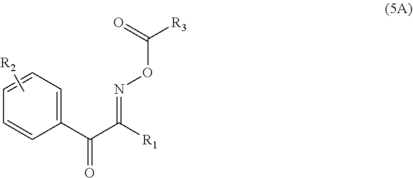

{In formula (5A), R₁ is a methyl or phenyl group, R₂ is a hydrogen atom or a monovalent organic group of 1 to 12 carbon atoms, and R₃ is an alkyl group of 1 to 5 carbon atoms, an alkoxy group of 1 to 5 carbon atoms or a phenyl group.}

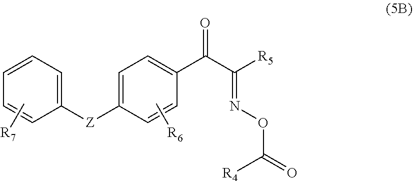

{In formula (5B), Z is a sulfur or oxygen atom, R₄ is a methyl or phenyl group, and R₅ to R₇ are each independently a hydrogen atom or a monovalent organic group.}

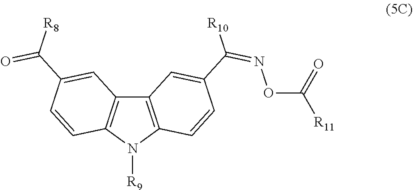

{In formula (5C), R₈ is a monovalent organic group derived from an aromatic group of 6 to 20 carbon atoms or a heterocyclic compound of 5 to 20 carbon atoms, R₉ is an alkyl group of 1 to 5 carbon atoms, R₁₀ is a monovalent organic group having an alkyl group of 1 to 10 carbon atoms or a saturated alicyclic structure of 3 to 10 carbon atoms, and R₁₁ is a methyl, ethyl, propyl or phenyl group.}

### (D) Solvent

Solvents include amides, sulfoxides, ureas, ketones, esters, lactones, ethers, halogenated hydrocarbons, hydrocarbons and alcohols, examples of which are N-methyl-2-pyrrolidone, N,N-dimethyl acetamide, N,N-dimethylformamide, dimethyl sulfoxide, tetramethylurea, acetone, methyl ethyl ketone, methyl isobutyl ketone, cyclopentanone, cyclohexanone, methyl acetate, ethyl acetate, butyl acetate, diethyl oxalate, ethyl lactate, methyl lactate, butyl lactate, γ-butyrolactone, propyleneglycol monomethyl ether acetate, propyleneglycol monomethyl ether, benzyl alcohol, phenyl glycol, tetrahydrofurfuryl alcohol, ethyleneglycol dimethyl ether, diethyleneglycol dimethyl ether, tetrahydrofuran, morpholine, dichloromethane, 3-methoxy-N,N-dimethylpropaneamide, 1,2-dichloroethane, 1,4-dichlorobutane, chlorobenzene, o-dichlorobenzene, anisole, hexane, heptane, benzene, toluene, xylene and mesitylene. Preferred among these are N-methyl-2-pyrrolidone, dimethyl sulfoxide, tetramethylurea, butyl acetate, ethyl lactate, γ-butyrolactone, propyleneglycol monomethyl ether acetate, propyleneglycol monomethyl ether, diethyleneglycol dimethyl ether, 3-methoxy-N,N-dimethylpropaneamide, benzyl alcohol, phenyl glycol and tetrahydrofurfuryl alcohol, from the viewpoint of solubility of the resin, stability of the resin composition and adhesion onto substrates.

Most preferred among such solvents are those that completely dissolve the polymer product, examples of which include N-methyl-2-pyrrolidone, N,N-dimethyl acetamide, N,N-dimethylformamide, dimethyl sulfoxide, 3-methoxy-N,N-dimethylpropaneamide, tetramethylurea and γ-butyrolactone. A single type of solvent may be used, or two or more solvents may be used in combination.

The amount of solvent used in the PI precursor resin composition is in the range of preferably 100 to 1000 parts by mass, more preferably 120 to 700 parts by mass and even more preferably 125 to 500 parts by mass, with respect to 100 parts by mass of the polyimide precursor resin.

The PI precursor resin composition may also comprise components other than components (A) to (D) (hereunder also referred to as “other components”). Other components to be used in addition to components (A) to (D) include, but are not limited to, photopolymerizable compounds and thermal base generators (E), nitrogen-containing heterocyclic rust inhibitors (H), hindered phenol compounds, organic titanium compounds, adhesion aids and sensitizing agents (F), and polymerization inhibitors (G). Materials among these “other components” that have an absorbance parameter Xt of 0.01 to 0.05 are generally classified as “exposure ray absorbers”. However, materials among the “other components” that have an absorbance parameter Xt of 0.01 to 0.05 but absorb light themselves, promoting higher sensitivity of the system by donating the obtained energy to other compounds, are instead classified as “sensitizing agents”. Using a sensitizing agent increases the sensitivity of the system, resulting in a narrower range for usable exposure dose and tending to promote formation of residue at the bases of the unexposed sections, thus having an opposite effect from that of the exposure ray absorber. Materials among the other components” that have an absorbance parameter Xt of 0.01 to 0.05 but that are nitrogen-containing heterocyclic compounds having interaction sites of imino groups or amino groups with the copper interface, are instead classified as “(H) nitrogen-containing heterocyclic rust inhibitors”. In addition, materials among the “other components” that have an absorbance parameter Xt of 0.01 to 0.05 but have interaction sites with silicon wafer interfaces, such as alkoxysilane structures, are classified as “adhesion aids”. This is because such “nitrogen-containing heterocyclic rust inhibitors” and “adhesion aids” become unevenly distributed near the wafer interface, and thus fail to function to adjust the absorbance of the film as a whole. Consequently, compounds classified as “sensitizing agents”, “nitrogen-containing heterocyclic rust inhibitors” and “adhesion aids” are not considered as “exposure ray absorbers”, even if the values of their absorbance parameters Xt are 0.01 to 0.05.

### (E) Photopolymerizable Compound

The PI precursor resin composition preferably includes a photopolymerizable compound. A photopolymerizable compound is a monomer that has a photopolymerizable unsaturated bond and is able to assist in formation of crosslinks in the polyimide precursor resin under exposure. Such a monomer is preferably a (meth)acrylic compound that undergoes radical polymerization reaction with a photopolymerization initiator. Examples of photopolymerizable compounds include, but are not limited to, mono- or diacrylates and methacrylates of ethylene glycol or polyethylene glycol, such as diethyleneglycol dimethacrylate and tetraethyleneglycol dimethacrylate, mono- or diacrylates and methacrylates of propylene glycol or polypropylene glycol, mono-, di- or triacrylates and methacrylates of glycerol, cyclohexane diacrylate and dimethacrylate, 1,4-butanediol diacrylate and dimethacrylate, 1,6-hexanediol diacrylate and dimethacrylate, neopentyl glycol diacrylate and dimethacrylate, bisphenol A mono- or diacrylate and methacrylate, benzene trimethacrylate, isobornyl acrylate and methacrylate, acrylamides and their derivatives, methacrylamides and their derivatives, trimethylolpropane triacrylate and methacrylate, glycerol di- and triacrylate and methacrylate, and pentaerythritol di-, tri- or tetraacrylate and methacrylate, as well as ethylene oxide or propylene oxide addition products of these compounds.

When the PI precursor resin composition comprises such a monomer having a photopolymerizable unsaturated bond, the content of the monomer having the photopolymerizable unsaturated bond is preferably 1 to 50 parts by mass with respect to 100 parts by mass of the polyimide precursor resin. If the added content is 1 part by mass or greater it will be possible to obtain satisfactory sensitivity during exposure, and if it is 50 parts by mass or lower the in-plane uniformity of the coating film will be excellent.

### Thermal Base Generator

The PI precursor resin composition may also comprise a base generator. A base generator is a compound that generates a base by heating. A thermal base generator can accelerate imidization of the PI precursor resin composition.

The type of thermal base generator is not particularly specified but may be an amine compound protected with a tert-butoxycarbonyl group, or a thermal base generator as disclosed in International Patent Publication No. WO2017/038598. There is no limitation to these, however, and publicly known thermal base generators may also be used.

Examples of amine compounds protected with tert-butoxycarbonyl include compounds such as ethanolamine, 3-amino-1-propanol, 1-amino-2-propanol, 2-amino-1-propanol, 4-amino-1-butanol, 2-amino-1-butanol, 1-amino-2-butanol, 3-amino-2,2-dimethyl-1-propanol, 4-amino-2-methyl-1-butanol, valinol, 3-amino-1,2-propanediol, 2-amino-1,3-propanediol, tyramine, norephedrine, 2-amino-1-phenyl-1,3-propanediol, 2-aminocyclohexanol, 4-aminocyclohexanol, 4-aminocyclohexaneethanol, 4-(2-aminoethyl)cyclohexanol, N-methylethanolamine, 3-(methylamino)-1-propanol, 3-(isopropylamino)propanol, N-cyclohexylethanolamine, α-[2-(methylamino)ethyl]benzyl alcohol, diethanolamine, diisopropanolamine, 3-pyrrolidinol, 2-pyrrolidinemethanol, 4-hydroxypiperidine, 3-hydroxypiperidine, 4-hydroxy-4-phenylpiperidine, 4-(3-hydroxyphenyl)piperidine, 4-piperidinemethanol, 3-piperidinemethanol, 2-piperidinemethanol, 4-piperidineethanol, 2-piperidineethanol, 2-(4-piperidyl)-2-propanol, 1,4-butanolbis(3-aminopropyl)ether, 1,2-bis(2-aminoethoxy)ethane, 2,2′-oxybis(ethylamine), 1,14-diamino-3,6,9,12-tetraoxatetradecane, 1-aza-15-crown 5-ether, diethylene glycolbis(3-aminopropyl)ether and 1,11-diamino-3,6,9-trioxaundecane, or their amino acids or derivatives, with tert-butoxycarbonyl-protected amino groups.

The thermal base generator added content is preferably 0.1 part by mass to 30 parts by mass and more preferably 1 part by mass to 20 parts by mass, with respect to 100 parts by mass of the polyimide precursor resin (A). The content is 0.1 part by mass or greater from the viewpoint of the imidation-accelerating effect, and the content is preferably 20 parts by mass or lower from the viewpoint of the physical properties of the photosensitive resin layer obtained by curing the PI precursor resin composition.

### (H) Nitrogen-Containing Heterocyclic Rust Inhibitor

When the PI precursor resin composition is used to form a cured film on a substrate made of copper or copper alloy, the PI precursor resin composition may optionally include a nitrogen-containing heterocyclic rust inhibitor to inhibit discoloration over the copper. Nitrogen-containing heterocyclic rust inhibitors include azole compounds and purine derivatives. However, 2-(2′-hydroxyphenyl)benzotriazole-based compounds lack a coordination site for copper and therefore are not included among nitrogen-containing heterocyclic rust inhibitors. The nitrogen-containing heterocyclic rust inhibitor is preferably a compound with an imino group or an amino group.

Examples of azole compounds include 1H-triazole, 5-methyl-1H-triazole, 5-ethyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, 1,5-dimethyltriazole, 4,5-diethyl-1H-triazole, 1H-benzotriazole, tolyltriazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole and 1-methyl-1H-tetrazole.

Particularly preferred are tolyltriazole, 5-methyl-1H-benzotriazole, 4-methyl-1H-benzotriazole and 5-amino-1H-tetrazole. These azole compounds may be used alone, or mixtures of two or more of them may be used.

Specific examples of purine derivatives include purine, adenine, guanine, hypoxanthine, xanthine, theobromine, caffeine, uric acid, isoguanine, 2,6-diaminopurine, 9-methyladenine, 2-hydroxyadenine, 2-methyladenine, 1-methyladenine, N-methyladenine, N,N-dimethyladenine, 2-fluoroadenine, guanineoxime, 8-aminoadenine, 6-amino-8-phenyl-9H-purine, 1-ethyladenine, 6-ethylaminopurine, 1-benzyladenine, N-methylguanine, 7-(2-hydroxyethyl)guanine, N-(3-chlorophenyl)guanine, N-(3-ethylphenyl)guanine, 2-azaadenine, 5-azaadenine, 8-azaadenine, 8-azaguanine, 8-azapurine, 8-azaxanthine and 8-azahypoxanthine, and derivatives of the same.

When the PI precursor resin composition contains the aforementioned azole compound or purine derivative, its content is preferably 0.1 to 20 parts by mass with respect to 100 parts by mass of the polyimide precursor resin (A), and more preferably 0.5 to 5 parts by mass, from the viewpoint of photosensitivity. If the content of the azole compound is 0.1 part by mass or greater with respect to 100 parts by mass of the polyimide precursor resin (A), discoloration of the copper or copper alloy surface will be inhibited when the PI precursor resin composition has been formed on the copper or copper alloy, and if it is 20 parts by mass or lower the photosensitivity will be excellent.

### (F) Hindered Phenol Compound

The PI precursor resin composition may also optionally include a hindered phenol compound to inhibit discoloration of the copper surface. Examples of hindered phenol compounds include, but are not limited to, 2,6-di-t-butyl-4-methylphenol, 2,5-di-t-butyl-hydroquinone, octadecyl-3-(3,5-di-t-butyl-4-hydroxyphenyl)propionate, isooctyl-3-(3,5-di-t-butyl-4-hydroxyphenyl)propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethylene glycol-bis[3-(3-t-butyl-5-methyl-4-hydroxyphenyl)propionate], 1,6-hexanediol-bis[3-(3,5-di-t-butyl-4-hydroxyphenyl)propionate], 2,2-thio-diethylenebis[3-(3,5-di-t-butyl-4-hydroxyphenyl)propionate], N,N′-hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butylphenol), pentaerythrityl-tetrakis[3-(3,5-di-t-butyl-4-hydroxyphenyl)propionate], tris-(3,5-di-t-butyl-4-hydroxybenzyl)-isocyanurate and 1,3,5-trimethyl-2,4,6-tris(3,5-di-t-butyl-4-hydroxybenzyl)benzene.

Additional examples of hindered phenol compounds include, but are not limited to, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione and 1,3,5-tris(4-t-butyl-5-ethyl-3-hydroxy-2-methylbenzyl)-1,3,5-triazine-2,4,6-(1H,3H,5H)-trione. Particularly preferred among these is 1,3,5-tris(4-t-butyl-3-hydroxy-2,6-dimethylbenzyl)-1,3,5-triazine-2,4,6-(1H,3H,5H)-trione.

The content of a hindered phenol compound is preferably 0.1 to 20 parts by mass with respect to 100 parts by mass of the polyimide precursor resin (A), and from the viewpoint of photosensitivity it is more preferably 0.5 to 10 parts by mass. If the content of the hindered phenol compound is 0.1 part by mass or greater with respect to 100 parts by mass of the polyimide precursor resin (A), then discoloration and corrosion of the copper or copper alloy surface will be prevented when the PI precursor resin composition has been formed on the copper or copper alloy, for example, while if it is 20 parts by mass or lower the photosensitivity will be excellent.

### Organic Titanium Compound

The PI precursor resin composition may also comprise an organic titanium compound. By comprising an organic titanium compound, it will be able to form a photosensitive resin layer with excellent chemical resistance even when cured at a low temperatures.

Organic titanium compounds that may be used include those having an organic chemical substance bonded to a titanium atom via a covalent bond or ionic bond. Specific examples of organic titanium compounds include the following I) to VII):
I) Titanium chelate compounds: More preferred are titanium chelates having two or more alkoxy groups, since it will be possible to obtain storage stability of the PI precursor resin composition, and a satisfactory pattern. Specific examples are titanium bis(triethanolamine) diisopropoxide, titanium di(n-butoxide) bis(2,4-pentanedionate), titanium diisopropoxide bis(2,4-pentanedionate), titanium diisopropoxide bis(tetramethylheptanedionate) and titanium diisopropoxide bis(ethylacetoacetate).
II) Tetraalkoxytitanium compounds: Examples are titanium tetra(n-butoxide), titanium tetraethoxide, titanium tetra(2-ethylhexoxide), titanium tetraisobutoxide, titanium tetraisopropoxide, titanium tetramethoxide, titanium tetramethoxypropoxide, titanium tetramethylphenoxide, titanium tetra(n-nonyloxide), titanium tetra(n-propoxide), titanium tetrastearyloxide and titanium tetrakis[bis{2,2-(allyloxymethyl)butoxide}].
III) Titanocene compounds: Examples are pentamethylcyclopentadienyltitanium trimethoxide, bis(η⁵-2,4-cyclopentadien-1-yl)bis(2,6-difluorophenyl)titanium and bis(η⁵-2,4-cyclopentadien-1-yl)bis(2,6-difluoro-3-(1H-pyrrol-1-yl)phenyl)titanium.
IV) Monoalkoxytitanium compounds: Examples are titanium tris(dioctylphosphate)isopropoxide and titanium tris(dodecylbenzenesulfonate)isopropoxide.
V) Titanium oxide compounds: Examples are titanium oxide bis(pentanedionate), titanium oxide bis(tetramethylheptanedionate) and phthalocyaninetitanium oxide.
VI) Titanium tetraacetylacetonate compounds: An example is titanium tetraacetylacetonate.
VII) Titanate coupling agents: An example is isopropyltridodecylbenzenesulfonyl titanate.

Among these, the organic titanium compound is preferably one or more compounds selected from the group consisting of I) titanium chelate compounds, II) tetraalkoxytitanium compounds and III) titanocene compounds, from the viewpoint of exhibiting more satisfactory chemical resistance. Particularly preferred are titanium diisopropoxide bis(ethylacetoacetate), titanium tetra(n-butoxide) and bis(η⁵-2,4-cyclopentadien-1-yl)bis(2,6-difluoro-3-(1H-pyrrol-1-yl)phenyl)titanium.

When an organic titanium compound is added, its content is preferably 0.05 to 10 parts by mass and more preferably 0.1 to 2 parts by mass, with respect to 100 parts by mass of the polyimide precursor resin (A). If the content is 0.05 parts by mass or greater, satisfactory heat resistance and chemical resistance will be exhibited, and if it is 10 parts by mass or lower, the storage stability will be excellent.

### Adhesion Aid

The PI precursor resin composition may also optionally include an adhesion aid to improve the adhesion between the base material and the film formed using the PI precursor resin composition. Examples of adhesion aids include silane coupling agents such as γ-aminopropyldimethoxysilane, N-(β-aminoethyl)-γ-aminopropylmethyldimethoxysilane, γ-glycidoxypropylmethyldimethoxysilane, γ-mercaptopropylmethyldimethoxysilane, 3-methacryloxypropyldimethoxymethylsilane, 3-methacryloxypropyltrimethoxysilane, dimethoxymethyl-3-piperidinopropylsilane, diethoxy-3-glycidoxypropylmethylsilane, N-(3-diethoxymethylsilylpropyl)succinimide, N-[3-(triethoxysilyl)propyl]phthalamic acid, benzophenone-3,3′-bis(N-[3-triethoxysilyl]propylamide)-4,4′-dicarboxylic acid, benzene-1,4-bis(N-[3-triethoxysilyl]propylamide)-2,5-dicarboxylic acid, 3-(triethoxysilyl)propylsuccinic anhydride, N-phenylaminopropyltrimethoxysilane, 3-ureidopropyltrimethoxysilane, 3-ureidopropyltriethoxysilane and 3-(trialkoxysilyl)propylsuccinic anhydride, and aluminum-based adhesion aids such as aluminum tris(ethylacetoacetate), aluminum tris(acetylacetonate) and aluminum ethylacetoacetate diisopropylate.

Among these adhesion aids it is more preferred to use a silane coupling agent, from the viewpoint of adhesive force. When the PI precursor resin composition comprises an adhesion aid, the content of the adhesion aid is preferably in the range of 0.5 to 25 parts by mass with respect to 100 parts by mass of the polyimide precursor resin (A).

Examples of silane coupling agents include, but are not limited to, 3-mercaptopropyltrimethoxysilane (KBM803, trade name of Shin-Etsu Chemical Co., Ltd. and SILA-ACE S810, trade name of Chisso Corp.), 3-mercaptopropyltriethoxysilane (SIM6475.0, trade name of Azmax Corp.), 3-mercaptopropylmethyldimethoxysilane (LS1375, trade name of Shin-Etsu Chemical Co., Ltd. and SIM6474.0, trade name of Azmax Corp.), mercaptomethyltrimethoxysilane (SIM6473.5C, trade name of Azmax Corp.), mercaptomethylmethyldimethoxysilane (SIM6473.0, trade name of Azmax Corp.), 3-mercaptopropyldiethoxymethoxysilane, 3-mercaptopropylethoxydimethoxysilane, 3-mercaptopropyltripropoxysilane, 3-mercaptopropyldiethoxypropoxysilane, 3-mercaptopropylethoxydipropoxysilane, 3-mercaptopropyldimethoxypropoxysilane, 3-mercaptopropylmethoxydipropoxysilane, 2-mercaptoethyltrimethoxysilane, 2-mercaptoethyldiethoxymethoxysilane, 2-mercaptoethylethoxydimethoxysilane, 2-mercaptoethyltripropoxysilane, 2-mercaptoethyltripropoxysilane, 2-mercaptoethylethoxydipropoxysilane, 2-mercaptoethyldimethoxypropoxysilane, 2-mercaptoethylmethoxydipropoxysilane, 4-mercaptobutyltrimethoxysilane, 4-mercaptobutyltriethoxysilane and 4-mercaptobutyltripropoxysilane.

Other examples of silane coupling agents include, but are not limited to, N-(3-triethoxysilylpropyl)urea (LS3610, trade name of Shin-Etsu Chemical Co., Ltd. and SIU9055.0, trade name of Azmax Corp.), N-(3-trimethoxysilylpropyl)urea (SIU9058.0, trade name of Azmax Corp.), N-(3-diethoxymethoxysilylpropyl)urea, N-(3-ethoxydimethoxysilylpropyl)urea, N-(3-tripropoxysilylpropyl)urea, N-(3-diethoxypropoxysilylpropyl)urea, N-(3-ethoxydipropoxysilylpropyl)urea, N-(3-dimethoxypropoxysilylpropyl)urea, N-(3-methoxydipropoxysilylpropyl)urea, N-(3-trimethoxysilylethyl)urea, N-(3-ethoxydimethoxysilylethyl)urea, N-(3-tripropoxysilylethyl)urea, N-(3-tripropoxysilylethyl)urea, N-(3-ethoxydipropoxysilylethyl)urea, N-(3-dimethoxypropoxysilylethyl)urea, N-(3-methoxydipropoxysilylethyl)urea, N-(3-trimethoxysilylbutyl)urea, N-(3-triethoxysilylbutyl)urea, N-(3-tripropoxysilylbutyl)urea, 3-(m-aminophenoxy)propyltrimethoxysilane (SLA0598.0, trade name of Azmax Corp.), m-aminophenyltrimethoxysilane (SLA0599.0, trade name of Azmax Corp.), p-aminophenyltrimethoxysilane (SLA0599.1, trade name of Azmax Corp.), and aminophenyltrimethoxysilane (SLA0599.2, trade name of Azmax Corp.).

Further examples of silane coupling agents include 2-(trimethoxysilylethyl)pyridine (SIT8396.0, trade name of Azmax Corp.), 2-(triethoxysilylethyl)pyridine, 2-(dimethoxysilylmethylethyl)pyridine, 2-(diethoxysilylmethylethyl)pyridine, (3-triethoxysilylpropyl)-t-butyl carbamate, (3-glycidoxypropyl)triethoxysilane, tetramethoxysilane, tetraethoxysilane, tetra-n-propoxysilane, tetra-i-propoxysilane, tetra-n-butoxysilane, tetra-i-butoxysilane, tetra-t-butoxysilane, tetrakis(methoxyethoxysilane), tetrakis(methoxy-n-propoxysilane), tetrakis(ethoxyethoxysilane), tetrakis(methoxyethoxyethoxysilane), bis(trimethoxysilyl)ethane, bis(trimethoxysilyl)hexane, bis(triethoxysilyl)methane, bis(triethoxysilyl)ethane, bis(triethoxysilyl)ethylene, bis(triethoxysilyl)octane, bis(triethoxysilyl)octadiene, bis[3-(triethoxysilyl)propyl]disulfide, bis[3-(triethoxysilyl)propyl]tetrasulfide, di-t-butoxydiacetoxysilane, di-i-butoxyaluminoxytriethoxysilane, phenylsilanetriol, methylphenylsilanediol, ethylphenylsilanediol, n-propylphenylsilanediol, isopropylphenylsilanediol, n-butyldiphenylsilanediol, isobutylphenylsilanediol, tert-butylphenylsilanediol, diphenylsilanediol, dimethoxydiphenylsilane, diethoxydiphenylsilane, dimethoxydi-p-tolylsilane, ethylmethylphenylsilanol, n-propylmethylphenylsilanol, isopropylmethylphenylsilanol, n-butylmethylphenylsilanol, isobutylmethylphenylsilanol, tert-butylmethylphenylsilanol, ethyl-n-propylphenylsilanol, ethylisopropylphenylsilanol, n-butylethylphenylsilanol, isobutylethylphenylsilanol, tert-butylethylphenylsilanol, methyldiphenylsilanol, ethyldiphenylsilanol, n-propyldiphenylsilanol, isopropyldiphenylsilanol, n-butyldiphenylsilanol, isobutyldiphenylsilanol, tert-butyldiphenylsilanol and triphenylsilanol, with no limitation to these.

These silane coupling agents may be used alone or in combinations of more than one. Preferred among the silane coupling agents mentioned above are phenylsilanetriol, trimethoxyphenylsilane, trimethoxy(p-tolyl)silane, diphenylsilanediol, dimethoxydiphenylsilane, diethoxydiphenylsilane, dimethoxydi-p-tolylsilane, triphenylsilanol, and silane coupling agents having structures represented by the following formula:

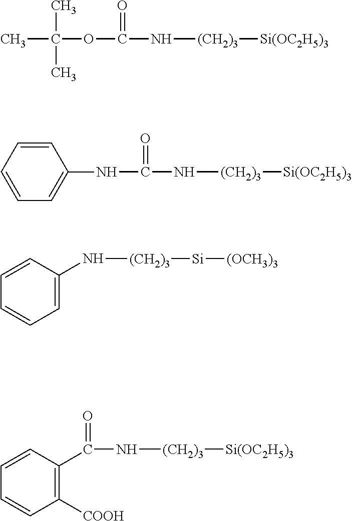

from the viewpoint of storage stability.

When a silane coupling agent is used, its content is preferably 0.01 to 20 parts by mass with respect to 100 parts by mass of the polyimide precursor resin (A).

### Sensitizing Agent

The PI precursor resin composition may also optionally include a sensitizing agent to improve the photosensitivity. Examples of sensitizing agents include Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylaminocinnamylideneindanone, p-dimethylaminobenzylideneindanone, 2-(p-dimethylaminophenylbiphenylene)-benzothiazole, 2-(p-dimethylaminophenylvinylene)benzothiazole, 2-(p-dimethylaminophenylvinylene)isonaphthothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin, N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzthiazole, 2-(p-dimethylaminostyryl)naphtho(1,2-d)thiazole and 2-(p-dimethylaminobenzoyl)styrene. Any of these may be used alone or in combinations of 2 to 5 different types, for example.

When the PI precursor resin composition comprises a sensitizing agent to improve the photosensitivity, its content is preferably in the range of 0.1 to 25 parts by mass with respect to 100 parts by mass of the polyimide precursor resin (A).

### (G) Polymerization Inhibitor

The PI precursor resin composition may also optionally include a polymerization inhibitor, particularly to increase the stability of the viscosity and photosensitivity of the PI precursor resin composition when stored in the state of a solution containing a solvent. Such polymerization inhibitors that may be used include hydroquinone, N-nitrosodiphenylamine, p-tert-butylcatechol, phenothiazine, N-phenylnaphthylamine, ethylenediaminetetraacetic acid, 1,2-cyclohexanediaminetetraacetic acid, glycol ether diaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-phenylhydroxylamine ammonium salt and N-nitroso-N-(1-naphthyl)hydroxylamine ammonium salt.

### <Content Deciding Step>

In the content deciding step, mass fraction β of the exposure ray absorber to be added and mass fraction β of the photopolymerization initiator to be added are decided based on the absorbance parameter Xp of the polyimide precursor resin, the absorbance parameter Xt of the exposure ray absorber, the absorbance parameter Xr of the photopolymerization initiator and the assumed thickness D of the prebaked film after coating and solvent removal of the PI precursor resin composition, according to the following formula (1):

0.7≤(Xp+Xt×α+Xr×β)×D≤2.2 (1). The mass fractions α and β are mass fractions based on 100 parts by mass for the polyimide precursor resin. The present inventors have found that, since the absorbance for a given type of light (such as i-line) differs depending on the PI precursor resin backbone, it is necessary to adjust the light ray absorption property for the resin composition as a whole to the aforementioned specified range using other components, in combination with the absorbance parameter of the PI precursor resin. This makes it possible to obtain a PI precursor resin composition with excellent resolvability and a wide range of usable exposure dose, suited for the film thickness that is used. Without being limited to any particular theory, the reason for this is thought to be that when the absorbance of the coated film of the PI precursor resin composition is set to within the range of formula (1), the amount of light reaching the film bottom layer during exposure can be adjusted to inhibit diffuse reflection in the underlying base material under the film bottom layer, thus allowing unwanted crosslinking reaction in the unexposed sections to be inhibited.

The value of (Xp+Xt×α+Xr×β)×D is preferably in the range of 0.7 to 2.2 and more preferably in the range of 0.7 to 1.4. If the value of formula (1) is less than 0.7, large amounts of residue will be generated at the development opening by diffuse reflection at the base material below the film bottom layer during exposure, making it impossible to obtain satisfactory resolvability. If the PI precursor resin composition is adjusted to satisfy formula (1) using a photopolymerization initiator alone without an exposure ray absorber, the sensitivity for exposure rays will be higher and the range of usable exposure dose will be narrowed, thus reducing the handleability. If the value in formula (1) exceeds 2.2, on the other hand, photocuring of the film bottom layer will be insufficient and tapered defects known as “undercuts” (overhangs) will become a problem. If the value in formula (1) is in the range of 0.7 to 1.4, it will be possible to obtain a pattern with satisfactory resolution and an optimal tapered form. An “optimal tapered form”, for the purpose of the disclosure, is a pattern form with wall face angles of about 70° to 80°. If the wall face angles are 70° or greater, coverage of the wiring on the lower layer of the PI cured film will be satisfactory, helping to reduce risk of exposure of the lower layer wiring, and if the wall face angles are 80° or smaller, adhesion of the seed layer sputtered onto the upper layer of the PI cured film for RDL wiring will be satisfactory, thus reducing risk of RDL wiring formation defects.

The assumed thickness D of the prebaked film is the assumed thickness of the prebaked film that is obtained by coating and solvent removal of the PI precursor resin composition. For the purpose of the present specification, the actual thickness of the prebaked film obtained by coating and solvent removal of the PI precursor resin composition is represented separately as D′. The assumed thickness D of the prebaked film is preferably 1 μm to 20 μm, more preferably 1 μm to 10 μm and even more preferably 1 μm or greater and less than 7 μm.

The content α of the exposure ray absorber decided based on formula (1) may be 0.1 part by mass to 20 parts by mass, 1 part by mass to 10 parts by mass or 1 part by mass to 8 parts by mass with respect to 100 parts by mass of the polyimide precursor resin, where i-line is set as the exposure ray and 10 μm is set as the assumed thickness D of the prebaked film.

The content β of the photopolymerization initiator decided based on formula (1) may be 0.1 part by mass to 10 parts by mass, 1 part by mass to 8 parts by mass or 1 part by mass to 5 parts by mass with respect to 100 parts by mass of the polyimide precursor resin, where i-line is set as the exposure ray and 10 μm is set as the assumed thickness D of the prebaked film.

### <Preparation Step for PI Precursor Resin Composition>

In the preparation step for the PI precursor resin composition, a PI precursor resin composition is prepared containing the decided PI precursor resin, the exposure ray absorber at the decided mass fraction α, the photopolymerization initiator at the decided mass fraction β, the solvent and the optionally selected other materials. More specifically, each material may be loaded in and mixed with a selected solvent to obtain the PI precursor resin composition. The viscosity of the PI precursor resin composition may be adjusted to 10 to 100 poise, for example. The PI precursor resin composition may also be filtered if necessary.

### <Method for Producing Relief Pattern Film>

The method for producing a relief pattern film of the disclosure includes (1) a step in which a PI precursor resin composition comprising a PI precursor resin, an exposure ray absorber, a photopolymerization initiator and a solvent is produced by the method for producing a PI precursor resin composition described above; (2) a film coating step in which a coating film of the PI precursor resin composition is obtained; (3) a drying step in which the solvent in the coating film is removed to obtain a prebaked film of thickness D′; (4) an exposure step in which the prebaked film is exposed by a specified type of light, and (5) a developing step in which the exposed photosensitive resin layer is developed to obtain a relief pattern film.

### (1) Step of Producing PI Precursor Resin Composition

In this step, a PI precursor resin composition is produced by a step of producing a PI precursor resin composition according to the disclosure as described above.

### (2) Film Coating Step

In this step, the PI precursor resin composition is coated onto an arbitrary base material to obtain a coated film of the PI precursor resin composition. The coating method may be a method conventionally used for coating of PI precursor resin compositions, and for example, a method of coating with a spin coater, bar coater, blade coater, curtain coater, screen printer or the like, or a method of spray coating with a spray coater, may be used.

### (3) Drying Step

In this step, the solvent in the coated film of the PI precursor resin composition is removed to obtain a prebaked film of actual thickness D′. The actual thickness D′ may be identical or approximately equal to the assumed thickness D, and may be in the range of about the assumed thickness D±5%. The thickness D′ is preferably 1 μm to 20 μm, more preferably 1 μm to 10 μm and even more preferably 1 μm or greater and less than 7 μm. The method of removing the solvent may be air-drying, heat drying with an oven or hot plate, or reduced-pressure or vacuum drying, for example. For air-drying or heat drying specifically, the drying may be carried out under conditions of 20° C. to 150° C. for 1 minute to 1 hour. The prebaked film of thickness D′ after solvent removal more preferably satisfies the inequality 0.7≤(Xp+Xt×α+Xr×β)×D′ ≤2.2, and even more preferably satisfies the inequality 0.7≤(Xp+Xt×α+Xr×β)×D′≤1.4.

### (4) Exposure Step

In this step, the formed photosensitive resin layer is exposed using a specified type of light. The exposure is carried out with an ultraviolet light source using an exposure device with a contact aligner, mirror projection and stepper, either directly or through a patterned photomask or reticle. Exposure causes the polyimide precursor in the PI precursor resin composition to undergo crosslinking at the exposed sections by action of the photopolymerization initiator, becoming insoluble in the developing solution.

### (5) Developing Step

In this step, the exposed photosensitive resin layer is developed to obtain a relief pattern film. When the unexposed sections of the exposed photosensitive resin layer are contacted with the developing solution, they are developed and removed. The developing method may be a conventionally known photoresist developing method, selected from among any methods such as a rotating spray method, paddle method or dipping method with ultrasonic treatment. Following development, post-development baking may be carried out with the desired combination of temperature and time necessary for the purpose of adjusting the relief pattern shape.

The developing solution used for development is preferably a good solvent for the PI precursor resin composition, or a combination of a good solvent and a poor solvent, for example. Preferred examples of good solvents are N-methyl-2-pyrrolidone, N-cyclohexyl-2-pyrrolidone, N,N-dimethylacetamide, cyclopentanone, cyclohexanone, γ-butyrolactone, α-acetyl-γ-butyrolactone and the like. Preferred examples of poor solvents are toluene, xylene, methanol, ethanol, isopropyl alcohol, ethyl lactate, propyleneglycol methyl ether acetate, water and the like. When a good solvent and a poor solvent are used in admixture, the proportion of the poor solvent with respect to the good solvent is preferably adjusted by the solubility of the polymer in the PI precursor resin composition. The solvents may be used in combinations of two or more, such as several solvents.

### <Method for Producing Cured Film (Cured Relief Pattern)>

The method for producing a cured film according to the disclosure includes a step of curing the relief pattern film that has been produced by the aforementioned developing step (5) to form a cured film (cured relief pattern).

### (6) Cured Relief Pattern Forming Step

In this step, the relief pattern obtained by development is heated to disperse the photosensitive component, while imidizing the polyimide precursor resin to convert it to a cured relief pattern comprising a polyimide. The heat treatment method may be selected from among various methods including methods using a hot plate, using an oven, or using a temperature programmable heating oven, for example. The heat treatment may be carried out under conditions of 160° C. to 350° C. for 30 minutes to 5 hours, for example. The temperature for heat treatment is preferably 250° C. or lower and more preferably 200° C. or lower. The atmosphere gas for heat curing may be air, or an inert gas such as nitrogen or argon may be used.

### <Polyimide>

The present invention also provides a cured film of a PI precursor resin composition, obtained by the method for producing a cured film described above. The cured film is one with a polyimide cured relief pattern. The polyimide imidization rate is preferably 80 to 100%. The structure of the polyimide in the cured film (cured relief pattern) formed from the polyimide precursor resin composition is preferably one represented by the following general formula.

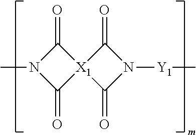

{In the formula, X₁ and Y₁ are the same as X₁ and Y₁ in general formula (1), and m is a positive integer.}

The preferred X₁ and Y₁ groups for general formula (1) are also preferred as polyimides with the structures represented by this general formula, for the same reason. The number of repeating units m in the general formula is not particularly restricted and may be an integer of 2 to 150.

### <Semiconductor Device>

The invention further provides a semiconductor device having a cured relief pattern obtained by the method for producing a cured relief pattern described above. For example, it can provide a semiconductor device having a base material as the semiconductor element, and a cured relief pattern of a polyimide formed on the base material by the method for producing a cured relief pattern described above. The invention can also provide a method for producing a semiconductor device, one step of which is the method for producing a cured relief pattern of the disclosure using a semiconductor element as the base material. The semiconductor device can be produced by forming a cured relief pattern, formed by the method for producing a cured relief pattern of the disclosure, as a surface-protecting film, interlayer dielectric film, rewiring insulating film, flip-chip device protective film or a protective film for a semiconductor device having a bump structure, and combining this with a known method for producing a semiconductor device.

### <Display Device>

The disclosure can also provide a display device comprising a display element and cured film formed on top of the display element, wherein the cured film is the cured relief pattern described above. The cured relief pattern may be layered in direct contact with the display element, or it may be layered across another layer. Examples of cured films include surface-protecting films for TFT liquid crystal display units and color filter elements, insulating films, and flattening films, as well as protrusions for MVA liquid crystal display devices, and partitions for organic EL element cathodes.

The PI precursor resin composition of the disclosure is preferably a PI precursor resin composition for formation of an insulating member or for formation of an interlayer dielectric film. In addition to application in semiconductor devices as described above, the PI precursor resin composition is also useful for application in interlayer dielectric films for multilayer circuits, cover coats for flexible copper-clad sheets, solder resist films and liquid crystal oriented films.

### EXAMPLES

The invention will now be explained in detail through Examples and Comparative Examples, with the understanding that these Examples are not limitative on the disclosure.

### <Production Example for Polyimide Precursor Resin (A)>

### Production Example 1

After placing 155.1 g of 4,4′-oxydiphthalic dianhydride (ODPA) in a 3 L separable flask, 135.4 g of 2-hydroxyethyl methacrylate (HEMA) and 400 mL of γ-butyrolactone were added, the mixture was stirred at room temperature, and 79.1 g of pyridine was added while stirring to obtain a reaction mixture. When heat release from the reaction was complete, it was allowed to cool to room temperature and then allowed to stand for 16 hours. Next, while cooling on ice, a solution of 203.3 g of dicyclohexylcarbodiimide (DCC) dissolved in 180 ml of γ-butyrolactone was added to the reaction mixture over a period of 40 minutes while stirring, and a suspension of 94.4 g of 2,2′-dimethylbiphenyl-4,4′-diamine (mTB) suspended in 300 mL of γ-butyrolactone was added over a period of 60 minutes while stirring. The reaction mixture was further stirred for 4 hours at room temperature, and then 50 mL of ethyl alcohol was added, stirring was continued for 1 hour, and 500 mL of γ-butyrolactone was added. The precipitate produced in the reaction mixture was removed off by filtration to obtain a reaction solution. The obtained reaction solution was added to 3 L of ethyl alcohol to form a precipitate comprising a crude polymer. The produced crude polymer was filtered and dissolved in 1.5 L of tetrahydrofuran to obtain a crude polymer solution. The obtained crude polymer solution was added dropwise into 28 L of water to precipitate the polymer, and after filtering the resulting precipitate, it was vacuum dried to obtain PI precursor resin A-1 as a powdered polyamic acid ester. The molecular weight of the PI precursor resin A-1 was measured by gel permeation chromatography (standard polystyrene equivalent), indicating a weight-average molecular weight (Mw) value of 30,000.

The weight-average molecular weight (Mw) of the PI precursor resin A-1 was measured by gel permeation chromatography (standard polystyrene equivalent) under the following conditions. The column used for measurement was a Shodex 805 M/806 M Series (trade name of Showa Denko K.K.), selecting standard monodisperse polystyrene, using N-methyl-2-pyrrolidone (NMP) as the developing solvent, and using Shodex RI-930 (trade name of Showa Denko K.K.) as the detector.

### Production Example 2

After placing 155.1 g of 4,4′-oxydiphthalic dianhydride (ODPA) in a 3 L separable flask, 135.4 g of 2-hydroxyethyl methacrylate (HEMA) and 400 mL of γ-butyrolactone were added, the mixture was stirred at room temperature, and 158.2 g of pyridine was added while stirring to obtain a reaction mixture. When heat release from the reaction was complete, it was allowed to cool to room temperature and allowed to stand for 16 hours. During subsequent cooling on ice, 130.9 g of thionyl chloride was added dropwise to an ODPA-HEMA solution over a period of 60 minutes while stirring, to obtain an acid chloride solution of ODPA. Next, a solution of 142.3 g of 2,2′-bis(trifluoromethyl)benzidine dissolved in 300 mL of NMP was added over a period of 60 minutes while stirring and cooling on ice. The reaction mixture was further stirred for 2 hours at room temperature, and then 50 mL of ethyl alcohol was added, stirring was continued for 1 hour, and 500 mL of γ-butyrolactone was added.

The obtained reaction solution was added to 3 L of ethyl alcohol to form a precipitate comprising a crude polymer. The produced crude polymer was filtered and dissolved in 1.5 L of tetrahydrofuran to obtain a crude polymer solution. The obtained crude polymer solution was added dropwise into 28 L of water to precipitate the polymer, and after filtering the resulting precipitate, it was vacuum dried to obtain PI precursor resin A-2 as a powdered polyamic acid ester. The molecular weight of the PI precursor resin A-2 was measured by the same method as Production Example 1, resulting in a weight-average molecular weight (Mw) of 28,000.

### Production Example 3

PI precursor resin A-3 was obtained by reaction in the same manner as Production Example 1 above, except that 93.0 g of 4,4′-diaminodiphenyl ether (DADPE) was used instead of the 94.4 g of 2,2′-dimethylbiphenyl-4,4′-diamine (mTB) in Production Example 1. The molecular weight of the PI precursor resin A-3 was measured by the same method as Production Example 1, resulting in a weight-average molecular weight (Mw) of 20,000.

### Production Example 4

PI precursor resin A-4 was obtained by reaction in the same manner as Production Example 3 above, except that 147.1 g of 3,3′,4,4′-biphenyltetracarboxylic dianhydride (BPDA) was used instead of the 155.1 g of 4,4′-oxydiphthalic dianhydride (ODPA) in Production Example 3, and the amount of 4,4′-diaminodiphenyl ether (DADPE) was changed to 90.1 g. The molecular weight of the PI precursor resin A-4 was measured by the same method as Production Example 1, resulting in a weight-average molecular weight (Mw) of 30,000.

### Production Example 5

PI precursor resin A-5 was obtained by reaction in the same manner as Production Example 3 above, except that 93.1 g of 4,4′-oxydiphthalic dianhydride (ODPA) and 58.8 g of 3,3′, 4,4′-biphenyltetracarboxylic dianhydride (BPDA) were used instead of the 155.1 g of 4,4′-oxydiphthalic dianhydride (ODPA) in Production Example 3, and the 93.0 g of 4,4′-diaminodiphenyl ether (DADPE) was changed to 87.6 g. The molecular weight of the PI precursor resin A-5 was measured by the same method as Production Example 1, resulting in a weight-average molecular weight (Mw) of 20,000.

### Production Example 6

PI precursor resin A-6 was obtained by reaction in the same manner as Production Example 1 above, except that 32.72 g of pyromellitic anhydride (PMDA) and 112.78 g of 3,3′,4,4′-benzophenonetetracarboxylic dianhydride were used instead of the 155.1 g of 4,4′-oxydiphthalic dianhydride (ODPA) in Production Example 1, and 85.10 g of 4,4′-diaminodiphenyl ether (DADPE) was used instead of the 94.4 g of 2,2′-dimethylbiphenyl-4,4′-diamine (mTB). The molecular weight of the PI precursor resin A-6 was measured by the same method as Production Example 1, resulting in a weight-average molecular weight (Mw) of 28,000.

### Production Example 7

PI precursor resin A-7 was obtained by reaction in the same manner as Production Example 2 above, except that 91.0 g of 2,2′-dimethylbiphenyl-4,4′-diamine (mTB) was used instead of the 142.3 g of 2,2′-bis(trifluoromethyl)benzidine in Production Example 2. The molecular weight of the PI precursor resin A-7 was measured by the same method as Production Example 1, resulting in a weight-average molecular weight (Mw) of 32,000.

### Production Example 8

After dissolving 47.1 g of 4,4′-oxydiphthalic dianhydride (ODPA), 5.54 g of 2-hydroxyethyl methacrylate (HEMA) and a catalytic amount of 1,4-diazabicyclo[2,2,2]octatriethylenediamine in 380 g of NMP, the mixture was stirred for 1 hour at 45° C. and then cooled to 25° C. This was followed by addition of 27.4 g of 2,2′-dimethylbiphenyl-4,4′-diamine (mTB) and 145 mL of NMP, and the mixture was stirred for 150 minutes at 45° C. and cooled to room temperature. To this solution there was added dropwise 59.7 g of trifluoroacetic anhydride, the mixture was stirred for 120 minutes, and then a catalytic amount of benzoquinone and 40.4 g of HEMA were added and stirring was continued for 20 hours at 45° C. The reaction solution was added dropwise into distilled water, and the precipitate was filtered and collected and dried under reduced pressure to obtain PI precursor resin A-8. The molecular weight of the PI precursor resin A-8 was measured by the same method as Production Example 1, resulting in a weight-average molecular weight (Mw) of 35,000.

### <Synthesis Example for Exposure Ray Absorber (B)>

### Synthesis Example 1

### Synthesis of Compound B-1 Having 1,2-Naphthoquinonediazide Structure

In a 1 L separable flask equipped with a stirrer, dropping funnel and thermometer there was placed 30.0 g (0.707 mol) of 4,4′-(1-(2-(4-hydroxyphenyl)-2-propyl)phenyl)ethylidene)bisphenol (Tris-PA, trade name of Honshu Chemical Industry Co., Ltd.) represented by the following formula (21), as a hydroxy compound.

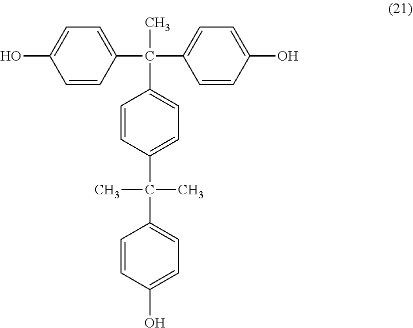 [SMILES: CC(C)(c1ccc(O)cc1)c1ccc(C(C)(c2ccc(O)cc2)c2ccc(O)cc2)cc1]

After stirring and dissolving 53.56 g (0.198 mol) of 1,2-naphthoquinonediazide-5-sulfonic acid chloride, as an amount corresponding to 93.3 mol % of the OH groups of the hydroxy compound, in 300 g of acetone, the solution was placed in the flask and the flask was adjusted to 30° C. with a thermostatic bath. Next, 20.0 g of triethylamine was dissolved in 18 g of acetone and the mixture was loaded into a dropping funnel and then added dropwise into the flask over a period of 30 minutes. Upon completion of the dropwise addition, stirring was continued for another 30 minutes, and then hydrochloric acid was added dropwise and the mixture was further stirred for 30 minutes to halt the reaction. The reaction product was then filtered to remove the triethylamine hydrochloride. In a 3 L beaker there were mixed and stirred 1640 g of purified water and 30 g of hydrochloric acid, and the filtrate was added dropwise into this mixture while stirring to obtain a precipitate. The precipitate was washed and filtered, and then dried for 48 hours under reduced pressure at 40° C. to obtain a photosensitive diazonaphthoquinone (B-1).

### Synthesis Example 2

### Synthesis of Compound B-2 Having 1,2-Naphthoquinonediazide Structure

Photosensitive diazonaphthoquinone (B-2) was obtained by reaction and purification in the same manner as described for Synthesis Example 1, except that 47.82 g (0.177 mol) of 1,2-naphthoquinonediazide-4-sulfonic acid chloride was used instead of the 53.56 g (0.198 mol) of 1,2-naphthoquinonediazide-5-sulfonic acid chloride in Synthesis Example 1.

### Synthesis Example 3

### Synthesis of Compound B-3 Having 1,2-Naphthoquinonediazide Structure

Photosensitive diazonaphthoquinone (B-3) was obtained by reaction and purification in the same manner as described for Synthesis Example 1, except that the 53.56 g (0.198 mol) of 1,2-naphthoquinonediazide-5-sulfonic acid chloride in Synthesis Example 1 was reduced to 38.26 g (0.141 mol).

### Synthesis Example 4

### Synthesis of Compound B-4 Having 1,2-Naphthoquinonediazide Structure

In a 1 L separable flask equipped with a stirrer, dropping funnel and thermometer there was placed 30 g (0.141 mol) of p-cumylphenol represented by the following formula (20) (Mitsui Fine Chemicals, Inc.), as a hydroxy compound.

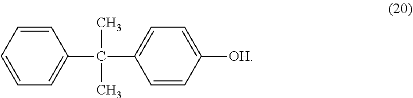 [SMILES: CC(C)(c1ccccc1)c1ccc(O)cc1]

After stirring and dissolving 38.1 g (0.141 mol) of 1,2-naphthoquinonediazide-5-sulfonic acid chloride, as an amount corresponding to 100 mol % of the OH groups of the hydroxy compound, in 300 g of acetone, the solution was placed in the flask and the flask was adjusted to 30° C. with a thermostatic bath. Next, 17.9 g of triethylamine was dissolved in 18 g of acetone and the mixture was loaded into a dropping funnel and then added dropwise into the flask over a period of 30 minutes. Upon completion of the dropwise addition, stirring was continued for another 30 minutes, and then hydrochloric acid was added dropwise and the mixture was further stirred for 30 minutes to halt the reaction. The reaction product was then filtered to remove the triethylamine hydrochloride. In a 3 L beaker there were mixed and stirred 1640 g of purified water and 30 g of hydrochloric acid, and the filtrate was added dropwise into this mixture while stirring to obtain a precipitate. The precipitate was washed and filtered, and then dried for 48 hours under reduced pressure at 40° C. to obtain a photosensitive diazonaphthoquinone (B-4).

### Synthesis Example 5

### Synthesis of Compound B-5 Having 1,2-Naphthoquinonediazide Structure

Photosensitive diazonaphthoquinone (B-5) was obtained by reaction and purification in the same manner as described for Synthesis Example 4, except that 38.1 g (0.141 mol) of 1,2-naphthoquinonediazide-4-sulfonic acid chloride was used instead of the 38.1 g (0.141 mol) of 1,2-naphthoquinonediazide-5-sulfonic acid chloride in Synthesis Example 4.

### Synthesis Example 6

### Synthesis of Compound B-6 Having 1,2-Naphthoquinonediazide Structure

In a 1 L separable flask equipped with a stirrer, dropping funnel and thermometer there was placed 30 g (0.0474 mol) of the compound represented by the following formula (29) (Tekoc-4HBPA, trade name of Honshu Chemical Industry Co., Ltd.), as a hydroxy compound.

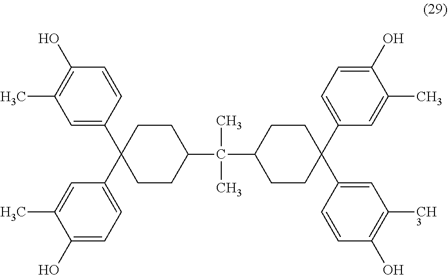

After stirring and dissolving 42.1 g (0.155 mol) of 1,2-naphthoquinonediazide-5-sulfonic acid chloride, as an amount corresponding to 80 mol % of the OH groups of the hydroxy compound, in 300 g of acetone, the solution was placed in the flask and the flask was adjusted to 30° C. with a thermostatic bath. Next, 15.4 g of triethylamine was dissolved in 15 g of acetone and the mixture was loaded into a dropping funnel and then added dropwise into the flask over a period of 30 minutes. Upon completion of the dropwise addition, stirring was continued for another 30 minutes, and then hydrochloric acid was added dropwise and the mixture was further stirred for 30 minutes to halt the reaction. The reaction product was filtered to remove the triethylamine hydrochloride. In a 3 L beaker there were mixed and stirred 1640 g of purified water and 22 g of hydrochloric acid, and the filtrate was added dropwise into this mixture while stirring to obtain a precipitate. The precipitate was washed and filtered, and then dried for 48 hours under reduced pressure at 40° C. to obtain a photosensitive diazonaphthoquinone (B-6).

### Synthesis Example 7

### Synthesis of Compound B-7 Having 1,2-Naphthoquinonediazide Structure

In a 1 L separable flask equipped with a stirrer, dropping funnel and thermometer there was placed 30 g (0.131 mol) of 2,2-bis(4-hydroxyphenyl)propane represented by the following formula (30), as a hydroxy compound.

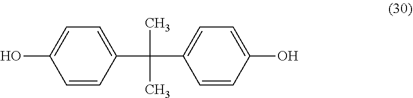 [SMILES: CC(C)(c1ccc(O)cc1)c1ccc(O)cc1]

After stirring and dissolving 71.14 g (0.263 mol) of 1,2-naphthoquinonediazide-5-sulfonic acid chloride, as an amount corresponding to 100 mol % of the OH groups of the hydroxy compound, in 300 g of acetone, the solution was placed in the flask and the flask was adjusted to 30° C. with a thermostatic bath. Next, 26.6 g of triethylamine was dissolved in 30 g of acetone and the mixture was loaded into a dropping funnel and then added dropwise into the flask over a period of 30 minutes. Upon completion of the dropwise addition, stirring was continued for another 30 minutes, and then hydrochloric acid was added dropwise and the mixture was further stirred for 30 minutes to halt the reaction. The reaction product was filtered to remove the triethylamine hydrochloride. In a 3 L beaker there were mixed and stirred 1640 g of purified water and 22 g of hydrochloric acid, and the filtrate was added dropwise into this mixture while stirring to obtain a precipitate. The precipitate was washed and filtered, and then dried for 48 hours under reduced pressure at 40° C. to obtain a photosensitive diazonaphthoquinone (B-7).

### Synthesis Example 8

### Synthesis of Compound B-8 Having 1,2-Naphthoquinonediazide Structure

Photosensitive diazonaphthoquinone (B-8) was obtained by reaction and purification in the same manner as described for Synthesis Example 1, except that the 53.56 g (0.198 mol) of 1,2-naphthoquinonediazide-5-sulfonic acid chloride in Synthesis Example 1 was reduced to 47.82 g (0.177 mol).

### Synthesis Example 9

### Synthesis of Compound B-13 Having 1,2-Naphthoquinonediazide Structure

In a 1 L separable flask equipped with a stirrer, dropping funnel and thermometer there was placed 30 g (0.277 mol) of p-cresol represented by the following formula (31), as a hydroxy compound.

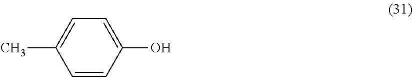

After stirring and dissolving 75.1 g (0.277 mol) of 1,2-naphthoquinonediazide-5-sulfonic acid chloride, as an amount corresponding to 100 mol % of the OH groups of the hydroxy compound, in 300 g of acetone, the solution was placed in the flask and the flask was adjusted to 30° C. with a thermostatic bath. Next, 28.1 g of triethylamine was dissolved in 30 g of acetone and the mixture was loaded into a dropping funnel and then added dropwise into the flask over a period of 30 minutes. Upon completion of the dropwise addition, stirring was continued for another 30 minutes, and then hydrochloric acid was added dropwise and the mixture was further stirred for 30 minutes to halt the reaction. The reaction product was filtered to remove the triethylamine hydrochloride. In a 3 L beaker there were mixed and stirred 1600 g of purified water and 22 g of hydrochloric acid, and the filtrate was added dropwise into this mixture while stirring to obtain a precipitate. The precipitate was washed and filtered, and then dried for 48 hours under reduced pressure at 40° C. to obtain a photosensitive diazonaphthoquinone (B-13).

### I. Examples 1 to 32 and Comparative Examples 1 to 26

### <Deciding Compositional Ratio for Polyimide Precursor Resin Compositions>

### Example 1

The type of light for exposure was decided to be i-line. The resins listed in Table 4 were selected as polyimide precursor resins (A) having an absorbance parameter Xp in the range of 0.001 to 0.20. The compounds listed in Table 4 were selected as exposure ray absorbers having an absorbance parameter Xt in the range of 0.01 to 0.05. The compounds listed in Table 4 were also selected as photopolymerization initiators (C) having an absorbance parameter Xr in the range of 0 to 0.04. The assumed thickness D of the prebaked film was set to 10 μm. The values for α and β were decided to be the mass fractions listed in Table 4, satisfying “0.7≤(Xp+Xt×α+Xr×β)×D≤2.2”. The (Xp+Xt×α+Xr×β)×D values were as listed in Table 5.

### Examples 2 to 32

The compositional ratio for each polyimide precursor resin composition was decided in the same manner as Example 1.

### <Preparation of Polyimide Precursor Resin Compositions>

### Examples 1 to 32 and Comparative Examples 1 to 26

The polyimide precursor resin (A), the exposure ray absorber (B), the photopolymerization initiator (C), the photopolymerizable compound (E), the hindered phenol compound (F) and the polymerization inhibitor (G) in the contents shown in Tables 4 and 6 were dissolved in a mixed solvent of γ-butyrolactone and DMSO as the solvent (D) (80:20 weight ratio), to prepare PI precursor resin compositions for Examples 1 to 32 and Comparative Examples 1 to 26. The contents in Tables 4 and 6 are mass fractions for each component with component (A) as 100 parts by mass. The viscosity of the obtained solution was adjusted to approximately 40 poise by further adding a small amount of the mixed solvent, and then filtered using a polyethylene filter with 0.2 μm pores, to obtain a resin composition. The denotations in the tables indicate the following components.

The following (A-1) to (A-8) were used for the polyimide precursor resin (A).
(A-1): Compound obtained in Production Example 1
(A-2): Compound obtained in Production Example 2
(A-3): Compound obtained in Production Example 3
(A-4): Compound obtained in Production Example 4
(A-5): Compound obtained in Production Example 5
(A-6): Compound obtained in Production Example 6
(A-7): Compound obtained in Production Example 7
(A-8): Compound obtained in Production Example 8

The following (B-1) to (B-13) were used for the exposure ray absorber (B).
(B-1): Diazonaphthoquinone compound obtained in Synthesis Example 1
(B-2): Diazonaphthoquinone compound obtained in Synthesis Example 2
(B-3): Diazonaphthoquinone compound obtained in Synthesis Example 3
(B-4): Diazonaphthoquinone compound obtained in Synthesis Example 4
(B-5): Diazonaphthoquinone compound obtained in Synthesis Example 5
(B-6): Diazonaphthoquinone compound obtained in Synthesis Example 6
(B-7): Diazonaphthoquinone compound obtained in Synthesis Example 7
(B-8): Diazonaphthoquinone compound obtained in Synthesis Example 8
(B-9): 2-(2H-Benzotriazol-2-yl)-4-(1,1,3,3-tetramethylbutyl)phenol (trade name: ADEKASTAB LA-29 by Adeka Corp.)
(B-10): 2,2′,4,4′-Tetrahydroxybenzophenone (trade name: SEESORB106 by Shipro Kasei Co., Ltd.)
(B-11): Curcumin (Tokyo Kasei Kogyo Co., Ltd.)
(B-12): 2-(2′-Hydroxy-5′-methylphenyl)benzotriazole (trade name: JF-77 by Johoku Chemical Industry Co., Ltd.)
(B-13): Diazonaphthoquinone compound obtained in Synthesis Example 9

The following (C-1) to (C-4) were used for the photopolymerization initiator (C).
(C-1): 1-Phenyl-1,2-propanedione-2-[O-(ethoxycarbonyl)oxime] (trade name: Quantacure-PDO by Nippon Kayaku Co., Ltd.)
(C-2): 1,2-Octanedione-1-[4-(phenylthio)phenyl]-2-(O-benzoyloxime) (trade name: IRGACURE-OXE-01 by BASF Corp.)
(C-3): 1-[9-Ethyl-6-(2-methylbenzoyl)-9H-carbazol-3-yl]-ethanone-1-(O-acetyloxime) (trade name: IRGACURE OXE-02 by BASF Corp.)
(C-4): N-Phenylglycine (Tokyo Kasei Kogyo Co., Ltd.)

The following (E-1) was used for the photopolymerizable compound (E).
(E-1): Tetraethyleneglycol dimethacrylate (Tokyo Kasei Kogyo Co., Ltd.)

The following components were also used.
(F) 1,3,5-tris(4-t-Butyl-3-hydroxy-2,6-dimethylbenzyl)-1,3,5-triazine-2,4,6-(1H,3H,5H)-trione
(G) 2-Nitroso-1-naphthol

The following (H-1) to (H-2) were used for the nitrogen-containing heterocyclic rust inhibitor (H).
(H-1): 8-Azaadenine (Tokyo Kasei Kogyo Co., Ltd.)
(H-2): 5-Amino-1H-tetrazole (Tokyo Kasei Kogyo Co., Ltd.)

### <Measurement of Absorbance Parameters>

### <Measurement of Absorbance Parameter Xp of Polyimide Precursor Resin (A)>

The absorbance (absorbance parameter Xp) for each of A-1 to A-8 was measured under the following conditions. Each of A-1 to A-8 was dissolved in NMP and adjusted to 1000 mg/L to prepare a measuring sample. The measuring apparatus used was an ultraviolet and visible spectrophotometer (UV-1800 by Shimadzu Corp.), using a 1 cm cell for the measurement. The 365 nm absorbance of each sample was divided by 10 to obtain Xp.

TABLE 1

| | Xp |
|---|---|
| A-1 | 0.028 |
| A-2 | 0.016 |
| A-3 | 0.020 |
| A-4 | 0.131 |
| A-5 | 0.060 |
| A-6 | 0.194 |
| A-7 | 0.005 |
| A-8 | 0.015 |

### <Measurement of Absorbance Parameter Xt of Exposure Ray Absorber (B)>

The absorbance (absorbance parameter Xt) for each of B-1 to B-13 was measured under the following conditions. Each component (B) was dissolved in NMP and adjusted to 10 mg/L to prepare a measuring sample. The measuring apparatus used was an ultraviolet and visible spectrophotometer (UV-1800 by Shimadzu Corp.), using a 1 cm cell for the measurement. The 365 nm absorbance of each sample was divided by 10 to obtain Xt.

TABLE 2

| | Xt |
|---|---|
| B-1 | 0.021 |
| B-2 | 0.019 |
| B-3 | 0.019 |
| B-4 | 0.019 |
| B-5 | 0.018 |
| B-6 | 0.019 |
| B-7 | 0.023 |
| B-8 | 0.021 |
| B-9 | 0.023 |
| B-10 | 0.040 |
| B-11 | 0.025 |
| B-12 | 0.032 |
| B-13 | 0.028 |

### <Measurement of Absorbance Parameter Xr of Photopolymerization Initiator (C)>

The absorbance (absorbance parameter Xr) for each of C-1 to C-4 was measured under the following conditions. Each component (C) was dissolved in NMP and adjusted to 10 mg/L to prepare a measuring sample. The measuring apparatus used was an ultraviolet and visible spectrophotometer (UV-1800 by Shimadzu Corp.), using a 1 cm cell for the measurement. The 365 nm absorbance of each sample was divided by 10 to obtain Xr.

TABLE 3

| | Xr |
|---|---|
| C-1 | 0.000 |
| C-2 | 0.009 |
| C-3 | 0.009 |
| C-4 | 0.001 |

### <Production and Evaluation of Relief Pattern Films>

A sputtering apparatus (Model L-440S-FHL, product of Canon Anelva Corp.) was used for sputtering of Ti to a 200 nm thickness and Cu to a 400 nm thickness, in that order, on a 6-inch wafer (product of Fujimi Denshi Kogyo, thickness: 625±25 μm), to prepare a sputtered Cu wafer substrate. The PI precursor resin composition was spin coated onto the sputtered Cu wafer substrate using a spin coater (Model D-SPIN60A by Sokudo Co.), and was then dried on a hot plate for 180 seconds at 100° C. to fabricate a prebaked film with a thickness of 10.0 μm±0.2 μm (D′). The spin coated film was exposed with a Prisma GHI S/N5503 1:1 projection exposure system (product of Ultratech Co.) using a test pattern reticle with a round concave 10 μm diameter pattern, and using a mounted gh-line cut filter to vary the exposure dose from 30 mJ/cm2 to 210 mJ/cm2 in 15 mJ/cm2 increments. The coating film formed on the sputtering Cu wafer was then subjected to spray development with a developing machine (Model D-SPIN 636 by Dainippon Screen Mfg. Co., Ltd.) using cyclopentanone, and rinsed with propyleneglycol methyl ether acetate to obtain a polyamic acid ester pattern. The developing time for spray development was defined as 1.4× the minimum time required to develop the resin composition at the unexposed sections for a 10.0 μm spin coated film.

### <Evaluation of Tapered Pattern Form>

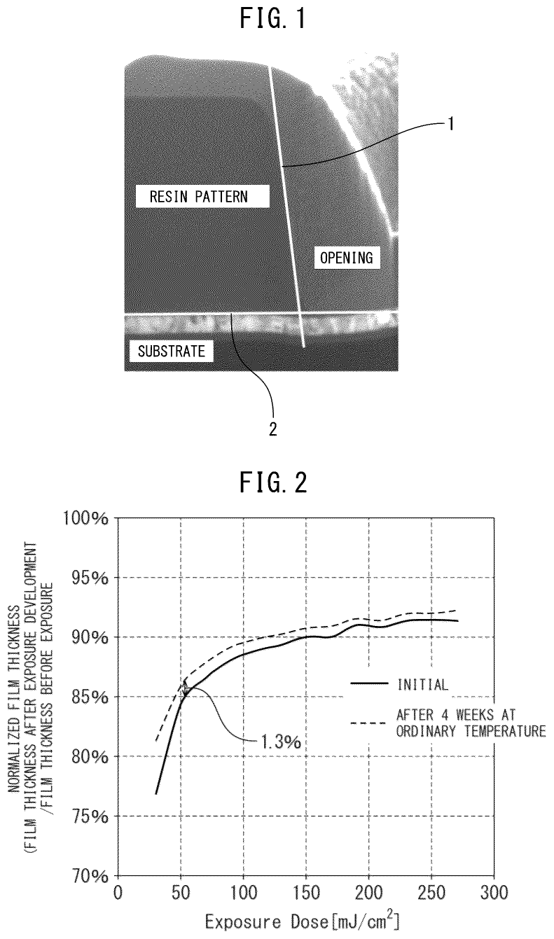

A cross-section was cut out from the obtained round concave 10 μm diameter pattern using an FIB apparatus (JIB-4000 by JEOL Corp.) and the cross-sectional shape of the pattern was observed, measuring the taper angle of the pattern with respect to the substrate, as a slope at the tapering midpoint. The pattern cross-sectional shape was evaluated as Excellent (AA) for a taper angle of 70° to 80°, Good (A) for 80° to 90°, and Unacceptable (D) for other angles. Samples with undercutting or bridging at the pattern cross-section were also evaluated as Unacceptable. FIG. 1 shows an FIB photograph of the pattern cross-sectional shape obtained in Example 1. FIG. 1 also shows an auxiliary line (1) indicating the slope at the midpoint of the pattern. The taper angle of the pattern obtained in Example 1 with respect to the substrate (auxiliary line (2)) was 82°. Samples with unacceptable pattern form in the tapered form evaluation were not assessed in the following maximum resolution or sensitivity tolerance evaluations.

### <Maximum Resolution Evaluation>

The round concave diameter was changed, and the minimum mask dimension for the obtained round concave relief pattern was recorded at the maximum resolution (μm) and evaluated on the following scale.
A: Pattern of <5 μm opened
B: Pattern of ≥5 μm and <6 μm opened
C: Pattern of ≥6 μm and <8 μm opened
D: Pattern of <8 μm not opened

It was determined that the round concave relief pattern opened if both of the following conditions (I) and (II) were satisfied.
(I) The area of the pattern openings was at least ½ of the corresponding pattern mask open area.
(II) The pattern cross-section had no bottom trailing and was free of undercuts, swelling and bridging.

### <Sensitivity Tolerance Evaluation>

The range of exposure dose with which 8 μm diameter openings were observed in the obtained round concave relief pattern was evaluated on the following scale.
A: Opening of 8 μm pattern with exposure dose width of 105 mJ/cm2 or greater
B: Opening of 8 μm pattern with exposure dose width of 45 mJ/cm2 or greater and less than 105 mJ/cm2
C: Opening of 8 μm pattern with exposure dose width of 15 mJ/cm2 or greater and less than 45 mJ/cm²
D: Pinpoint opening or no opening of 8 μm pattern

TABLE 4

| | | (A) PI precursor | | (B) Exposure | | (C) Photopolymerization | | | | (E) Photopolymerizable | | | |
|---|---|---|---|---|---|---|---|---|---|---|---|---|---|
| | | resin | | ray absorber | | initiator | | | | crosslinking agent | | (F) | (G) |
| | D | | Mass | | Mass | | Mass | | Mass | | Mass | Mass | Mass |
| | (μm) | Type | fraction | Type | fraction | Type | fraction | Type | fraction | Type | fraction | fraction | fraction |
| Example 1 | 10 | A-1 | 100 | B-1 | 7 | C-2 | 2 | — | — | E-1 | 10 | 0.50 | 0.05 |
| Example 2 | 10 | A-1 | 100 | B-1 | 5 | C-2 | 2 | — | — | E-1 | 10 | 0.50 | 0.05 |
| Example 3 | 10 | A-1 | 100 | B-1 | 5 | C-1 | 4 | — | — | E-1 | 10 | 0.50 | 0.05 |
| Example 4 | 10 | A-1 | 100 | B-1 | 5 | C-3 | 2 | — | — | E-1 | 10 | 0.50 | 0.05 |
| Example 5 | 10 | A-1 | 100 | B-1 | 2 | C-2 | 2 | — | — | E-1 | 10 | 0.50 | 0.05 |
| Example 6 | 10 | A-1 | 100 | B-2 | 5 | C-2 | 2 | — | — | E-1 | 10 | 0.50 | 0.05 |
| Example 7 | 10 | A-1 | 100 | B-3 | 5 | C-2 | 2 | — | — | E-1 | 10 | 0.50 | 0.05 |
| Example 8 | 10 | A-1 | 100 | B-4 | 5 | C-2 | 2 | — | — | E-1 | 10 | 0.50 | 0.05 |
| Example 9 | 10 | A-1 | 100 | B-5 | 5 | C-2 | 2 | — | — | E-1 | 10 | 0.50 | 0.05 |
| Example 10 | 10 | A-1 | 100 | B-6 | 5 | C-2 | 2 | — | — | E-1 | 10 | 0.50 | 0.05 |
| Example 11 | 10 | A-1 | 100 | B-7 | 5 | C-2 | 2 | — | — | E-1 | 10 | 0.50 | 0.05 |
| Example 12 | 10 | A-2 | 100 | B-1 | 5 | C-2 | 2 | — | — | E-1 | 10 | 0.50 | 0.05 |
| Example 13 | 10 | A-2 | 100 | B-2 | 5 | C-2 | 2 | — | — | E-1 | 10 | 0.50 | 0.05 |
| Example 14 | 10 | A-2 | 100 | B-3 | 5 | C-2 | 2 | — | — | E-1 | 10 | 0.50 | 0.05 |
| Example 15 | 10 | A-2 | 100 | B-4 | 5 | C-2 | 2 | — | — | E-1 | 10 | 0.50 | 0.05 |
| Example 16 | 10 | A-2 | 100 | B-5 | 5 | C-2 | 2 | — | — | E-1 | 10 | 0.50 | 0.05 |
| Example 17 | 10 | A-3 | 100 | B-1 | 5 | C-2 | 2 | — | — | E-1 | 10 | 0.50 | 0.05 |
| Example 18 | 10 | A-3 | 100 | B-1 | 3 | C-2 | 2 | — | — | E-1 | 10 | 0.50 | 0.05 |
| Example 19 | 10 | A-3 | 100 | B-3 | 5 | C-2 | 2 | — | — | E-1 | 10 | 0.50 | 0.05 |
| Example 20 | 10 | A-4 | 100 | B-1 | 1 | C-2 | 2 | — | — | E-1 | 10 | 0.50 | 0.05 |
| Example 21 | 10 | A-3 | 60 | B-1 | 5 | C-2 | 2 | — | — | E-1 | 10 | 0.50 | 0.05 |
| | | A-4 | 40 | | | | | | | | | | |
| Example 22 | 10 | A-3 | 60 | B-1 | 2 | C-2 | 2 | — | — | E-1 | 10 | 0.50 | 0.05 |
| | | A-4 | 40 | | | | | | | | | | |
| Example 23 | 10 | A-5 | 100 | B-1 | 5 | C-2 | 2 | — | — | E-1 | 10 | 0.50 | 0.05 |
| Example 24 | 10 | A-5 | 100 | B-1 | 2 | C-2 | 2 | — | — | E-1 | 10 | 0.50 | 0.05 |
| Example 25 | 10 | A-1 | 100 | B-11 | 2 | C-2 | 2 | — | — | E-1 | 10 | 0.50 | 0.05 |
| Example 26 | 10 | A-1 | 100 | B-12 | 2 | C-2 | 2 | — | — | E-1 | 10 | 0.50 | 0.05 |
| Example 27 | 10 | A-5 | 100 | B-9 | 1 | C-2 | 2 | — | — | E-1 | 10 | 0.50 | 0.05 |
| Example 28 | 10 | A-5 | 100 | B-10 | 1 | C-2 | 2 | — | — | E-1 | 10 | 0.50 | 0.05 |
| Example 29 | 10 | A-7 | 100 | B-1 | 2.5 | C-2 | 2 | — | — | E-1 | 10 | 0.50 | 0.05 |
| Example 30 | 10 | A-8 | 100 | B-1 | 4 | C-2 | 2 | — | — | E-1 | 10 | 0.50 | 0.05 |
| Example 31 | 10 | A-4 | 100 | B-1 | 3 | C-2 | 2 | — | — | E-1 | 10 | 0.50 | 0.05 |
| Example 32 | 10 | A-1 | 100 | B-8 | 4 | C-2 | 2 | — | — | E-1 | 10 | 0.50 | 0.05 |

TABLE 5

| | | D′ | | Taper | Maximum | Sensitivity |
|---|---|---|---|---|---|---|
| | (Xp + Xt*α + Xr*β)*D | (um) | (Xp + Xt*α + Xr*β)*D' | form | resolution | tolerance |
| Example 1 | 1.93 | 10 | 1.93 | A | A | A |
| Example 2 | 1.51 | 10 | 1.51 | A | A | A |
| Example 3 | 1.33 | 9.9 | 1.32 | AA | A | A |
| Example 4 | 1.51 | 10 | 1.51 | A | A | A |
| Example 5 | 0.88 | 10 | 0.88 | AA | A | B |
| Example 6 | 1.41 | 10 | 1.41 | A | A | B |
| Example 7 | 1.41 | 10 | 1.41 | A | B | A |
| Example 8 | 1.41 | 10 | 1.41 | A | B | A |
| Example 9 | 1.36 | 10 | 1.36 | AA | B | B |
| Example 10 | 1.41 | 10.2 | 1.44 | A | B | A |
| Example 11 | 1.61 | 10 | 1.61 | A | B | A |
| Example 12 | 1.39 | 10 | 1.39 | AA | A | A |
| Example 13 | 1.29 | 9.9 | 1.28 | AA | A | B |
| Example 14 | 1.29 | 10 | 1.29 | AA | B | A |
| Example 15 | 1.29 | 10 | 1.29 | AA | B | A |
| Example 16 | 1.24 | 10.1 | 1.25 | AA | B | B |
| Example 17 | 1.43 | 10 | 1.43 | A | B | A |
| Example 18 | 1.01 | 10 | 1.01 | AA | B | C |
| Example 19 | 1.33 | 10 | 1.33 | AA | B | C |
| Example 20 | 1.70 | 10.2 | 1.73 | A | B | B |
| Example 21 | 1.87 | 10 | 1.87 | A | B | A |
| Example 22 | 1.24 | 10 | 1.24 | AA | B | B |
| Example 23 | 1.83 | 10 | 1.83 | A | B | A |
| Example 24 | 1.20 | 10 | 1.20 | AA | B | B |
| Example 25 | 0.96 | 10 | 0.96 | AA | B | C |
| Example 26 | 1.10 | 10 | 1.10 | AA | B | B |
| Example 27 | 1.01 | 10 | 1.01 | AA | B | C |
| Example 28 | 1.18 | 10 | 1.18 | AA | B | C |
| Example 29 | 0.76 | 10 | 0.76 | AA | A | B |
| Example 30 | 1.17 | 10 | 1.17 | AA | A | A |
| Example 31 | 2.12 | 10.1 | 2.14 | A | B | B |
| Example 32 | 1.30 | 9.9 | 1.29 | AA | A | A |

TABLE 6

| | | (A) PI precursor | | (B) Exposure | | (C) Photopolymerization | | | | (E) Photopolymerizable | | | |
|---|---|---|---|---|---|---|---|---|---|---|---|---|---|
| | | resin | | ray absorber | | initiator | | | | crosslinking agent | | | |
| | D | | Mass | | Mass | | Mass | | Mass | | Mass | (F) Mass | (G) Mass |
| | (μm) | Type | fraction | Type | fraction | Type | fraction | Type | fraction | Type | fraction | fraction | fraction |
| Comp. Ex. 1 | 10 | A-1 | 100 | B-1 | 10 | C-2 | 2 | — | — | E-1 | 10 | 0.50 | 0.05 |
| Comp. Ex. 2 | 10 | A-1 | 100 | B-1 | 1 | C-2 | 2 | — | — | E-1 | 10 | 0.50 | 0.05 |
| Comp. Ex. 3 | 10 | A-1 | 100 | — | — | C-2 | 7 | — | — | E-1 | 10 | 0.50 | 0.05 |
| Comp. Ex. 4 | 10 | A-1 | 100 | B-1 | 5 | — | — | — | — | E-1 | 10 | 0.50 | 0.05 |
| Comp. Ex. 5 | 10 | A-2 | 100 | B-1 | 10 | C-2 | 3 | — | — | E-1 | 10 | 0.50 | 0.05 |
| Comp. Ex. 6 | 10 | A-2 | 100 | — | — | C-2 | 2 | — | — | E-1 | 10 | 0.50 | 0.05 |
| Comp. Ex. 7 | 10 | A-2 | 100 | B-1 | 1 | C-2 | 2 | — | — | E-1 | 10 | 0.50 | 0.05 |
| Comp. Ex. 8 | 10 | A-3 | 100 | B-1 | 10 | C-2 | 2 | — | — | E-1 | 10 | 0.50 | 0.05 |
| Comp. Ex. 9 | 10 | A-3 | 100 | B-1 | 5 | — | — | — | — | E-1 | 10 | 0.50 | 0.05 |
| Comp. Ex. 10 | 10 | A-3 | 100 | — | — | C-2 | 2 | — | — | E-1 | 10 | 0.50 | 0.05 |
| Comp. Ex. 11 | 10 | A-3 | 100 | B-1 | 1 | C-2 | 2 | — | — | E-1 | 10 | 0.50 | 0.05 |
| Comp. Ex. 12 | 10 | A-4 | 100 | B-1 | 5 | C-2 | 2 | — | — | E-1 | 10 | 0.50 | 0.05 |
| Comp. Ex. 13 | 10 | A-3 | 60 | B-1 | 10 | C-2 | 2 | — | — | E-1 | 10 | 0.50 | 0.05 |
| | | A-4 | 40 | | | | | | | | | | |
| Comp. Ex. 14 | 10 | A-5 | 100 | B-1 | 10 | C-2 | 2 | — | — | E-1 | 10 | 0.50 | 0.05 |
| Comp. Ex. 15 | 10 | A-6 | 100 | B-7 | 5 | C-4 | 8 | — | — | E-1 | 10 | 0.50 | 0.05 |
| Comp. Ex. 16 | 10 | A-6 | 100 | B-7 | 3 | C-1 | 4 | — | — | E-1 | 10 | 0.50 | 0.05 |
| Comp. Ex. 17 | 10 | A-1 | 100 | B-9 | 1 | C-3 | 0.2 | C-1 | 3 | E-1 | 10 | 0.50 | 0.05 |
| Comp. Ex. 18 | 10 | A-1 | 100 | B-10 | 0.5 | C-3 | 0.2 | C-1 | 3 | E-1 | 10 | 0.50 | 0.05 |
| Comp. Ex. 19 | 10 | A-1 | 100 | B-11 | 1 | C-3 | 0.5 | — | — | E-1 | 10 | 0.50 | 0.05 |
| Comp. Ex. 20 | 10 | A-7 | 100 | B-12 | 1 | C-1 | 7 | C-3 | 0.2 | E-1 | 10 | 0.50 | 0.05 |
| Comp. Ex. 21 | 10 | A-8 | 100 | B-11 | 1 | C-1 | 6 | C-3 | 0.4 | E-1 | 10 | 0.50 | 0.05 |
| Comp. Ex. 22 | 10 | A-8 | 100 | B-12 | 1 | C-1 | 7 | C-3 | 0.2 | E-1 | 10 | 0.50 | 0.05 |
| Comp. Ex. 23 | 10 | A-8 | 100 | B-9 | 1 | C-1 | 7 | C-3 | 0.2 | E-1 | 10 | 0.50 | 0.05 |
| Comp. Ex. 24 | 10 | A-8 | 100 | B-10 | 0.5 | C-1 | 3 | C-3 | 0.2 | E-1 | 10 | 0.50 | 0.05 |
| Comp. Ex. 25 | 10 | A-6 | 100 | B-13 | 1 | C-2 | 2 | — | — | E-1 | 10 | 0.50 | 0.05 |
| Comp. Ex. 26 | 10 | A-3 | 100 | B-8 | 10 | C-2 | 3 | — | — | E-1 | 10 | 0.50 | 0.05 |

TABLE 7

| | | | | Taper | Maximum | Sensitivity |
|---|---|---|---|---|---|---|
| | (Xp + Xt*α + Xr*β)*D | D′ | (Xp + Xt*α + Xr*β)*D' | form | resolution | tolerance |
| Comp. Ex. 1 | 2.56 | 10.0 | 2.56 | D | — | — |
| Comp. Ex. 2 | 0.67 | 10.0 | 0.67 | AA | B | D |
| Comp. Ex. 3 | 0.91 | 10.0 | 0.91 | AA | B | D |
| Comp. Ex. 4 | 1.33 | 10.0 | 1.33 | D | — | — |
| Comp. Ex. 5 | 2.53 | 9.9 | 2.50 | D | — | — |
| Comp. Ex. 6 | 0.34 | 10.0 | 0.34 | AA | C | D |
| Comp. Ex. 7 | 0.55 | 10.1 | 0.56 | AA | B | D |
| Comp. Ex. 8 | 2.48 | 10.0 | 2.48 | D | — | — |
| Comp. Ex. 9 | 1.25 | 10.0 | 1.25 | D | — | — |
| Comp. Ex. 10 | 0.38 | 9.8 | 0.37 | AA | D | D |
| Comp. Ex. 11 | 0.59 | 10.0 | 0.59 | AA | C | D |
| Comp. Ex. 12 | 2.54 | 10.0 | 2.54 | D | — | — |
| Comp. Ex. 13 | 2.92 | 10.0 | 2.92 | D | — | — |
| Comp. Ex. 14 | 2.88 | 10.0 | 2.88 | D | — | — |
| Comp. Ex. 15 | 3.17 | 10.2 | 3.23 | D | — | — |
| Comp. Ex. 16 | 2.63 | 10.0 | 2.63 | D | — | — |
| Comp. Ex. 17 | 0.53 | 10.0 | 0.53 | AA | C | D |
| Comp. Ex. 18 | 0.50 | 10.0 | 0.50 | AA | C | D |
| Comp. Ex. 19 | 0.58 | 10.0 | 0.58 | AA | C | D |
| Comp. Ex. 20 | 0.39 | 10 | 0.39 | AA | C | D |
| Comp. Ex. 21 | 0.44 | 10.1 | 0.44 | AA | C | D |
| Comp. Ex. 22 | 0.49 | 10 | 0.49 | AA | C | D |
| Comp. Ex. 23 | 0.40 | 10 | 0.40 | AA | C | D |
| Comp. Ex. 24 | 0.37 | 10 | 0.37 | AA | C | D |
| Comp. Ex. 25 | 2.40 | 10 | 2.40 | D | — | — |
| Comp. Ex. 26 | 2.57 | 10.0 | 2.57 | D | — | — |

### II. Examples 33 to 49 and Comparative Examples 27 to 40

### <Deciding Compositional Ratio for Polyimide Precursor Resin Compositions>

### Example 33

The type of light for exposure was decided to be i-line. The resins listed in Table 8 were selected as polyimide precursor resins (A) having an absorbance parameter Xp in the range of 0.001 to 0.20. The compounds listed in Table 8 were selected as exposure ray absorbers having an absorbance parameter Xt in the range of 0.01 to 0.05. The compounds listed in Table 8 were also selected as photopolymerization initiators (C) having an absorbance parameter Xr in the range of 0 to 0.04. The assumed thickness D of the prebaked film was set to 5 μm. The values for α and β were decided to be the mass fractions listed in Table 8, satisfying “0.7≤(Xp+Xt×α+Xr×β)×D≤2.2”. The (Xp+Xt×α+Xr×β3)×D values were as listed in Table 9.

### Examples 34 to 49

The compositional ratio for each polyimide precursor resin composition was decided in the same manner as Example 33.

### <Preparation of Polyimide Precursor Resin Compositions>

### Examples 33 to 49 and Comparative Examples 27 to 40

The polyimide precursor resin (A), the exposure ray absorber (B), the photopolymerization initiator (C), the photopolymerizable compound (E), the hindered phenol compound (F) and the polymerization inhibitor (G) in the contents shown in Tables 8 and 10 were dissolved in a mixed solvent of γ-butyrolactone and DMSO as the solvent (D) (80:20 weight ratio), to prepare PI precursor resin compositions for Examples 33 to 49 and Comparative Examples 27 to 40. The contents in Tables 8 and 10 are mass fractions for each component with component (A) as 100 parts by mass. The viscosity of the obtained solution was adjusted to approximately 15 poise by further adding a small amount of the mixed solvent, and then filtered using a polyethylene filter with 0.2 μm pores, to obtain a resin composition.

### <Production and Evaluation of Relief Pattern Films>

A sputtering apparatus (Model L-440S-FHL, product of Canon Anelva Corp.) was used for sputtering of Ti to a 200 nm thickness and Cu to a 400 nm thickness, in that order, on a 6-inch wafer (product of Fujimi Denshi Kogyo, thickness: 625±25 μm), to prepare a sputtered Cu wafer substrate. The PI precursor resin composition was spin coated onto the sputtered Cu wafer substrate using a spin coater (Model D-SPIN60A by Sokudo Co.), and was then dried on a hot plate for 180 seconds at 100° C. to fabricate a coating film with a thickness of 5 μm±0.2 μm (D′). The spin coated film was exposed with a Prisma GHI S/N5503 1:1 projection exposure system (product of Ultratech Co.) using a test pattern reticle with a round concave 5 μm diameter pattern, and using a mounted gh-line cut filter to vary the exposure dose from 30 mJ/cm2 to 150 mJ/cm² in 10 mJ/cm2 increments. The coating film formed on the sputter Cu wafer was then subjected to spray development with a developing machine (Model D-SPIN 636 by Dainippon Screen Mfg. Co., Ltd.) using cyclopentanone, and rinsed with propyleneglycol methyl ether acetate to obtain a polyamic acid ester pattern. The developing time for spray development was defined as 1.4× the minimum time required to develop the resin composition at the unexposed sections for a 5 μm spin coated film.

### <Evaluation of Tapered Pattern Form>

A cross-section was cut out from the obtained round concave 5 μm diameter pattern using an FIB apparatus (JIB-4000 by JEOL Corp.) and the cross-sectional shape of the pattern was observed, measuring the taper angle of the pattern with respect to the substrate, as a slope at the tapering midpoint. The pattern cross-sectional shape was evaluated as Excellent (AA) for a taper angle of 70° to 80°, Good (A) for 80° to 90°, and unacceptable (D) for other angles. Samples with undercutting or bridging at the pattern cross-section were also evaluated as Unacceptable. Samples with unacceptable pattern form in the tapered form evaluation were not assessed in the following maximum resolution or sensitivity tolerance evaluations.

### <Maximum Resolution Evaluation>

The round concave diameter was changed, and the minimum mask dimension for the resulting round concave relief pattern was recorded at the maximum resolution (μm) and evaluated on the following scale.
A: Pattern of <3.5 μm opened
B: Pattern of ≥3.5 μm and <4.5 μm opened
C: Pattern of ≥4.5 μm and <6 μm opened
D: Pattern of <6 μm not opened

It was determined that the round concave relief pattern opened if both of the following conditions (I) and (II) were satisfied.
(I) The area of the pattern openings was at least ½ of the corresponding pattern mask open area.
(II) The pattern cross-section had no bottom trailing and was free of undercuts, swelling and bridging.

### <Sensitivity Tolerance Evaluation>

The range of exposure dose with which 5 μm diameter openings were observed in the obtained round concave relief pattern was evaluated on the following scale.
A: Opening of 5 μm pattern with exposure dose width of 30 mJ/cm2 or greater
B: Opening of 5 μm pattern with exposure dose width of 20 mJ/cm2 or greater and less than 30 mJ/cm2
C: Opening of 5 μm pattern with exposure dose width of 10 mJ/cm2 or greater and less than 20 mJ/cm²
D: Pinpoint opening or no opening of 5 μm pattern

TABLE 8

| | | (A) PI precursor | | (B) Exposure | | (C) Photopolymerization | | | | (E) Photopolymerizable | | | |
|---|---|---|---|---|---|---|---|---|---|---|---|---|---|
| | | resin | | ray absorber | | initiator | | | | crosslinking agent | | (F) | (G) |
| | D | | Mass | | Mass | | Mass | | Mass | | Mass | Mass | Mass |
| | (μm) | Type | fraction | Type | fraction | Type | fraction | Type | fraction | Type | fraction | fraction | fraction |
| Example 33 | 5 | A-1 | 100 | B-1 | 10 | C-2 | 2 | — | — | E-1 | 20 | 0.50 | 0.05 |
| Example 34 | 5 | A-1 | 100 | B-1 | 4.5 | C-2 | 2 | — | — | E-1 | 20 | 0.50 | 0.05 |
| Example 35 | 5 | A-1 | 100 | B-3 | 8 | C-2 | 4 | — | — | E-1 | 20 | 0.50 | 0.05 |
| Example 36 | 5 | A-1 | 100 | B-4 | 8 | C-2 | 2 | — | — | E-1 | 20 | 0.50 | 0.05 |
| Example 37 | 5 | A-2 | 100 | B-1 | 10 | C-2 | 2 | — | — | E-1 | 20 | 0.50 | 0.05 |
| Example 38 | 5 | A-3 | 100 | B-1 | 8 | C-2 | 4 | — | — | E-1 | 20 | 0.50 | 0.05 |
| Example 39 | 5 | A-4 | 100 | B-1 | 10 | C-2 | 4 | — | — | E-1 | 20 | 0.50 | 0.05 |
| Example 40 | 5 | A-3 | 60 | B-1 | 5 | C-2 | 2 | — | — | E-1 | 20 | 0.50 | 0.05 |
| | | A-4 | 40 | | | | | | | | | | |
| Example 41 | 5 | A-5 | 100 | B-1 | 8 | C-2 | 4 | — | — | E-1 | 20 | 0.50 | 0.05 |
| Example 42 | 5 | A-1 | 100 | B-11 | 5 | C-2 | 3 | — | — | E-1 | 20 | 0.50 | 0.05 |
| Example 43 | 5 | A-1 | 100 | B-12 | 4 | C-2 | 3 | — | — | E-1 | 20 | 0.50 | 0.05 |
| Example 44 | 5 | A-1 | 100 | B-1 | 12 | C-2 | 4 | — | — | E-1 | 20 | 0.50 | 0.05 |
| Example 45 | 5 | A-1 | 100 | B-2 | 5 | C-2 | 4 | — | — | E-1 | 20 | 0.50 | 0.05 |
| Example 46 | 5 | A-8 | 100 | B-1 | 7 | C-2 | 2 | — | — | E-1 | 20 | 0.50 | 0.05 |
| Example 47 | 5 | A-1 | 100 | B-5 | 8 | C-2 | 2 | — | — | E-1 | 20 | 0.50 | 0.05 |
| Example 48 | 5 | A-1 | 100 | B-1 | 8 | C-1 | 4 | — | — | E-1 | 20 | 0.50 | 0.05 |
| Example 49 | 5 | A-1 | 100 | B-7 | 8 | C-2 | 2 | — | — | E-1 | 20 | 0.50 | 0.05 |

TABLE 9

| | | D′ | | Taper | Maximum | Sensitivity |
|---|---|---|---|---|---|---|
| | (Xp + Xt*α + Xr*β)*D | (um) | (Xp + Xt*α + Xr*β)*D' | form | resolution | tolerance |
| Example 33 | 1.28 | 5 | 1.28 | AA | A | A |
| Example 34 | 0.70 | 5.1 | 0.72 | AA | A | A |
| Example 35 | 1.08 | 5 | 1.08 | AA | B | A |
| Example 36 | 0.99 | 4.9 | 0.97 | AA | B | A |
| Example 37 | 1.22 | 5 | 1.22 | AA | A | A |
| Example 38 | 1.12 | 5.1 | 1.14 | AA | B | A |
| Example 39 | 1.89 | 5 | 1.89 | A | B | A |
| Example 40 | 0.94 | 5 | 0.94 | AA | B | A |
| Example 41 | 1.32 | 5.1 | 1.35 | AA | B | A |
| Example 42 | 0.90 | 5 | 0.90 | AA | B | C |
| Example 43 | 0.92 | 5 | 0.92 | AA | B | B |
| Example 44 | 1.58 | 4.9 | 1.55 | A | A | A |
| Example 45 | 0.80 | 5 | 0.80 | AA | A | B |
| Example 46 | 0.90 | 5 | 0.90 | AA | A | A |
| Example 47 | 0.95 | 5 | 0.95 | AA | B | B |
| Example 48 | 0.98 | 5.1 | 1.00 | AA | A | A |
| Example 49 | 1.15 | 5 | 1.15 | AA | B | A |

TABLE 10

| | | (A) PI precursor | | (B) Exposure ray | | | | | | (E) Photopolymerizable | | | |
|---|---|---|---|---|---|---|---|---|---|---|---|---|---|
| | | resin | | absorber | | (C) Photopolymerization initiator | | | | crosslinking agent | | (F) | (G) |
| | D | | Mass | | Mass | | Mass | | Mass | | Mass | Mass | Mass |
| | (μm) | Type | fraction | Type | fraction | Type | fraction | Type | fraction | Type | fraction | fraction | fraction |
| Comp. Ex. 27 | 5 | A-1 | 100 | B-1 | 1 | C-2 | 2 | — | — | E-1 | 20 | 0.50 | 0.05 |
| Comp. Ex. 28 | 5 | A-1 | 100 | — | — | C-2 | 2 | — | — | E-1 | 20 | 0.50 | 0.05 |
| Comp. Ex. 29 | 5 | A-2 | 100 | B-1 | 2 | C-2 | 2 | — | — | E-1 | 20 | 0.50 | 0.05 |
| Comp. Ex. 30 | 5 | A-3 | 100 | B-3 | 1 | C-2 | 2 | — | — | E-1 | 20 | 0.50 | 0.05 |
| Comp. Ex. 31 | 5 | A-4 | 100 | — | — | C-2 | 2 | — | — | E-1 | 20 | 0.50 | 0.05 |
| Comp. Ex. 32 | 5 | A-4 | 100 | B-1 | 20 | C-2 | 2 | — | — | E-1 | 20 | 0.50 | 0.05 |
| Comp. Ex. 33 | 5 | A-3 | 60 | B-1 | 1 | C-2 | 2 | — | — | E-1 | 20 | 0.50 | 0.05 |
| | | A-4 | 40 | | | | | | | | | | |
| Comp. Ex. 34 | 5 | A-5 | 100 | B-1 | 1 | C-2 | 2 | — | — | E-1 | 20 | 0.50 | 0.05 |
| Comp. Ex. 35 | 5 | A-7 | 100 | B-12 | 1 | C-1 | 7 | C-3 | 0.2 | E-1 | 20 | 0.50 | 0.05 |
| Comp. Ex. 36 | 5 | A-8 | 100 | B-11 | 1 | C-1 | 6 | C-3 | 0.4 | E-1 | 20 | 0.50 | 0.05 |
| Comp. Ex. 37 | 5 | A-8 | 100 | B-12 | 1 | C-1 | 7 | C-3 | 0.2 | E-1 | 20 | 0.50 | 0.05 |
| Comp. Ex. 38 | 5 | A-1 | 100 | — | — | C-2 | 13 | — | — | E-1 | 20 | 0.50 | 0.05 |
| Comp. Ex. 39 | 5 | A-1 | 100 | B-1 | 8 | — | — | — | — | E-1 | 20 | 0.50 | 0.05 |
| Comp. Ex. 40 | 5 | A-8 | 100 | B-9 | 1 | C-1 | 7 | C-3 | 0.2 | E-1 | 20 | 0.50 | 0.05 |

TABLE 11

| | | | | Taper | Maximum | Sensitivity |
|---|---|---|---|---|---|---|
| | (Xp + Xt*α + Xr*β)*D | D′ | (Xp + Xt*α + Xr*β)*D′ | form | resolution | tolerance |
| Comp. Ex. 27 | 0.34 | 4.9 | 0.33 | AA | B | D |
| Comp. Ex. 28 | 0.23 | 5.0 | 0.23 | AA | C | D |
| Comp. Ex. 29 | 0.38 | 5.0 | 0.38 | AA | B | D |
| Comp. Ex. 30 | 0.29 | 5.0 | 0.29 | AA | D | D |
| Comp. Ex. 31 | 0.75 | 5.1 | 0.76 | AA | C | D |
| Comp. Ex. 32 | 2.85 | 4.9 | 2.79 | D | — | — |
| Comp. Ex. 33 | 0.52 | 5.0 | 0.52 | AA | C | D |
| Comp. Ex. 34 | 0.50 | 5.0 | 0.50 | AA | C | D |
| Comp. Ex. 35 | 0.19 | 5 | 0.19 | AA | C | D |
| Comp. Ex. 36 | 0.22 | 5.1 | 0.22 | AA | C | D |
| Comp. Ex. 37 | 0.24 | 5 | 0.24 | AA | C | D |
| Comp. Ex. 38 | 0.73 | 5 | 0.73 | AA | D | D |
| Comp. Ex. 39 | 0.98 | 5 | 0.98 | D | — | — |
| Comp. Ex. 40 | 0.20 | 5 | 0.20 | AA | C | D |

### III. Examples 50 to 65 and Comparative Examples 41 to 44

### <Deciding Compositional Ratio for Polyimide Precursor Resin Compositions>

### Examples 50 to 65

The compositional ratio for each polyimide precursor resin composition was decided in the same manner as Example 1.

### <Preparation of Polyimide Precursor Resin Compositions>

### Examples 50 to 65 and Comparative Examples 41 to 44

The polyimide precursor resin (A), the exposure ray absorber (B), the photopolymerization initiator (C), the photopolymerizable compound (E), the hindered phenol compound (F), the polymerization inhibitor (G) and the nitrogen-containing heterocyclic rust inhibitor (H) in the contents shown in the table were dissolved in a mixed solvent of γ-butyrolactone and DMSO as the solvent (D) (80:20 weight ratio), to prepare PI precursor resin compositions for Examples 50 to 65 and Comparative Examples 41 to 44. The contents in the tables are mass fractions for each component with component (A) as 100 parts by mass. The viscosity of the obtained solution was adjusted to approximately 40 poise by further adding a small amount of the mixed solvent, and then filtered using a polyethylene filter with 0.2 μm pores, to obtain a resin composition.

### <Production and Evaluation of Relief Pattern Films>

The obtained polyimide precursor resin compositions were used to produce relief pattern films in the same manner as Examples 1 to 32 and Comparative Examples 1 to 26.

### <Evaluation of Tapered Pattern Form>

The tapered forms of the obtained relief pattern films were evaluated in the same manner as Examples 1 to 32 and Comparative Examples 1 to 26.

### <Maximum Resolution Evaluation>

The resolutions of the obtained relief pattern films were evaluated in the same manner as Examples 1 to 32 and Comparative Examples 1 to 26.

### <Sensitivity Tolerance Evaluation>

The sensitivity tolerances of the obtained relief pattern films were evaluated in the same manner as Examples 1 to 32 and Comparative Examples 1 to 26.

### <Storage Stability Evaluation>

After preparing the photosensitive resin composition, and stirring for 3 days at room temperature (23.0° C.±0.5° C., relative humidity: 50%±10%) as the initial state, it was allowed to stand for 4 weeks at room temperature. The PI precursor resin composition in the initial state was spin coated onto a 6-inch silicon wafer (product of Fujimi Denshi Kogyo, thickness: 625±25 μm) using a spin coater (Model D-SPIN60A by Sokudo Co.), and was then dried on a hot plate for 180 seconds at 100° C. to fabricate a prebaked film with a thickness of 10.0 μm±0.2 μm (D′). The spin coated film was exposed with a Prisma GHI S/N5503 1:1 projection exposure system (product of Ultratech Co.) using a test pattern reticle with a round concave 10 μm diameter pattern, and using a mounted gh-line cut filter to vary the exposure dose from 30 mJ/cm2 to 270 mJ/cm2 in 20 mJ/cm² increments. The coating film formed on the wafer was then subjected to spray development with a developing machine (Model D-SPIN 636 by Dainippon Screen Mfg. Co., Ltd.) using cyclopentanone, and rinsed with propyleneglycol methyl ether acetate to obtain a polyamic acid ester pattern. The developing time for spray development was defined as 1.4× the minimum time required to develop the resin composition at the unexposed sections for a 10.0 μm spin coated film. The film thickness was measured for different exposure doses on the relief pattern obtained in Example 50. FIG. 2 shows an example of an obtained sensitivity curve. The ordinate represents the normalized film thickness as: (Film thickness after exposure development/film thickness before exposure)×100(%), and the abscissa represents exposure dose. The exposure dose at the sections with normalized film thickness of about 85% was defined as the sensitivity exposure (mJ/cm2).

Next, the PI precursor resin composition that had been allowed to stand at room temperature for 4 weeks was spin coated, exposed and developed under the same conditions as the PI precursor resin composition in the initial state, fabricating a relief pattern film, and the normalized film thickness was calculated in the same manner. The storage stability was evaluated on the following scale, based on the amount of change in normalized film thickness over time at the sensitivity exposure set by evaluation of the PI precursor resin in the initial state. For example, the amount of change in the normalized film thickness over time is 1.3% in FIG. 2.
A: Amount of change in normalized film thickness over time was from 0 to less than ±2%.
B: Amount of change in normalized film thickness over time was ±2% or greater.

In Tables 13 and 15, samples with higher values for normalized film thickness of the PI precursor resin composition after standing for 4 weeks compared to the normalized film thickness of the PI precursor resin composition in the initial state are listed in the (+) column, and those with lower values are listed in the (−) column.

TABLE 12

| | | (A) PI precursor | | (B) Exposure ray | | (C) Photopolymerization | | | |
|---|---|---|---|---|---|---|---|---|---|
| | | resin | | absorber | | initiator | | | |
| | D | | Mass | | Mass | | Mass | | Mass |
| | (μm) | Type | fraction | Type | fraction | Type | fraction | Type | fraction |
| Example 50 | 10 | A-1 | 100 | B-1 | 4 | C-2 | 2 | — | — |
| Example 51 | 10 | A-3 | 100 | B-1 | 4 | C-2 | 2 | — | — |
| Example 52 | 10 | A-5 | 100 | B-1 | 2.5 | C-2 | 2 | — | — |
| Example 53 | 10 | A-1 | 100 | B-1 | 4 | C-2 | 2 | — | — |
| Example 54 | 10 | A-1 | 100 | B-12 | 2.5 | C-2 | 2 | — | — |
| Example 55 | 10 | A-1 | 100 | B-12 | 2.5 | C-2 | 2 | — | — |
| Example 56 | 10 | A-1 | 100 | B-11 | 3 | C-2 | 2 | — | — |
| Example 57 | 10 | A-1 | 100 | B-11 | 3 | C-2 | 2 | — | — |
| Example 58 | 10 | A-1 | 100 | B-1 | 4 | C-2 | 2 | — | — |
| Example 59 | 10 | A-1 | 100 | B-12 | 2.5 | C-2 | 2 | — | — |
| Example 60 | 10 | A-1 | 100 | B-11 | 3 | C-2 | 2 | — | — |
| Example 61 | 10 | A-5 | 100 | B-1 | 2.5 | C-2 | 2 | — | — |
| Example 62 | 10 | A-8 | 100 | B-1 | 4 | C-2 | 2 | — | — |
| Example 63 | 10 | A-8 | 100 | B-12 | 3 | C-2 | 2 | — | — |
| Example 64 | 10 | A-8 | 100 | B-1 | 4 | C-2 | 2 | — | — |
| Example 65 | 10 | A-8 | 100 | B-12 | 3 | C-2 | 2 | — | — |

| | | | | | (H) Rust- | |
|---|---|---|---|---|---|---|
| | (E) Photopolymerizable | | | | preventive agent | |
| | crosslinking agent | | (F) | (G) | mass fraction | |
| | | Mass | Mass | Mass | | Mass |
| | Type | fraction | fraction | fraction | Type | fraction |
| Example 50 | E-1 | 20 | 0.50 | 0.05 | H-1 | 0.50 |
| Example 51 | E-1 | 20 | 0.50 | 0.05 | H-1 | 0.50 |
| Example 52 | E-1 | 20 | 0.50 | 0.05 | H-1 | 0.50 |
| Example 53 | E-1 | 20 | 0.50 | 0.05 | H-2 | 0.50 |
| Example 54 | E-1 | 20 | 0.50 | 0.05 | H-1 | 0.50 |
| Example 55 | E-1 | 20 | 0.50 | 0.05 | H-2 | 0.50 |
| Example 56 | E-1 | 20 | 0.50 | 0.05 | H-1 | 0.50 |
| Example 57 | E-1 | 20 | 0.50 | 0.05 | H-2 | 0.50 |
| Example 58 | E-1 | 20 | 0.50 | 0.05 | — | — |
| Example 59 | E-1 | 20 | 0.50 | 0.05 | — | — |
| Example 60 | E-1 | 20 | 0.50 | 0.05 | — | — |
| Example 61 | E-1 | 20 | 0.50 | 0.05 | — | — |
| Example 62 | E-1 | 20 | 0.50 | 0.05 | H-2 | 0.50 |
| Example 63 | E-1 | 20 | 0.50 | 0.05 | H-2 | 0.50 |
| Example 64 | E-1 | 20 | 0.50 | 0.05 | — | — |
| Example 65 | E-1 | 20 | 0.50 | 0.05 | — | — |

TABLE 13

| | | | | | | | Storage | |
|---|---|---|---|---|---|---|---|---|
| | | D′ | | Taper | Maximum | Sensitivity | stability | |
| | (Xp + Xt*α + Xr*β)*D | (um) | (Xp + Xt*α + Xr*β)*D′ | form | resolution | tolerance | + | − |
| Example 50 | 1.30 | 10.1 | 1.31 | AA | A | A | A | |
| Example 51 | 1.22 | 9.9 | 1.21 | AA | B | B | | A |
| Example 52 | 1.31 | 10 | 1.31 | AA | B | B | | A |
| Example 53 | 1.30 | 10.1 | 1.31 | AA | A | A | A | |
| Example 54 | 1.26 | 10 | 1.26 | AA | B | B | A | |
| Example 55 | 1.26 | 9.9 | 1.25 | AA | B | B | A | |
| Example 56 | 1.21 | 10 | 1.21 | AA | B | C | A | |
| Example 57 | 1.21 | 10 | 1.21 | AA | B | C | A | |
| Example 58 | 1.30 | 10.1 | 1.31 | AA | A | A | B | |
| Example 59 | 1.26 | 9.9 | 1.25 | AA | B | B | B | |
| Example 60 | 1.21 | 9.9 | 1.20 | AA | B | C | B | |
| Example 61 | 1.31 | 10 | 1.31 | AA | B | B | | B |
| Example 62 | 1.17 | 9.9 | 1.16 | AA | A | A | A | |
| Example 63 | 1.29 | 10 | 1.29 | AA | B | B | A | |
| Example 64 | 1.17 | 10.1 | 1.18 | AA | A | A | B | |
| Example 65 | 1.29 | 10 | 1.29 | AA | B | B | B | |

TABLE 14

| | | | | | | | | | | | | | | (H) Rust- | |
|---|---|---|---|---|---|---|---|---|---|---|---|---|---|---|---|
| | | (A) PI precursor | | (B) Exposure ray | | (C) Photopolymerization | | | | (E) Photopolymerizable | | | | preventive agent | |
| | | resin | | absorber | | initiator | | | | crosslinking agent | | | | mass fraction | |
| | | | Mass | | Mass | | Mass | | Mass | | Mass | (F) | (G) | | Mass |
| | D | | frac- | | frac- | | frac- | | frac- | | frac- | Mass | Mass | | frac- |
| | (μm) | Type | tion | Type | tion | Type | tion | Type | tion | Type | tion | fraction | fraction | Type | tion |
| Comp. | 10 | A-1 | 100 | — | — | C-2 | 2 | — | — | E-1 | 20 | 0.50 | 0.05 | H-1 | 0.50 |
| Ex. 41 | | | | | | | | | | | | | | | |
| Comp. | 10 | A-1 | 100 | — | — | C-2 | 2 | — | — | E-1 | 20 | 0.50 | 0.05 | H-2 | 0.50 |
| Ex. 42 | | | | | | | | | | | | | | | |
| Comp. | 10 | A-8 | 100 | — | — | C-2 | 2 | — | — | E-1 | 20 | 0.50 | 0.05 | H-2 | 0.50 |
| Ex. 43 | | | | | | | | | | | | | | | |
| Comp. | 10 | A-5 | 100 | — | — | C-2 | 2 | — | — | E-1 | 20 | 0.50 | 0.05 | H-1 | 0.50 |
| Ex. 44 | | | | | | | | | | | | | | | |

TABLE 15

| | | | | | | | Storage | |
|---|---|---|---|---|---|---|---|---|
| | | D′ | | Taper | Maximum | Sensitivity | stability | |
| | (Xp + Xt*α + Xr*β)*D | (um) | (Xp + Xt*α + Xr*β)*D′ | form | resolution | tolerance | + | − |
| Comp. Ex. 41 | 0.46 | 10 | 0.46 | AA | B | D | B | |
| Comp. Ex. 42 | 0.46 | 9.9 | 0.46 | AA | B | D | B | |
| Comp. Ex. 43 | 0.33 | 10.1 | 0.33 | AA | C | D | B | |
| Comp. Ex. 44 | 0.78 | 10 | 0.78 | AA | C | D | | B |

### IV. Examples 66 to 78 and Comparative Examples 45 to 47

### <Deciding Compositional Ratio for Polyimide Precursor Resin Compositions>

### Examples 66 to 78

The compositional ratio for each polyimide precursor resin composition was decided in the same manner as Example 33.

### <Preparation of Polyimide Precursor Resin Compositions>

### Examples 66 to 78 and Comparative Examples 45 to 47

The polyimide precursor resin (A), the exposure ray absorber (B), the photopolymerization initiator (C), the photopolymerizable compound (E), the hindered phenol compound (F), the polymerization inhibitor (G) and the nitrogen-containing heterocyclic rust inhibitor (H) in the contents shown in the table were dissolved in a mixed solvent of γ-butyrolactone and DMSO as the solvent (D) (80:20 weight ratio), to prepare PI precursor resin compositions for Examples 66 to 78 and Comparative Examples 45 to 47. The contents in the tables are mass fractions for each component with component (A) as 100 parts by mass. The viscosity of the obtained solution was adjusted to approximately 15 poise by further adding a small amount of the mixed solvent, and then filtered using a polyethylene filter with 0.2 μm pores, to obtain a resin composition. The symbols in the tables indicate the components mentioned above.

### <Production and Evaluation of Relief Pattern Films>

The obtained polyimide precursor resin compositions were used to produce relief pattern films in the same manner as Examples 33 to 49 and Comparative Examples 27 to 40.

### <Evaluation of Tapered Pattern Form>

The tapered forms of the obtained relief pattern films were evaluated in the same manner as Examples 33 to 49 and Comparative Examples 27 to 40.

### <Maximum Resolution Evaluation>

The resolutions of the obtained relief pattern films were evaluated in the same manner as Examples 33 to 49 and Comparative Examples 27 to 40.

### <Sensitivity Tolerance Evaluation>

The sensitivity tolerances of the obtained relief pattern films were evaluated in the same manner as Examples 33 to 49 and Comparative Examples 27 to 40.

### <Storage Stability Evaluation>

After preparing the photosensitive resin composition, and stirring for 3 days at room temperature (23.0° C.±0.5° C., relative humidity: 50%±10%) as the initial state, it was allowed to stand for 4 weeks at room temperature. The PI precursor resin composition in the initial state was spin coated onto a 6-inch silicon wafer (product of Fujimi Denshi Kogyo, thickness: 625±25 μm) using a spin coater (Model D-SPIN60A by Sokudo Co.), and was then dried on a hot plate for 180 seconds at 100° C. to fabricate a prebaked film with a thickness of 5.0 μm±0.2 μm (D′). The spin coated film was exposed with a Prisma GHI S/N5503 1:1 projection exposure system (product of Ultratech Co.) using a test pattern reticle with a round concave 10 μm diameter pattern, and using a mounted gh-line cut filter to vary the exposure dose from 30 mJ/cm² to 150 mJ/cm² in 10 mJ/cm² increments. The coating film formed on the wafer was then subjected to spray development with a developing machine (Model D-SPIN 636 by Dainippon Screen Mfg. Co., Ltd.) using cyclopentanone, and rinsed with propyleneglycol methyl ether acetate to obtain a polyamic acid ester pattern. The developing time for spray development was defined as 1.4× the minimum time required to develop the resin composition at the unexposed sections for a 5.0 μm spin coated film. The normalized film thickness was calculated for the obtained relief pattern, and the exposure dose at the sections where the normalized film thickness was about 80% was defined as the sensitivity exposure (mJ/cm2).

The PI precursor resin composition that had been allowed to stand at room temperature for 4 weeks was then spin coated, exposed and developed under the same conditions as the PI precursor resin composition in the initial state, and the storage stability was evaluated on the following scale based on amount of change in normalized film thickness over time for sensitivity exposure.
A: Amount of change in normalized film thickness over time was from 0 to less than ±2%. B: Amount of change in normalized film thickness over time was ±2% or greater.

In Tables 17 and 19, samples with higher values for normalized film thickness of the PI precursor resin composition after standing for 4 weeks compared to the normalized film thickness of the PI precursor resin composition in the initial state are listed in the (+) column, and those with lower values are listed in the (−) column.

TABLE 16

| | | (A) PI precursor | | (B) Exposure ray | | (C) Photopolymerization | | | |
|---|---|---|---|---|---|---|---|---|---|
| | | resin | | absorber | | initiator | | | |
| | D | | Mass | | Mass | | Mass | | Mass |
| | (μm) | Type | fraction | Type | fraction | Type | fraction | Type | fraction |
| Example 66 | 5 | A-1 | 100 | B-1 | 6 | C-2 | 2 | — | — |
| Example 67 | 5 | A-1 | 100 | B-1 | 6 | C-2 | 2 | — | — |
| Example 68 | 5 | A-1 | 100 | B-12 | 4 | C-2 | 2 | — | — |
| Example 69 | 5 | A-1 | 100 | B-12 | 4 | C-2 | 2 | — | — |
| Example 70 | 5 | A-1 | 100 | B-11 | 5 | C-2 | 2 | — | — |
| Example 71 | 5 | A-1 | 100 | B-11 | 5 | C-2 | 2 | — | — |
| Example 72 | 5 | A-1 | 100 | B-1 | 6 | C-2 | 2 | — | — |
| Example 73 | 5 | A-1 | 100 | B-12 | 4 | C-2 | 2 | — | — |
| Example 74 | 5 | A-1 | 100 | B-11 | 5 | C-2 | 2 | — | — |
| Example 75 | 5 | A-8 | 100 | B-1 | 6 | C-2 | 2 | — | — |
| Example 76 | 5 | A-8 | 100 | B-12 | 4 | C-2 | 2 | — | — |
| Example 77 | 5 | A-8 | 100 | B-1 | 6 | C-2 | 2 | — | — |
| Example 78 | 5 | A-8 | 100 | B-12 | 4 | C-2 | 2 | — | — |

| | | | | | (H) Rust- | |
|---|---|---|---|---|---|---|
| | (E) Photopolymerizable | | | | preventive agent | |
| | crosslinking agent | | | | mass fraction | |
| | | Mass | (F) Mass | (G) Mass | | Mass |
| | Type | fraction | fraction | fraction | Type | fraction |
| Example 66 | E-1 | 20 | 0.50 | 0.05 | H-1 | 0.50 |
| Example 67 | E-1 | 20 | 0.50 | 0.05 | H-2 | 0.50 |
| Example 68 | E-1 | 20 | 0.50 | 0.05 | H-1 | 0.50 |
| Example 69 | E-1 | 20 | 0.50 | 0.05 | H-2 | 0.50 |
| Example 70 | E-1 | 20 | 0.50 | 0.05 | H-1 | 0.50 |
| Example 71 | E-1 | 20 | 0.50 | 0.05 | H-2 | 0.50 |
| Example 72 | E-1 | 20 | 0.50 | 0.05 | — | — |
| Example 73 | E-1 | 20 | 0.50 | 0.05 | — | — |
| Example 74 | E-1 | 20 | 0.50 | 0.05 | — | — |
| Example 75 | E-1 | 20 | 0.50 | 0.05 | H-2 | 0.50 |
| Example 76 | E-1 | 20 | 0.50 | 0.05 | H-2 | 0.50 |
| Example 77 | E-1 | 20 | 0.50 | 0.05 | — | — |
| Example 78 | E-1 | 20 | 0.50 | 0.05 | — | — |

TABLE 17

| | | | | | | Storage | |
|---|---|---|---|---|---|---|---|
| | D′ | | Taper | Maximum | Sensitivity | stability | |
| (Xp + Xt*α + Xr*β)*D | (um) | (Xp + Xt*α + Xr*β)*D′ | form | resolution | tolerance | + | − |

| | | | | | | | |
|---|---|---|---|---|---|---|---|
| Example 66 | 0.86 | 5.1 | 0.88 | AA | A | A | A |
| Example 67 | 0.86 | 5 | 0.86 | AA | A | A | A |
| Example 68 | 0.87 | 5 | 0.87 | AA | B | B | A |
| Example 69 | 0.87 | 5 | 0.87 | AA | B | B | A |
| Example 70 | 0.86 | 5.1 | 0.87 | AA | B | C | A |
| Example 71 | 0.86 | 5 | 0.86 | AA | B | C | A |
| Example 72 | 0.86 | 5 | 0.86 | AA | A | A | B |
| Example 73 | 0.87 | 5 | 0.87 | AA | B | B | B |
| Example 74 | 0.86 | 4.9 | 0.84 | AA | B | C | B |
| Example 75 | 0.80 | 5 | 0.80 | AA | A | A | A |
| Example 76 | 0.81 | 5 | 0.81 | AA | B | B | A |
| Example 77 | 0.80 | 5 | 0.80 | AA | A | A | B |
| Example 78 | 0.81 | 5.1 | 0.82 | AA | B | B | B |

TABLE 18

| | | | | | | | | | | (E) | | | | (H) Rust- | |
|---|---|---|---|---|---|---|---|---|---|---|---|---|---|---|---|
| | | (A) PI precursor | | (B) Exposure ray | | (C) Photopolymerization | | | | Photopolymerizable | | | | preventive agent | |
| | | resin | | absorber | | initiator | | | | crosslinking agent | | | | mass fraction | |
| | | | Mass | | Mass | | Mass | | Mass | | Mass | (F) Mass | (G) Mass | | Mass |
| | D | | frac- | | frac- | | frac- | | frac- | | frac- | frac- | frac- | | frac- |
| | (μm) | Type | tion | Type | tion | Type | tion | Type | tion | Type | tion | tion | tion | Type | tion |
| Comp. | 5 | A-1 | 100 | — | — | C-2 | 2 | — | — | E-1 | 20 | 0.50 | 0.05 | H-1 | 0.50 |
| Ex. 45 | | | | | | | | | | | | | | | |
| Comp. | 5 | A-1 | 100 | — | — | C-2 | 2 | — | — | E-1 | 20 | 0.50 | 0.05 | H-2 | 0.50 |
| Ex. 46 | | | | | | | | | | | | | | | |
| Comp. | 5 | A-8 | 100 | — | — | C-2 | 2 | — | — | E-1 | 20 | 0.50 | 0.05 | H-2 | 0.50 |
| Ex. 47 | | | | | | | | | | | | | | | |

TABLE 19

| | | | | | | Storage | |
|---|---|---|---|---|---|---|---|
| | D′ | | Taper | Maximum | Sensitivity | stability | |
| (Xp + Xt*α + Xr*β)*D | (um) | (Xp + Xt*α + Xr*β)*D′ | form | resolution | tolerance | + | − |

| | | | | | | | |
|---|---|---|---|---|---|---|---|
| Comp. Ex. 45 | 0.23 | 5 | 0.23 | AA | C | D | B |
| Comp. Ex. 46 | 0.23 | 5 | 0.23 | AA | C | D | B |
| Comp. Ex. 47 | 0.17 | 5.1 | 0.17 | AA | C | D | B |

From the results shown in Tables 4 to 19 it is clear that the PI precursor resin compositions of the Examples which comprised exposure ray absorbers exhibited improved maximum resolution and sensitivity tolerance compared to the Comparative Examples. Tables 12 to 19 further show that in the Examples that included both an exposure ray absorber and a nitrogen-containing heterocyclic rust inhibitor, the storage stability test results were “A”, with the storage stability specifically being superior when using the combination of both compared to a composition with only either one alone.

### INDUSTRIAL APPLICABILITY

According to the disclosure it is possible to provide a patterned cured film having excellent resolution and handleability, and a method of forming a cured relief pattern using the PI precursor resin composition described above, by adjusting the light transmittance for the resin composition as a whole using the light ray (i-line) absorbing function of an exposure ray absorber. The present disclosure can be utilized with advantages in the field of photosensitive materials that are useful for production of electrical and electronic materials such as semiconductor devices and multilayer circuit boards.

1. A method for producing a polyimide (PI) precursor resin composition comprising a PI precursor resin, an exposure ray absorber, a photopolymerization initiator and a solvent, wherein the method includes:
specifying a type of light to be used for exposure;
selecting the PI precursor resin from among resins having an absorbance parameter Xp in the range of 0.001 to 0.20 for the specified type of light, selecting the exposure ray absorber from among materials having an absorbance parameter Xt in the range of 0.01 to 0.05 for the specified type of light, and selecting the photopolymerization initiator from among materials having an absorbance parameter Xr in the range of 0 to 0.04 for the specified type of light;
deciding mass fraction α of the exposure ray absorber to be added and mass fraction β of the photopolymerization initiator to be added, with respect to 100 parts by mass of the PI precursor resin, so as to satisfy the following formula:
0.7≤(Xp+Xt×α+Xr×β)×D≤2.2
based on the absorbance parameter Xp of the selected PI precursor resin, the absorbance parameter Xt of the selected exposure ray absorber, the absorbance parameter Xr of the selected photopolymerization initiator, and an assumed thickness D of a prebaked film after coating and solvent removal of the PI precursor resin composition; and
preparing a PI precursor resin composition so as to include the decided PI precursor resin, the exposure ray absorber at the decided mass fraction α, the photopolymerization initiator at the decided mass fraction β, and the solvent.

2. The method according to claim 1, wherein the PI precursor resin has a structural unit represented by the following formula (1): 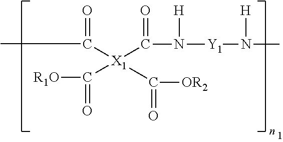
{where X₁ is a tetravalent organic group, Y₁ is a divalent organic group, n₁ is an integer of 2 to 150, and R₁ and R₂ are each independently a hydrogen atom, a monovalent organic group represented by the following general formula (2) or a saturated aliphatic group of 1 to 4 carbon atoms.} 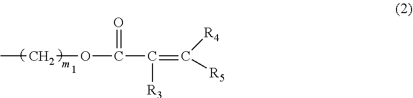
{where R₃, R₄ and R₅ are each independently a hydrogen atom or an organic group of 1 to 3 carbon atoms, and mi is an integer of 2 to 10}.

3. The method according to claim 1, wherein the type of light used for exposure is i-line.

4. The method according to claim 1, wherein the assumed thickness D is set to be 1 μm or greater and less than 7 μm for deciding the mass fraction α of the exposure ray absorber to be added and the mass fraction β of the photopolymerization initiator to be added.

5. The method according to claim 1, wherein the photopolymerization initiator has an oxime ester structure represented by the following general formula (5): 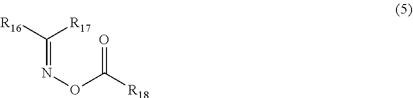
{where R₁₆, R₁₇ and R₁₈ are each a monovalent organic group, and R₁₆ and R₁₇ may be linked together to form a ring structure}.

6. The method according to claim 1, wherein the PI precursor resin composition further includes a nitrogen-containing heterocyclic rust inhibitor.

7. The method according to claim 1, wherein the exposure ray absorber is a compound having a 1,2-naphthoquinonediazide structure.

8. The method according to claim 1, wherein the PI precursor resin composition further includes a photopolymerizable compound.

9. The method according to claim 1, wherein Y₁ in formula (1) is a divalent organic group represented by the following formula (3): 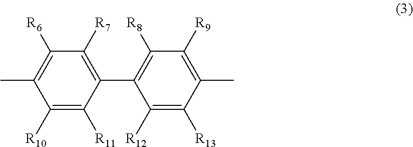
{where R₆ to R₁₃ are each independently a hydrogen atom, a fluorine atom or a monovalent organic group, with at least one of R₆ to R₁₃ being a methyl, trifluoromethyl or methoxy group}.

10. The method according to claim 1, wherein Y₁ in formula (1) is a divalent organic group represented by the following formula (4): 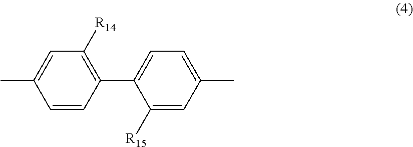
{where R₁₄ and R₁₅ are each independently a methyl, trifluoromethyl or methoxy group}.

11. The method according to claim 1, wherein the exposure ray absorber is a 1,2-naphthoquinonediazide-4-sulfonic acid ester and/or 1,2-naphthoquinonediazide-5-sulfonic acid ester of at least one hydroxy compound selected from the group consisting of the following general formulas (6) to (10): 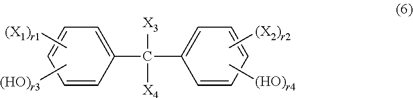
{where X₁ and X₂ are each independently a hydrogen atom or a monovalent organic group of 1 to 60 carbon atoms, X₃ and X₄ are each independently a hydrogen atom or a monovalent organic group of 1 to 60 carbon atoms, r1, r2, r3 and r4 are each independently an integer of 0 to 5, at least one of r3 and r4 is an integer of 1 to 5, r1+r3=5 and r2+r4=5}, 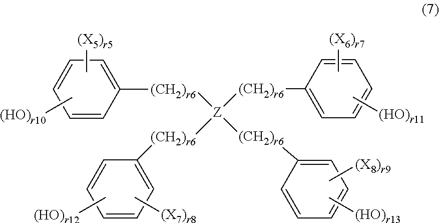
{where Z is a tetravalent organic group of 1 to 20 carbon atoms, X₅, X₆, X₇ and X₈ are each independently a monovalent organic group of 1 to 30 carbon atoms, r6 is an integer of 0 or 1, r5, r7, r8 and r9 are each independently an integer of 0 to 3, r10, r11, r12 and r13 are each independently an integer of 0 to 2, and at least one of r10, r11, r12 and r13 is 1 or 2}, 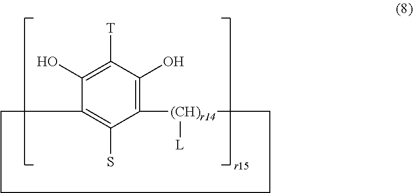
{where r14 is an integer of 1 to 5, r15 is an integer of 3 to 8, the L groups in the number of r14×r15 are each independently a monovalent organic group of 1 to 20 carbon atoms, the T groups in the number of r15 are each independently a hydrogen atom or a monovalent organic group of 1 to 20 carbon atoms, and the S groups in the number of r15 are each independently a hydrogen atom or a monovalent organic group of 1 to 20 carbon atoms}, 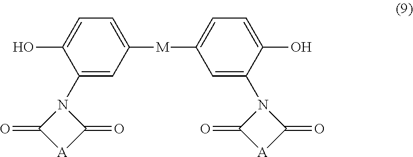
{where A is a divalent organic group including an aliphatic tertiary or quaternary carbon atom, and M is a divalent organic group}, 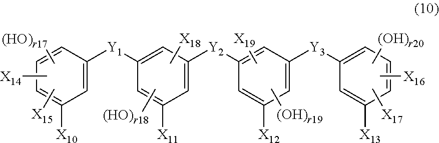
{where r17, r18, r19 and r20 are each independently an integer of 0 to 2, at least one of r17, r18, r19 and r20 being 1 or 2, X₁₀ to X₁₉ are each independently a hydrogen atom, a halogen atom or at least one monovalent group selected from the group consisting of alkyl, alkenyl, alkoxy, allyl and acyl groups, and Y₁ to Y₃ are each independently a single bond, or at least one divalent group selected from the group consisting of —O—, —S—, —SO—, —SO₂—, —CO—, —CO₂—, cyclopentylidene, cyclohexylidene, phenylene and divalent organic groups of 1 to 20 carbon atoms}.

12. The method according claim 1, wherein the exposure ray absorber is a 1,2-naphthoquinonediazide-5-sulfonic acid ester of at least one hydroxy compound selected from the group consisting of formulas (6) to (10).

13. The method according to claim 1, wherein the esterification rate of the exposure ray absorber is 80% or greater.

14. The method according to claim 1, wherein the hydroxy compound represented by general formula (6) above is represented by the following general formula (11): 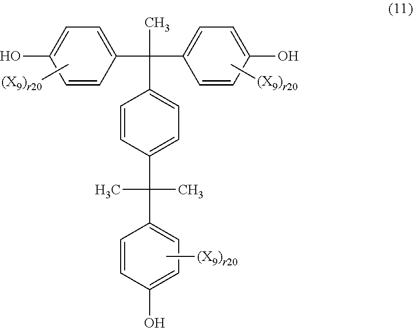
{where each r20 is independently an integer of 0 to 2, and each X₉ is independently a hydrogen atom or a monovalent organic group of 1 to 20 carbon atoms}.

15. A method for producing a relief pattern film, wherein the method includes:
producing a PI precursor resin composition comprising a PI precursor resin, an exposure ray absorber, a photopolymerization initiator and a solvent by the method according to claim 1,
film coating in which a coating film of the PI precursor resin composition is obtained,
drying in which the solvent in the coating film is removed to obtain a photosensitive resin layer of thickness D′,
exposing in which the photosensitive resin layer is exposed by a specified type of light, and
developing in which the exposed photosensitive resin layer is developed to obtain a relief pattern film.

16. A method for producing a relief pattern film according to claim 15,
wherein the coating film of thickness D′ after solvent removal satisfies:
0.7≤(Xp+Xt×α+Xr×β)×D′≤2.2.

17. A PI precursor resin composition comprising a PI precursor resin, an exposure ray absorber at mass fraction α and a photopolymerization initiator at mass fraction β with respect to 100 parts by mass of the PI precursor resin, and a solvent, wherein:
the relationships between:
the absorbance parameter Xp of the PI precursor resin for i-line,
the absorbance parameter Xt of the exposure ray absorber for i-line,
the absorbance parameter Xr of the photopolymerization initiator for i-line,
the mass fraction α of the exposure ray absorber, and
the mass fraction β of the photopolymerization initiator, are:
0.7≤(Xp+Xt×α+Xr×β)×10≤2.2, or 0.7≤(Xp+Xt×α+Xr×β)×5≤2.2,
wherein 0.001≤Xp≤0.20
0.01≤Xt≤0.05, and
0≤Xr≤0.04.

18. (canceled)

19. The PI precursor resin composition according to claim 17, wherein the PI precursor resin has a structural unit represented by the following formula (1): 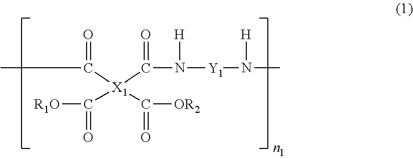
{where X₁ is a tetravalent organic group, Y₁ is a divalent organic group, n₁ is an integer of 2 to 150, and R₁ and R₂ are each independently a hydrogen atom or a monovalent organic group represented by the following general formula (2) or a saturated aliphatic group of 1 to 4 carbon atoms.} 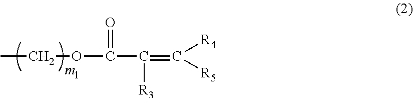
{where R₃, R₄ and R₅ are each independently a hydrogen atom or an organic group of 1 to 3 carbon atoms, and mi is an integer of 2 to 10}.

20. The PI precursor resin composition according to claim 17, wherein the photopolymerization initiator has an oxime ester structure represented by the following general formula (5): 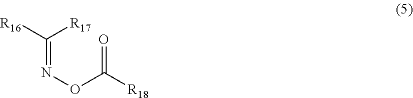
{where R₁₆, R₁₇ and R₁₈ are each a monovalent organic group, and R₁₆ and R₁₇ may be linked together to form a ring structure}.

21. The PI precursor resin composition according to claim 17, wherein the PI precursor resin composition further includes a nitrogen-containing heterocyclic rust inhibitor.

22. The PI precursor resin composition according to claim 17, wherein the exposure ray absorber is a compound having a 1,2-naphthoquinonediazide structure.

23. The PI precursor resin composition according to claim 17, wherein the PI precursor resin composition further includes a photopolymerizable compound.

24. The PI precursor resin composition according to claim 17, wherein Y₁ in formula (1) is a divalent organic group represented by the following formula (3): 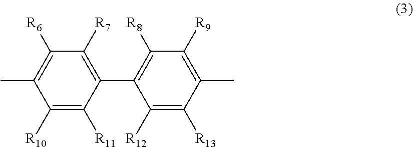
{where R₆ to R₁₃ are each independently a hydrogen atom, a fluorine atom or a monovalent organic group, with at least one of R₆ to R₁₃ being a methyl, trifluoromethyl or methoxy group}.

25. The PI precursor resin composition according to claim 17, wherein Y₁ in formula (1) is a divalent organic group represented by the following formula (4): 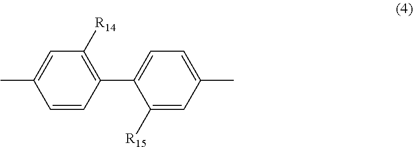
{where R₁₄ and R₁₅ are each independently a methyl, trifluoromethyl or methoxy group}.

26. The PI precursor resin composition according to claim 17, wherein the exposure ray absorber is a 1,2-naphthoquinonediazide-4-sulfonic acid ester and/or 1,2-naphthoquinonediazide-5-sulfonic acid ester of at least one hydroxy compound selected from the group consisting of the following general formulas (6) to (10): 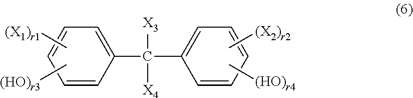
{where X₁ and X₂ are each independently a hydrogen atom or a monovalent organic group of 1 to 60 carbon atoms, X₃ and X₄ are each independently a hydrogen atom or a monovalent organic group of 1 to 60 carbon atoms, r1, r2, r3 and r4 are each independently an integer of 0 to 5, at least one of r3 and r4 is an integer of 1 to 5, r1+r3=5 and r2+r4=5}, 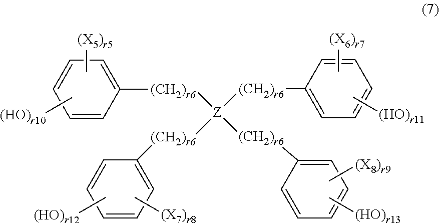
{where Z is a tetravalent organic group of 1 to 20 carbon atoms, X₅, X₆, X₇ and X₈ are each independently a monovalent organic group of 1 to 30 carbon atoms, r6 is an integer of 0 or 1, r5, r7, r8 and r9 are each independently an integer of 0 to 3, r10, r11, r12 and r13 are each independently an integer of 0 to 2, and at least one of r10, r11, r12 and r13 is 1 or 2}, 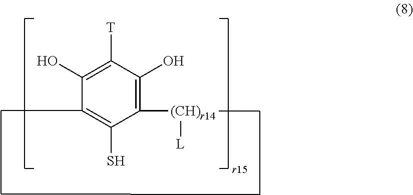
{where r14 is an integer of 1 to 5, r15 is an integer of 3 to 8, the L groups in the number of r14×r15 are each independently a monovalent organic group of 1 to 20 carbon atoms, the T groups in the number of r15 are each independently a hydrogen atom or a monovalent organic group of 1 to 20 carbon atoms, and the S groups in the number of r15 are each independently a hydrogen atom or a monovalent organic group of 1 to 20 carbon atoms}, 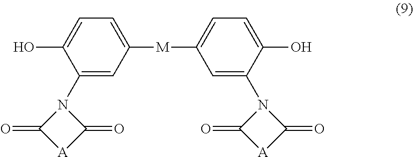
{where A is a divalent organic group including an aliphatic tertiary or quaternary carbon atom, and M is a divalent organic group}, 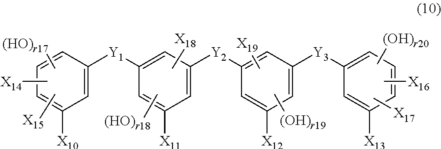
{where r17, r18, r19 and r20 are each independently an integer of 0 to 2, at least one of r17, r18, r19 and r20 being 1 or 2, X₁₀ to X₁₉ are each independently a hydrogen atom, a halogen atom or at least one monovalent group selected from the group consisting of alkyl, alkenyl, alkoxy, allyl and acyl groups, and Y₁ to Y₃ are each independently a single bond, or at least one divalent group selected from the group consisting of —O—, —S—, —SO—, —SO₂—, —CO—, —CO₂—, cyclopentylidene, cyclohexylidene, phenylene and divalent organic groups of 1 to 20 carbon atoms}.

27. The PI precursor resin composition according to claim 17, wherein the exposure ray absorber is a 1,2-naphthoquinonediazide-5-sulfonic acid ester of at least one hydroxy compound selected from the group consisting of formulas (6) to (10).

28. The PI precursor resin composition according to claim 17, wherein the esterification rate of the exposure ray absorber is 80% or greater.

29. The PI precursor resin composition according to claim 17, wherein the hydroxy compound represented by general formula (6) above is represented by the following general formula (11): 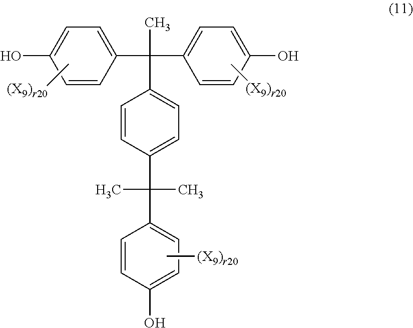
{where each r20 is independently an integer of 0 to 2, and each X₉ is independently a hydrogen atom or a monovalent organic group of 1 to 20 carbon atoms}.

30. A cured film of a PI precursor resin composition according to claim 17.

31. A prebaked film which has a thickness D′ satisfying 1 μm≤D′≤20 μm, wherein:
the prebaked film comprises a polyimide (PI) precursor resin, an exposure ray absorber at mass fraction α with respect to 100 parts by mass of the PI precursor resin and a photopolymerization initiator at mass fraction β with respect to 100 parts by mass of the PI precursor resin, and a solvent,
the PI precursor resin has an absorbance parameter Xp in the range of 0.001≤Xp≤0.20 for i-line,
the exposure ray absorber has an absorbance parameter Xt in the range of 0.01≤Xt≤0.05 for i-line,
the photopolymerization initiator has an absorbance parameter Xr in the range of 0≤Xr≤0.04 for i-line, and
the parameters satisfy the following inequality:
0.7≤(Xp+Xt×α+Xr×β)×D′≤2.2.

32. The prebaked film according to claim 31, wherein the PI precursor resin has a structural unit represented by the following formula (1): 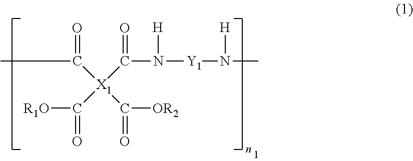
{where X₁ is a tetravalent organic group, Y₁ is a divalent organic group, n₁ is an integer of 2 to 150, and R₁ and R₂ are each independently a hydrogen atom or a monovalent organic group represented by the following general formula (2) or a saturated aliphatic group of 1 to 4 carbon atoms.} 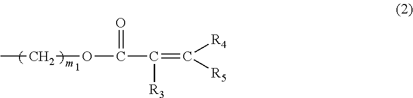
{where R₃, R₄ and R₅ are each independently a hydrogen atom or an organic group of 1 to 3 carbon atoms, and mi is an integer of 2 to 10}.

33. The prebaked film according to claim 31, wherein the thickness D′ of the prebaked film satisfies 1 μm≤D′<7 μm.

34. The prebaked film according to claim 31, wherein the photopolymerization initiator has an oxime ester structure represented by the following general formula (5): 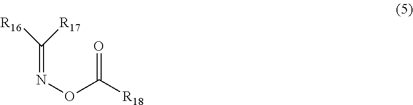
{where R₁₆, R₁₇ and R₁₈ are each a monovalent organic group, and R₁₆ and R₁₇ may be linked together to form a ring structure}.

35. The prebaked film according to claim 31, wherein the prebaked film further includes a nitrogen-containing heterocyclic rust inhibitor.

36. The prebaked film according to claim 31, wherein the exposure ray absorber is a compound having a 1,2-naphthoquinonediazide structure.

37. The prebaked film according to claim 31, wherein the prebaked film further includes a photopolymerizable compound.

38. The prebaked film according to claim 31, wherein Y₁ in formula (1) is a divalent organic group represented by the following formula (3): 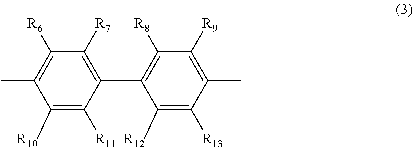
{where R₆ to R₁₃ are each independently a hydrogen atom, a fluorine atom or a monovalent organic group, with at least one of R₆ to R₁₃ being a methyl, trifluoromethyl or methoxy group}.

39. The prebaked film according to claim 31, wherein Y₁ in formula (1) is a divalent organic group represented by the following formula (4): 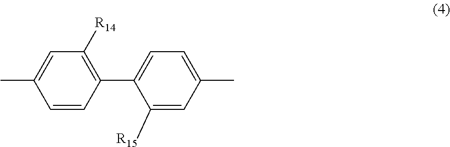
{where R₁₄ and R₁₅ are each independently a methyl, trifluoromethyl or methoxy group}.

40. The prebaked film according to claim 31, wherein the exposure ray absorber is a 1,2-naphthoquinonediazide-4-sulfonic acid ester and/or 1,2-naphthoquinonediazide-5-sulfonic acid ester of at least one hydroxy compound selected from the group consisting of the following general formulas (6) to (10): 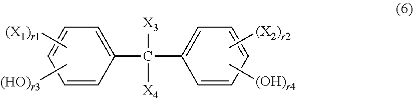
{where X₁ and X₂ are each independently a hydrogen atom or a monovalent organic group of 1 to 60 carbon atoms, X₃ and X₄ are each independently a hydrogen atom or a monovalent organic group of 1 to 60 carbon atoms, r1, r2, r3 and r4 are each independently an integer of 0 to 5, at least one of r3 and r4 is an integer of 1 to 5, r1+r3=5 and r2+r4=5}, 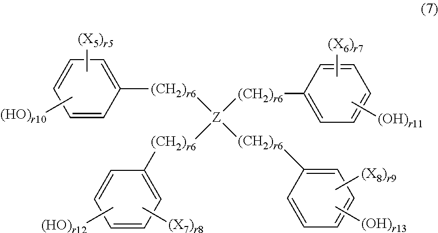
{where Z is a tetravalent organic group of 1 to 20 carbon atoms, X₅, X₆, X₇ and X₈ are each independently a monovalent organic group of 1 to 30 carbon atoms, r6 is an integer of 0 or 1, r5, r7, r8 and r9 are each independently an integer of 0 to 3, r10, r11, r12 and r13 are each independently an integer of 0 to 2, and at least one of r10, r11, r12 and r13 is 1 or 2}, 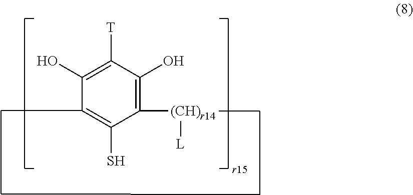
{where r14 is an integer of 1 to 5, r15 is an integer of 3 to 8, the L groups in the number of r14×r15 are each independently a monovalent organic group of 1 to 20 carbon atoms, the T groups in the number of r15 are each independently a hydrogen atom or a monovalent organic group of 1 to 20 carbon atoms, and the S groups in the number of r15 are each independently a hydrogen atom or a monovalent organic group of 1 to 20 carbon atoms}, 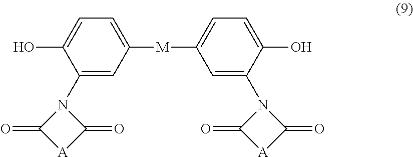
{where A is a divalent organic group including an aliphatic tertiary or quaternary carbon atom, and M is a divalent organic group}, 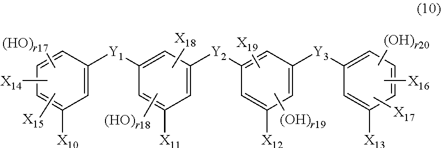
{where r17, r18, r19 and r20 are each independently an integer of 0 to 2, at least one of r17, r18, r19 and r20 being 1 or 2, X₁₀ to X₁₉ are each independently a hydrogen atom, a halogen atom or at least one monovalent group selected from the group consisting of alkyl, alkenyl, alkoxy, allyl and acyl groups, and Y₁ to Y₃ are each independently a single bond, or at least one divalent group selected from the group consisting of —O—, —S—, —SO—, —SO₂—, —CO—, —CO₂—, cyclopentylidene, cyclohexylidene, phenylene and divalent organic groups of 1 to 20 carbon atoms}.

41. The prebaked film according to claim 31, wherein the exposure ray absorber is a 1,2-naphthoquinonediazide-5-sulfonic acid ester of at least one hydroxy compound selected from the group consisting of formulas (6) to (10).

42. The prebaked film according to claim 31, wherein the esterification rate of the exposure ray absorber is 80% or greater.

43. The prebaked film according to claim 31, wherein the hydroxy compound represented by general formula (6) above is represented by the following general formula (11): 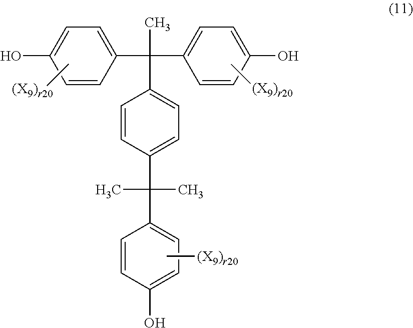
{where each r20 is independently an integer of 0 to 2, and each X₉ is independently a hydrogen atom or a monovalent organic group of 1 to 20 carbon atoms}.
